(19) United States
(12) Patent Application Publication
(10) Pub. No.: US 2024/0172393 A1
(43) Pub. Date: May 23, 2024

(54) METHODS AND APPARATUS FOR IMMERSION COOLING SYSTEMS

(71) Applicant: Intel Corporation, Santa Clara, CA (US)

(72) Inventors: Sandeep Ahuja, Portland, OR (US); Yang Yao, Shanghai (CN); Ming Zhang, Shanghai (CN); Yuehong Fan, Shanghai (CN); Xiang Que, Suzhou (CN); Mark MacDonald, Beaverton, OR (US); Casey Jamesen Carte, Portland, OR (US); Yue Yang, Shanghai (CN); Eric D. McAfee, Portland, OR (US); Satyam Saini, Hillsboro, OR (US); Suchismita Sarangi, Lindstrom, MN (US); Drew Damm, Beaverton, OR (US); Jessica Gullbrand, Brightwood, OR (US)

(21) Appl. No.: 18/428,991

(22) Filed: Jan. 31, 2024

Related U.S. Application Data
(63) Continuation of application No. PCT/CN2023/139912, filed on Dec. 19, 2023.

(30) Foreign Application Priority Data
Dec. 19, 2023 (WO) PCT/CN2023/139912

(51) Int. Cl. H05K 7/20

(52) U.S. Cl. CPC H05K 7/20272; H05K 7/20236; H05K 7/20772

(57) ABSTRACT

Methods and apparatus for immersion cooling systems are disclosed herein. An example apparatus includes a base plate, fins extending from the base plate, a tube extending along an axis through the fins, the tube including an inlet, and a slot extending along the axis, the inlet, the slot, and the fins sequentially defining a flow pathway.

### FIELD OF THE DISCLOSURE

This disclosure relates generally to cooling systems and, more particularly, to methods and apparatus for immersion cooling systems.

### BACKGROUND

The use of liquids to cool electronic components is being explored for its benefits over more traditional air cooling systems, as there is an increasing need to address thermal management risks resulting from increased thermal design power in high performance systems (e.g., CPU and/or GPU servers in data centers, cloud computing, edge computing, and the like). More particularly, relative to air, liquid has inherent advantages of higher specific heat (when no boiling is involved) and higher latent heat of vaporization (when boiling is involved).

### BRIEF DESCRIPTION OF THE DRAWINGS

FIG. 1 illustrates one or more example environments in which teachings of this disclosure may be implemented.

FIG. 2 illustrates at least one example of a data center for executing workloads with disaggregated resources.

FIG. 3 illustrates at least one example of a pod that may be included in the data center of FIG. 2.

FIG. 4 is a perspective view of at least one example of a rack that may be included in the pod of FIG. 3.

FIG. 5 is a side elevation view of the rack of FIG. 4.

FIG. 6 is a perspective view of the rack of FIG. 4 having a sled mounted therein.

FIG. 7 is a is a block diagram of at least one example of a top side of the sled of FIG. 6.

FIG. 8 is a block diagram of at least one example of a bottom side of the sled of FIG. 7.

FIG. 9 is a block diagram of at least one example of a compute sled usable in the data center of FIG. 2.

FIG. 10 is a top perspective view of at least one example of the compute sled of FIG. 9.

FIG. 11 is a block diagram of at least one example of an accelerator sled usable in the data center of FIG. 2.

FIG. 12 is a top perspective view of at least one example of the accelerator sled of FIG. 11.

FIG. 13 is a block diagram of at least one example of a storage sled usable in the data center of FIG. 2.

FIG. 14 is a top perspective view of at least one example of the storage sled of FIG. 13.

FIG. 15 is a block diagram of at least one example of a memory sled usable in the data center of FIG. 2.

FIG. 16 is a block diagram of a system that may be established within the data center of FIG. 2 to execute workloads with managed nodes of disaggregated resources.

FIG. 17A is a block diagram of an example immersion tank having an example first coolant pathway arrangement including example ducts in accordance with teachings of this disclosure.

FIG. 17B is a block diagram of the immersion tank of FIG. 17A having an example second coolant pathway arrangement including example ducts in accordance with teachings of this disclosure.

FIG. 18 is a perspective view of the ducts FIGS. 17A and 17B coupled to an example bottom plate of the immersion tank of FIGS. 17A and 17B.

FIG. 19 is a perspective cross-sectional view of the coupling between the duct of FIGS. 17A-18 and the bottom plate of FIG. 18.

FIG. 20 is a front cross-section view of the coupling between one of the ducts of FIGS. 17A-18 and the bottom plate of FIG. 18.

FIG. 21A is a schematic view of an example first duct that can be used to implement the duct of FIGS. 17A-19.

FIG. 21B is a schematic view of an example second duct that can be used to implement the duct of FIGS. 17A-19.

FIG. 21C is a schematic view of an example third duct that can be used to implement the duct of FIGS. 17A-19.

FIG. 22 is a side schematic view of example system including a coolant distribution unit (CDU) the immersion cooling tank of FIGS. 17A and 17B, and flow control circuitry in accordance with teachings of this disclosure.

FIG. 23 is a perspective view of an example bottom plate that can be used with the immersion cooling tank of FIGS. 17A, 17B and 21.

FIG. 24A is a schematic view of the example system of FIG. 22 in an example first coolant pathway arrangement.

FIG. 24B is a schematic view of the example system of FIG. 22 in an example second coolant pathway arrangement.

FIG. 24C is a schematic view of the example system of FIG. 22 in an example third coolant pathway arrangement.

FIG. 25 is side schematic view of another example system including a CDU, the immersion cooling tank of FIGS. 17A and 17B, and flow control circuitry in accordance with teachings of this disclosure.

FIG. 26 is a block diagram of an example implementation of the flow control circuitry of FIGS. 21 and 25.

FIG. 27 is a flowchart representative of example machine readable instructions and/or example operations that may be executed, instantiated, and/or performed by example programmable circuitry to implement the flow control circuitry of FIG. 26.

FIG. 28 is a perspective view of an example heat sink assembly in accordance with teachings of this disclosure.

FIG. 29 is a cross-sectional top view of the example heat sink assembly of FIG. 28.

FIG. 30 is a cross-sectional top view of another example heat sink assembly in accordance with teachings of this disclosure.

FIG. 31 is a cross-sectional top view of another example heat sink assembly in accordance with teachings of this disclosure.

FIG. 32 is a cross-sectional top view of an example system including a plurality of heat sink assemblies in accordance with teachings of this disclosure.

FIG. 33A is a schematic view of an example first cooling system including the heat sink assemblies of FIG. 28-31.

FIG. 33B is a schematic view of an example second cooling system including the system of FIG. 32.

FIG. 34 is a block diagram of an example processing platform including programmable circuitry structured to execute, instantiate, and/or perform the example machine readable instructions and/or perform the example operations of FIG. 27 to implement the flow control circuitry of FIG. 26.

FIG. 35 is a block diagram of an example implementation of the programmable circuitry of FIG. 34.

FIG. 36 is a block diagram of another example implementation of the programmable circuitry of FIG. 34.

In general, the same reference numbers will be used throughout the drawing(s) and accompanying written description to refer to the same or like parts. The figures are not necessarily to scale.

### DETAILED DESCRIPTION

As noted above, the use of liquids to cool electronic components is being explored for its benefits over more traditional air cooling systems, as there are increasing needs to address thermal management risks resulting from increased thermal design power in high performance systems (e.g., CPU and/or GPU servers in data centers, accelerators, artificial intelligence computing, machine learning computing, cloud computing, edge computing, and the like). More particularly, relative to air, liquid has inherent advantages of higher specific heat (when no boiling is involved) and higher latent heat of vaporization (when boiling is involved). In some instances, liquid can be used to indirectly cool electronic components by cooling a cold plate that is thermally coupled to the electronic component(s). An alternative approach is to directly immerse electronic components in the cooling liquid. In direct immersion cooling, the liquid can be in direct contact with the electronic components to directly draw away heat from the electronic components. To enable the cooling liquid to be in direct contact with electronic components, the cooling liquid is electrically insulative (e.g., a dielectric liquid).

A liquid cooling system can involve at least one of single-phase cooling or two-phase cooling. As used herein, single-phase cooling (e.g., single-phase immersion cooling) means the cooling fluid (sometimes also referred to herein as cooling liquid or coolant) used to cool electronic components draws heat away from heat sources (e.g., electronic components) without changing phase (e.g., without boiling and becoming vapor). Such cooling fluids are referred to herein as single-phase cooling fluids, liquids, or coolants. By contrast, as used herein, two-phase cooling (e.g., two-phase immersion cooling) means the cooling fluid (in this case, a cooling liquid) vaporizes or boils from the heat generated by the electronic components to be cooled, thereby changing from the liquid phase to the vapor phase. The gaseous vapor may subsequently be condensed back into a liquid (e.g., via a condenser) to again be used in the cooling process. Such cooling fluids are referred to herein as two-phase cooling fluids, liquids, or coolants. Notably, gases (e.g., air) can also be used to cool components and, therefore, may also be referred to as a cooling fluid and/or a coolant. However, indirect cooling and immersion cooling typically involves at least one cooling liquid (which may or may not change to the vapor phase when in use). Example systems, apparatus, and associated methods to improve cooling systems and/or associated cooling processes are disclosed herein.

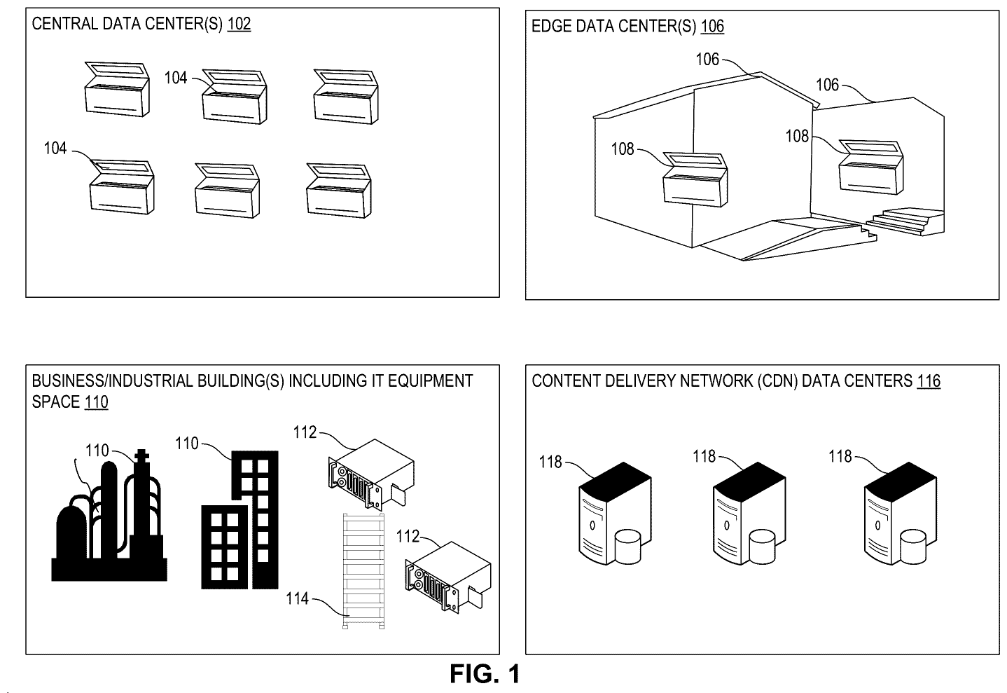

FIG. 1 illustrates one or more example environments in which teachings of this disclosure may be implemented. The example environment(s) of FIG. 1 can include one or more central data centers 102. The central data center(s) 102 can store a large number of servers used by, for instance, one or more organizations for data processing, storage, etc. As illustrated in FIG. 1, the central data center(s) 102 include a plurality of immersion tank(s) 104 to facilitate cooling of the servers and/or other electronic components stored at the central data center(s) 102. The immersion tank(s) 104 can provide for single-phase cooling or two-phase cooling.

The example environments of FIG. 1 can be part of an edge computing system. For instance, the example environments of FIG. 1 can include edge data centers or micro-data centers 106. The edge data center(s) 106 can include, for example, data centers located at a base of a cell tower. In some examples, the edge data center(s) 106 are located at or near a top of a cell tower and/or other utility pole. The edge data center(s) 106 include respective housings that store server(s), where the server(s) can be in communication with, for instance, the server(s) stored at the central data center(s) 102, client devices, and/or other computing devices in the edge network. Example housings of the edge data center(s) 106 may include materials that form one or more exterior surfaces that partially or fully protect contents therein, in which protection may include weather protection, hazardous environment protection (e.g., EMI, vibration, extreme temperatures), and/or enable submergibility. Example housings may include power circuitry to provide power for stationary and/or portable implementations, such as AC power inputs, DC power inputs, AC/DC or DC/AC converter(s), power regulators, transformers, charging circuitry, batteries, wired inputs and/or wireless power inputs. As illustrated in FIG. 1, the edge data center(s) 106 can include immersion tank(s) 108 to store server(s) and/or other electronic component(s) located at the edge data center(s) 106.

The example environment(s) of FIG. 1 can include buildings 110 for purposes of business and/or industry that store information technology (IT) equipment in, for example, one or more rooms of the building(s) 110. For example, as represented in FIG. 1, server(s) 112 can be stored with server rack(s) 114 that support the server(s) 112 (e.g., in an opening of a slot of the rack 114, etc.). In some examples, the server(s) 112 located at the buildings 110 include on-premise server(s) of an edge computing network, where the on-premise server(s) are in communication with remote server(s) (e.g., the server(s) at the edge data center(s) 106) and/or other computing device(s) within an edge network.

The example environment(s) of FIG. 1 include content delivery network (CDN) data center(s) 116. The CDN data center(s) 116 of this example include server(s) 118 that cache content such as images, webpages, videos, etc. accessed via user devices. The server(s) 118 of the CDN data centers 116 can be disposed in immersion cooling tank(s) such as the immersion tanks 104, 108 shown in connection with the data centers 102, 106.

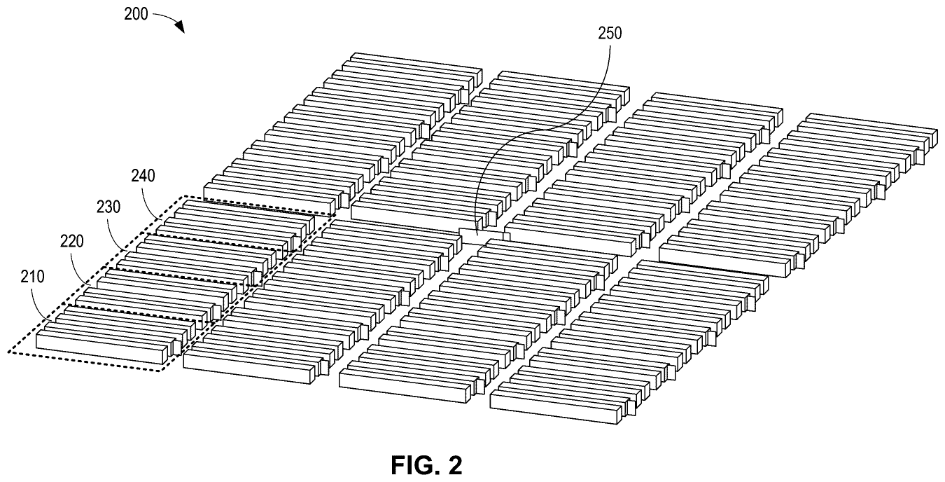

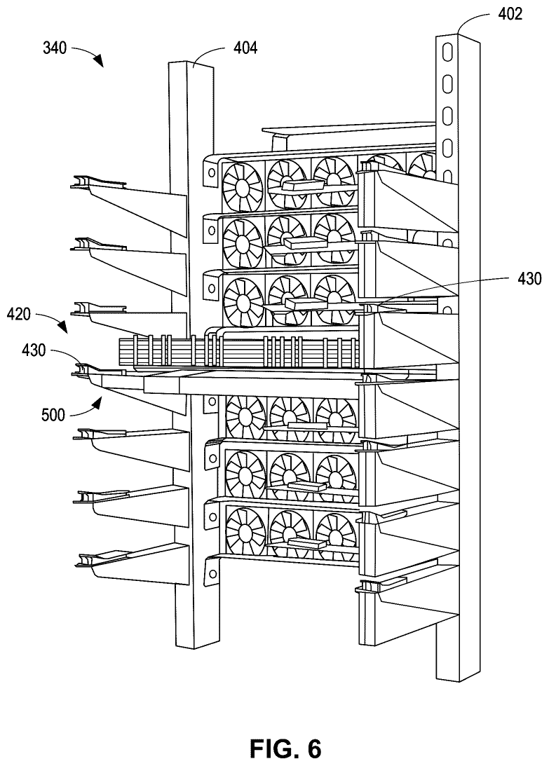

In some instances, the example data centers 102, 106, 116 and/or building(s) 110 of FIG. 1 include servers and/or other electronic components that are cooled independent of immersion tanks (e.g., the immersion tanks 104, 108) and/or an associated immersion cooling system. That is, in some examples, some or all of the servers and/or other electronic components in the data centers 102, 106, 116 and/or building(s) 110 can be cooled by air and/or liquid coolants without immersing the servers and/or other electronic components therein. Thus, in some examples, the immersion tanks 104, 108 of FIG. 1 may be omitted. Further, the example data centers 102, 106, 116 and/or building(s) 110 of FIG. 1 can correspond to, be implemented by, and/or be adaptations of the example data center 200 described in further detail below in connection with FIGS. 2-16.

Although a certain number of cooling tank(s) and other component(s) are shown in the figures, any number of such components may be present. Also, the example cooling data centers and/or other structures or environments disclosed herein are not limited to arrangements of the size that are depicted in FIG. 1. For instance, the structures containing example cooling systems and/or components thereof disclosed herein can be of a size that includes an opening to accommodate service personnel, such as the example data center(s) 106 of FIG. 1, but can also be smaller (e.g., a “doghouse” enclosure). For instance, the structures containing example cooling systems and/or components thereof disclosed herein can be sized such that access (e.g., the only access) to an interior of the structure is a port for service personnel to reach into the structure. In some examples, the structures containing example cooling systems and/or components thereof disclosed herein are be sized such that only a tool can reach into the enclosure because the structure may be supported by, for a utility pole or radio tower, or a larger structure.

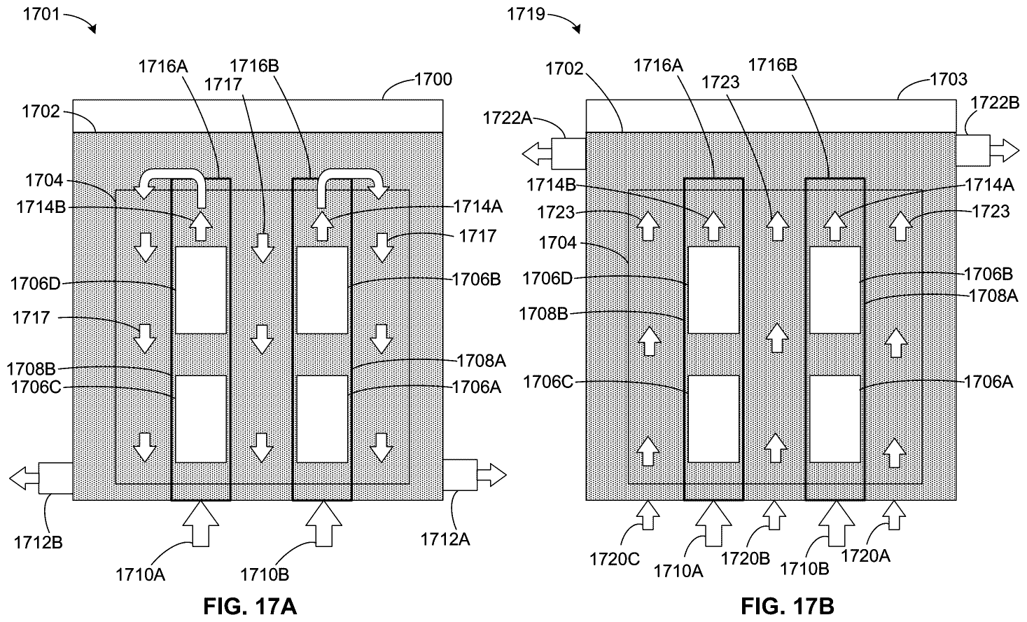

In addition to or as an alternative to the immersion tanks 104, 108, any of the example environments of FIG. 1 can utilize one or more liquid cooling systems having a cold plate to control the temperature of the electronic devices/components in the example environments. An example liquid cooling system and example cold plates are disclosed in further detail in connection with FIGS. 17A-33B.

FIG. 2 illustrates an example data center 200 in which disaggregated resources may cooperatively execute one or more workloads (e.g., applications on behalf of customers). The illustrated data center 200 includes multiple platforms 210, 220, 230, 240 (referred to herein as pods), each of which includes one or more rows of racks. Although the data center 200 is shown with multiple pods, in some examples, the data center 200 may be implemented as a single pod. As described in more detail herein, a rack may house multiple sleds. A sled may be primarily equipped with a particular type of resource (e.g., memory devices, data storage devices, accelerator devices, general purpose programmable circuitry), i.e., resources that can be logically coupled to form a composed node. Some such nodes may act as, for example, a server. In the illustrative example, the sleds in the pods 210, 220, 230, 240 are connected to multiple pod switches (e.g., switches that route data communications to and from sleds within the pod). The pod switches, in turn, connect with spine switches 250 that switch communications among pods (e.g., the pods 210, 220, 230, 240) in the data center 200. In some examples, the sleds may be connected with a fabric using Intel Omni-Path™ technology. In other examples, the sleds may be connected with other fabrics, such as InfiniBand or Ethernet. As described in more detail herein, resources within the sleds in the data center 200 may be allocated to a group (referred to herein as a “managed node”) containing resources from one or more sleds to be collectively utilized in the execution of a workload. The workload can execute as if the resources belonging to the managed node were located on the same sled. The resources in a managed node may belong to sleds belonging to different racks, and even to different pods 210, 220, 230, 240. As such, some resources of a single sled may be allocated to one managed node while other resources of the same sled are allocated to a different managed node (e.g., first programmable circuitry assigned to one managed node and second programmable circuitry of the same sled assigned to a different managed node).

A data center including disaggregated resources, such as the data center 200, can be used in a wide variety of contexts, such as enterprise, government, cloud service provider, and communications service provider (e.g., Telco's), as well in a wide variety of sizes, from cloud service provider mega-data centers that consume over 200,000 sq. ft. to single- or multi-rack installations for use in base stations.

In some examples, the disaggregation of resources is accomplished by using individual sleds that include predominantly a single type of resource (e.g., compute sleds including primarily compute resources, memory sleds including primarily memory resources). The disaggregation of resources in this manner, and the selective allocation and deallocation of the disaggregated resources to form a managed node assigned to execute a workload, improves the operation and resource usage of the data center 200 relative to typical data centers. Such typical data centers include hyperconverged servers containing compute, memory, storage and perhaps additional resources in a single chassis. For example, because a given sled will contain mostly resources of a same particular type, resources of that type can be upgraded independently of other resources. Additionally, because different resource types (programmable circuitry, storage, accelerators, etc.) typically have different refresh rates, greater resource utilization and reduced total cost of ownership may be achieved. For example, a data center operator can upgrade the programmable circuitry throughout a facility by only swapping out the compute sleds. In such a case, accelerator and storage resources may not be contemporaneously upgraded and, rather, may be allowed to continue operating until those resources are scheduled for their own refresh. Resource utilization may also increase. For example, if managed nodes are composed based on requirements of the workloads that will be running on them, resources within a node are more likely to be fully utilized. Such utilization may allow for more managed nodes to run in a data center with a given set of resources, or for a data center expected to run a given set of workloads, to be built using fewer resources.

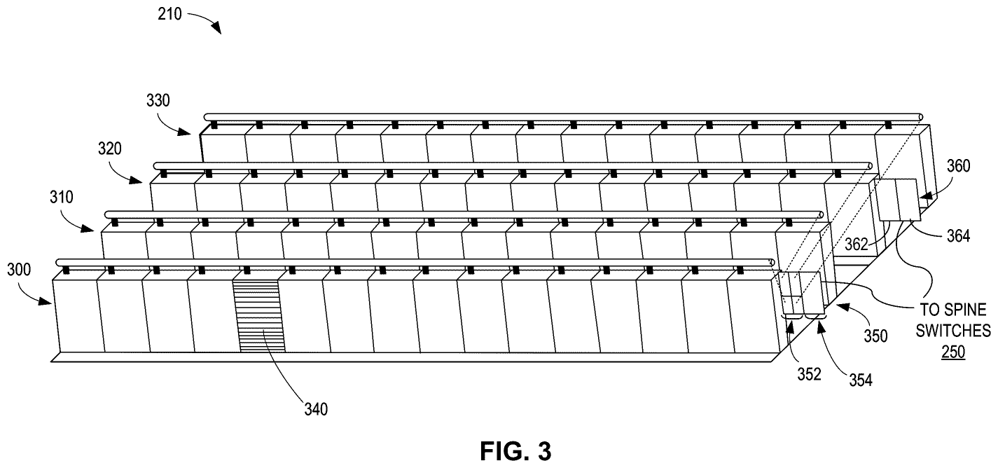

Referring now to FIG. 3, the pod 210, in the illustrative example, includes a set of rows 300, 310, 320, 330 of racks 340. Individual ones of the racks 340 may house multiple sleds (e.g., sixteen sleds) and provide power and data connections to the housed sleds, as described in more detail herein. In the illustrative example, the racks are connected to multiple pod switches 350, 360. The pod switch 350 includes a set of ports 352 to which the sleds of the racks of the pod 210 are connected and another set of ports 354 that connect the pod 210 to the spine switches 250 to provide connectivity to other pods in the data center 200. Similarly, the pod switch 360 includes a set of ports 362 to which the sleds of the racks of the pod 210 are connected and a set of ports 364 that connect the pod 210 to the spine switches 250. As such, the use of the pair of switches 350, 360 provides an amount of redundancy to the pod 210. For example, if either of the switches 350, 360 fails, the sleds in the pod 210 may still maintain data communication with the remainder of the data center 200 (e.g., sleds of other pods) through the other switch 350, 360. Furthermore, in the illustrative example, the switches 250, 350, 360 may be implemented as dual-mode optical switches, capable of routing both Ethernet protocol communications carrying Internet Protocol (IP) packets and communications according to a second, high-performance link-layer protocol (e.g., PCI Express) via optical signaling media of an optical fabric.

It should be appreciated that any one of the other pods 220, 230, 240 (as well as any additional pods of the data center 200) may be similarly structured as, and have components similar to, the pod 210 shown in and disclosed in regard to FIG. 3 (e.g., a given pod may have rows of racks housing multiple sleds as described above). Additionally, while two pod switches 350, 360 are shown, it should be understood that in other examples, a different number of pod switches may be present, providing even more failover capacity. In other examples, pods may be arranged differently than the rows-of-racks configuration shown in FIGS. 2 and 3. For example, a pod may include multiple sets of racks arranged radially, i.e., the racks are equidistant from a center switch.

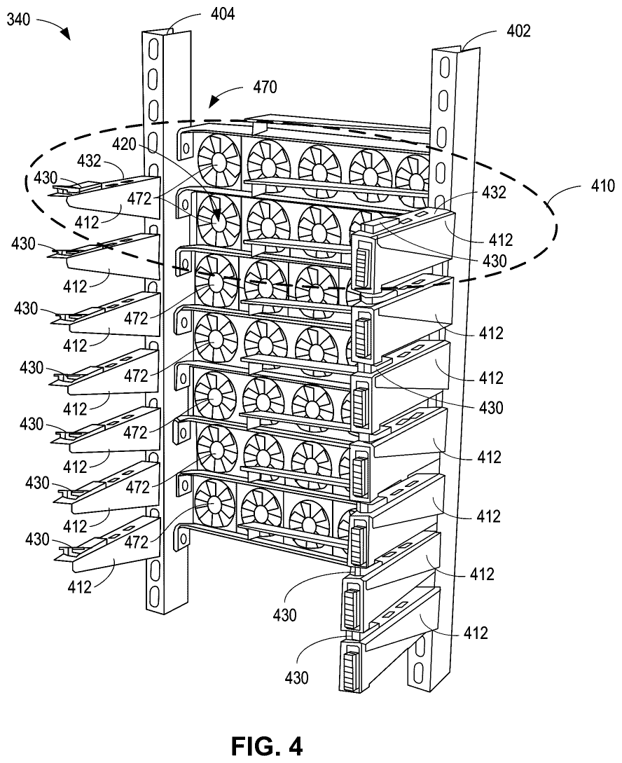

FIGS. 4-6 illustrate an example rack 340 of the data center 200. As shown in the illustrated example, the rack 340 includes two elongated support posts 402, 404, which are arranged vertically. For example, the elongated support posts 402, 404 may extend upwardly from a floor of the data center 200 when deployed. The rack 340 also includes one or more horizontal pairs 410 of elongated support arms 412 (identified in FIG. 4 via a dashed ellipse) configured to support a sled of the data center 200 as discussed below. One elongated support arm 412 of the pair of elongated support arms 412 extends outwardly from the elongated support post 402 and the other elongated support arm 412 extends outwardly from the elongated support post 404.

In the illustrative examples, at least some of the sleds of the data center 200 are chassis-less sleds. That is, such sleds have a chassis-less circuit board substrate on which physical resources (e.g., programmable circuitry, memory, accelerators, storage, etc.) are mounted as discussed in more detail below. As such, the rack 340 is configured to receive the chassis-less sleds. For example, a given pair 410 of the elongated support arms 412 defines a sled slot 420 of the rack 340, which is configured to receive a corresponding chassis-less sled. To do so, the elongated support arms 412 include corresponding circuit board guides 430 configured to receive the chassis-less circuit board substrate of the sled. The circuit board guides 430 are secured to, or otherwise mounted to, a top side 432 of the corresponding elongated support arms 412. For example, in the illustrative example, the circuit board guides 430 are mounted at a distal end of the corresponding elongated support arm 412 relative to the corresponding elongated support post 402, 404. For clarity of FIGS. 4-6, not every circuit board guide 430 may be referenced in each figure. In some examples, at least some of the sleds include a chassis and the racks 340 are suitably adapted to receive the chassis.

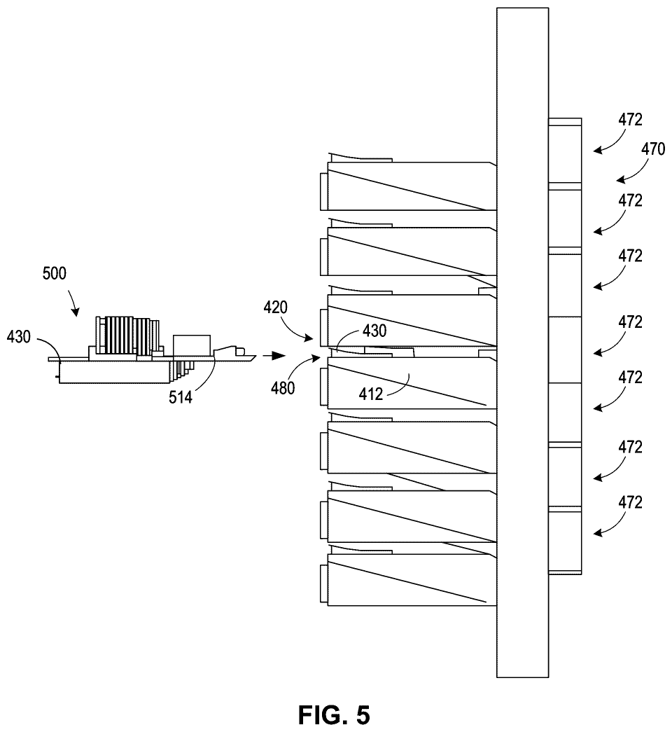

The circuit board guides 430 include an inner wall that defines a circuit board slot 480 configured to receive the chassis-less circuit board substrate of a sled 500 when the sled 500 is received in the corresponding sled slot 420 of the rack 340. To do so, as shown in FIG. 5, a user (or robot) aligns the chassis-less circuit board substrate of an illustrative chassis-less sled 500 to a sled slot 420. The user, or robot, may then slide the chassis-less circuit board substrate forward into the sled slot 420 such that each side edge 514 of the chassis-less circuit board substrate is received in a corresponding circuit board slot 480 of the circuit board guides 430 of the pair 410 of elongated support arms 412 that define the corresponding sled slot 420 as shown in FIG. 5. By having robotically accessible and robotically manipulable sleds including disaggregated resources, the different types of resource can be upgraded independently of one other and at their own optimized refresh rate. Furthermore, the sleds are configured to blindly mate with power and data communication cables in the rack 340, enhancing their ability to be quickly removed, upgraded, reinstalled, and/or replaced. As such, in some examples, the data center 200 may operate (e.g., execute workloads, undergo maintenance and/or upgrades, etc.) without human involvement on the data center floor. In other examples, a human may facilitate one or more maintenance or upgrade operations in the data center 200.

It should be appreciated that the circuit board guides 430 are dual sided. That is, a circuit board guide 430 includes an inner wall that defines a circuit board slot 480 on each side of the circuit board guide 430. In this way, the circuit board guide 430 can support a chassis-less circuit board substrate on either side. As such, a single additional elongated support post may be added to the rack 340 to turn the rack 340 into a two-rack solution that can hold twice as many sled slots 420 as shown in FIG. 4. The illustrative rack 340 includes seven pairs 410 of elongated support arms 412 that define seven corresponding sled slots 420. The sled slots 420 are configured to receive and support a corresponding sled 500 as discussed above. In other examples, the rack 340 may include additional or fewer pairs 410 of elongated support arms 412 (i.e., additional or fewer sled slots 420). It should be appreciated that because the sled 500 is chassis-less, the sled 500 may have an overall height that is different than typical servers. As such, in some examples, the height of a given sled slot 420 may be shorter than the height of a typical server (e.g., shorter than a single rank unit, referred to as “1U”). That is, the vertical distance between pairs 410 of elongated support arms 412 may be less than a standard rack unit “1U.” Additionally, due to the relative decrease in height of the sled slots 420, the overall height of the rack 340 in some examples may be shorter than the height of traditional rack enclosures. For example, in some examples, the elongated support posts 402, 404 may have a length of six feet or less. Again, in other examples, the rack 340 may have different dimensions. For example, in some examples, the vertical distance between pairs 410 of elongated support arms 412 may be greater than a standard rack unit “1U”. In such examples, the increased vertical distance between the sleds allows for larger heatsinks to be attached to the physical resources and for larger fans to be used (e.g., in the fan array 470 described below) for cooling the sleds, which in turn can allow the physical resources to operate at increased power levels. Further, it should be appreciated that the rack 340 does not include any walls, enclosures, or the like. Rather, the rack 340 is an enclosure-less rack that is opened to the local environment. In some cases, an end plate may be attached to one of the elongated support posts 402, 404 in those situations in which the rack 340 forms an end-of-row rack in the data center 200.

In some examples, various interconnects may be routed upwardly or downwardly through the elongated support posts 402, 404. To facilitate such routing, the elongated support posts 402, 404 include an inner wall that defines an inner chamber in which interconnects may be located. The interconnects routed through the elongated support posts 402, 404 may be implemented as any type of interconnects including, but not limited to, data or communication interconnects to provide communication connections to the sled slots 420, power interconnects to provide power to the sled slots 420, and/or other types of interconnects.

The rack 340, in the illustrative example, includes a support platform on which a corresponding optical data connector (not shown) is mounted. Such optical data connectors are associated with corresponding sled slots 420 and are configured to mate with optical data connectors of corresponding sleds 500 when the sleds 500 are received in the corresponding sled slots 420. In some examples, optical connections between components (e.g., sleds, racks, and switches) in the data center 200 are made with a blind mate optical connection. For example, a door on a given cable may prevent dust from contaminating the fiber inside the cable. In the process of connecting to a blind mate optical connector mechanism, the door is pushed open when the end of the cable approaches or enters the connector mechanism. Subsequently, the optical fiber inside the cable may enter a gel within the connector mechanism and the optical fiber of one cable comes into contact with the optical fiber of another cable within the gel inside the connector mechanism.

The illustrative rack 340 also includes a fan array 470 coupled to the cross-support arms of the rack 340. The fan array 470 includes one or more rows of cooling fans 472, which are aligned in a horizontal line between the elongated support posts 402, 404. In the illustrative example, the fan array 470 includes a row of cooling fans 472 for the different sled slots 420 of the rack 340. As discussed above, the sleds 500 do not include any on-board cooling system in the illustrative example and, as such, the fan array 470 provides cooling for such sleds 500 received in the rack 340. In other examples, some or all of the sleds 500 can include on-board cooling systems. Further, in some examples, the sleds 500 and/or the racks 340 may include and/or incorporate a liquid and/or immersion cooling system to facilitate cooling of electronic component(s) on the sleds 500. The rack 340, in the illustrative example, also includes different power supplies associated with different ones of the sled slots 420. A given power supply is secured to one of the elongated support arms 412 of the pair 410 of elongated support arms 412 that define the corresponding sled slot 420. For example, the rack 340 may include a power supply coupled or secured to individual ones of the elongated support arms 412 extending from the elongated support post 402. A given power supply includes a power connector configured to mate with a power connector of a sled 500 when the sled 500 is received in the corresponding sled slot 420. In the illustrative example, the sled 500 does not include any on-board power supply and, as such, the power supplies provided in the rack 340 supply power to corresponding sleds 500 when mounted to the rack 340. A given power supply is configured to satisfy the power requirements for its associated sled, which can differ from sled to sled. Additionally, the power supplies provided in the rack 340 can operate independent of each other. That is, within a single rack, a first power supply providing power to a compute sled can provide power levels that are different than power levels supplied by a second power supply providing power to an accelerator sled. The power supplies may be controllable at the sled level or rack level, and may be controlled locally by components on the associated sled or remotely, such as by another sled or an orchestrator.

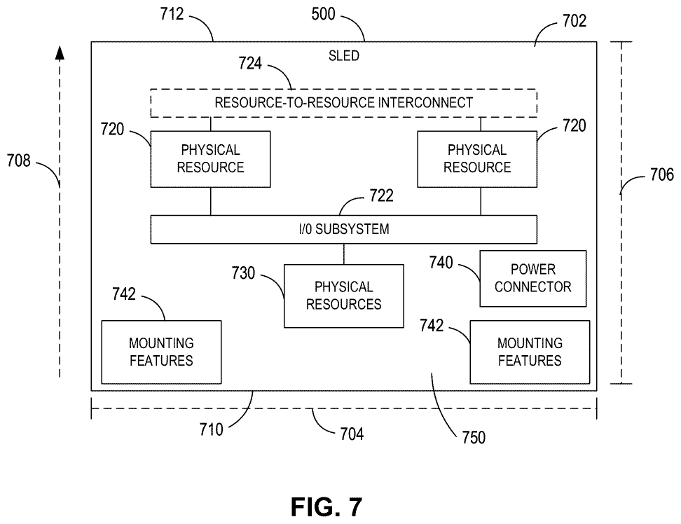

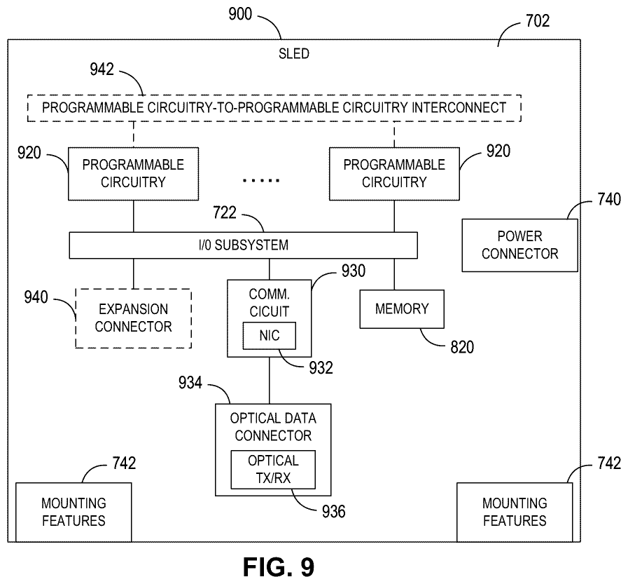

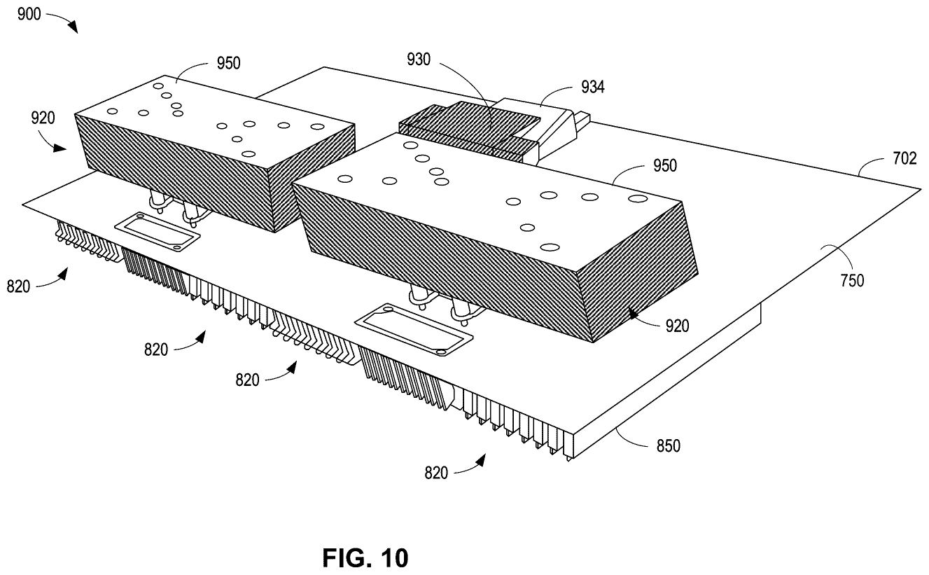

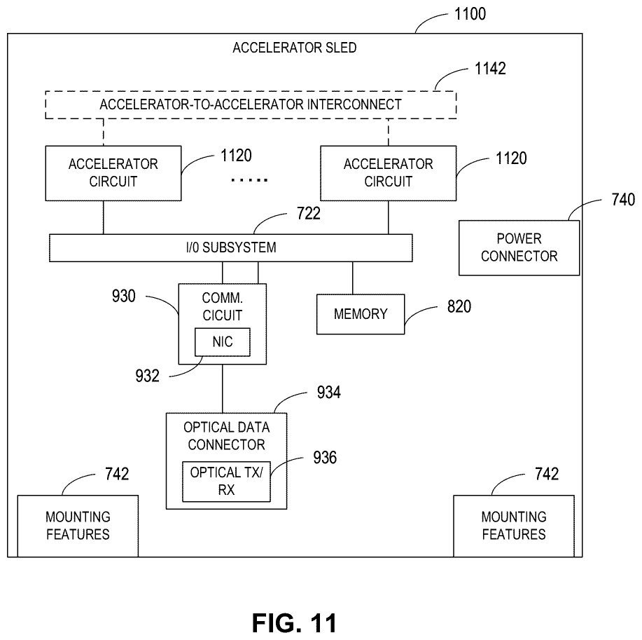

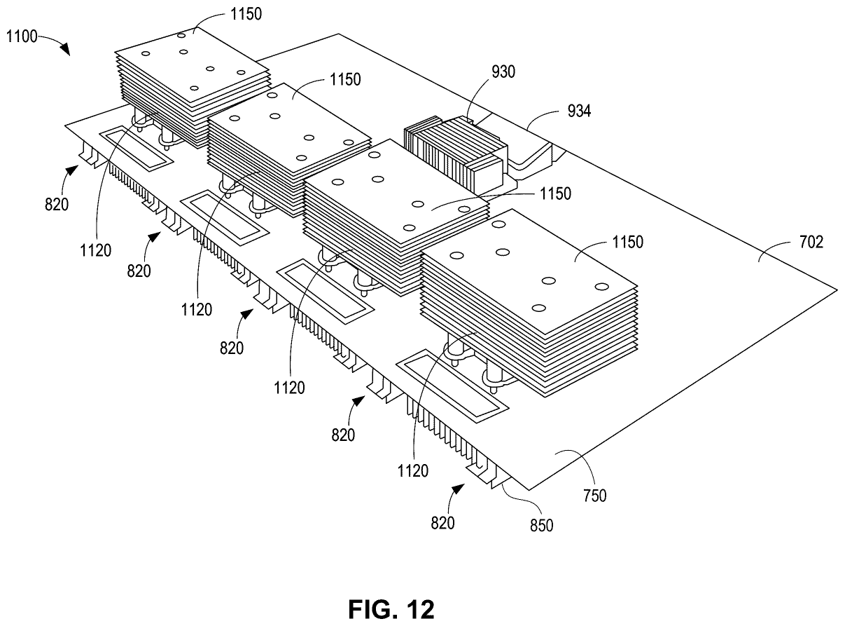

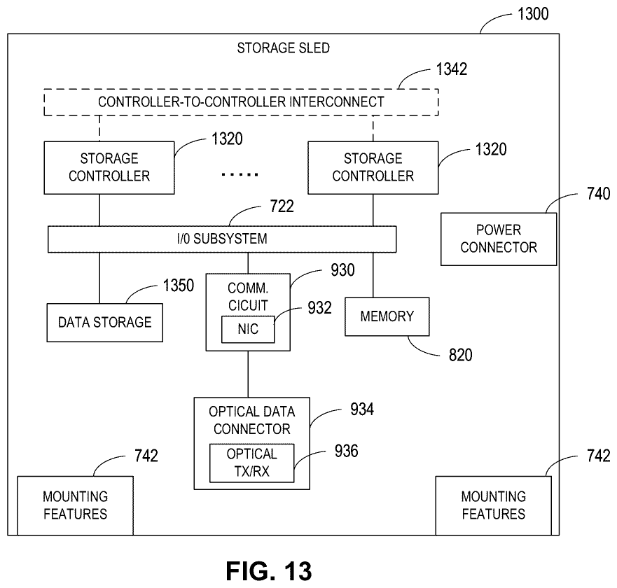

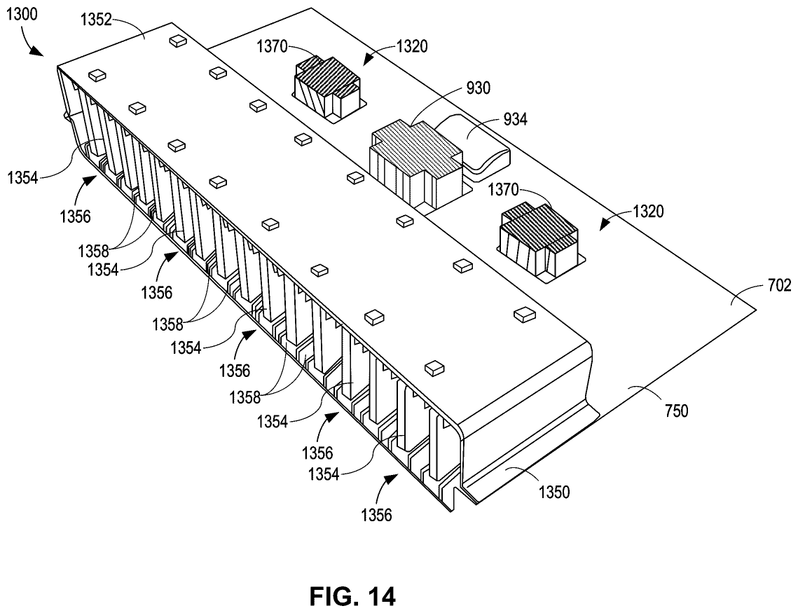

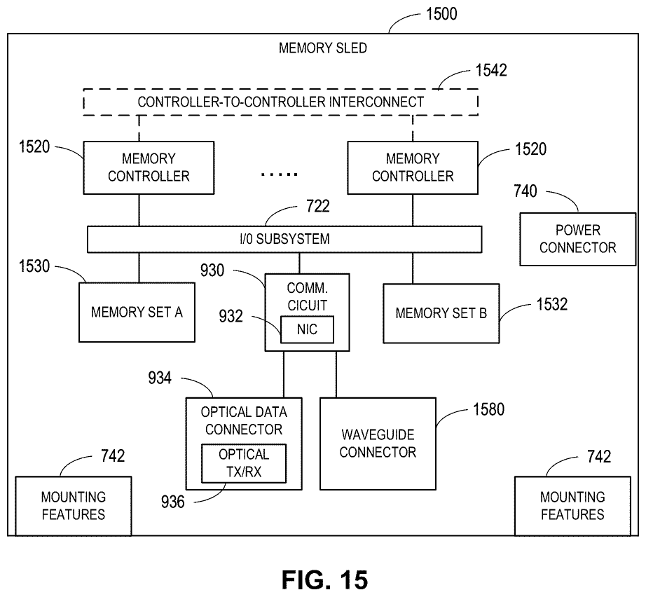

Referring now to FIG. 7, the sled 500, in the illustrative example, is configured to be mounted in a corresponding rack 340 of the data center 200 as discussed above. In some examples, a given sled 500 may be optimized or otherwise configured for performing particular tasks, such as compute tasks, acceleration tasks, data storage tasks, etc. For example, the sled 500 may be implemented as a compute sled 900 as discussed below in regard to FIGS. 9 and 10, an accelerator sled 1100 as discussed below in regard to FIGS. 11 and 12, a storage sled 1300 as discussed below in regard to FIGS. 13 and 14, or as a sled optimized or otherwise configured to perform other specialized tasks, such as a memory sled 1500, discussed below in regard to FIG. 15.

As discussed above, the illustrative sled 500 includes a chassis-less circuit board substrate 702, which supports various physical resources (e.g., electrical components) mounted thereon. It should be appreciated that the circuit board substrate 702 is “chassis-less” in that the sled 500 does not include a housing or enclosure. Rather, the chassis-less circuit board substrate 702 is open to the local environment. The chassis-less circuit board substrate 702 may be formed from any material capable of supporting the various electrical components mounted thereon. For example, in an illustrative example, the chassis-less circuit board substrate 702 is formed from an FR-4 glass-reinforced epoxy laminate material. Other materials may be used to form the chassis-less circuit board substrate 702 in other examples.

As discussed in more detail below, the chassis-less circuit board substrate 702 includes multiple features that improve the thermal cooling characteristics of the various electrical components mounted on the chassis-less circuit board substrate 702. As discussed, the chassis-less circuit board substrate 702 does not include a housing or enclosure, which may improve the airflow over the electrical components of the sled 500 by reducing those structures that may inhibit air flow. For example, because the chassis-less circuit board substrate 702 is not positioned in an individual housing or enclosure, there is no vertically-arranged backplane (e.g., a back plate of the chassis) attached to the chassis-less circuit board substrate 702, which could inhibit air flow across the electrical components. Additionally, the chassis-less circuit board substrate 702 has a geometric shape configured to reduce the length of the airflow path across the electrical components mounted to the chassis-less circuit board substrate 702. For example, the illustrative chassis-less circuit board substrate 702 has a width 704 that is greater than a depth 706 of the chassis-less circuit board substrate 702. In one particular example, the chassis-less circuit board substrate 702 has a width of about 21 inches and a depth of about 9 inches, compared to a typical server that has a width of about 17 inches and a depth of about 39 inches. As such, an airflow path 708 that extends from a front edge 710 of the chassis-less circuit board substrate 702 toward a rear edge 712 has a shorter distance relative to typical servers, which may improve the thermal cooling characteristics of the sled 500. Furthermore, although not illustrated in FIG. 7, the various physical resources mounted to the chassis-less circuit board substrate 702 in this example are mounted in corresponding locations such that no two substantively heat-producing electrical components shadow each other as discussed in more detail below. That is, no two electrical components, which produce appreciable heat during operation (i.e., greater than a nominal heat sufficient enough to adversely impact the cooling of another electrical component), are mounted to the chassis-less circuit board substrate 702 linearly in-line with each other along the direction of the airflow path 708 (i.e., along a direction extending from the front edge 710 toward the rear edge 712 of the chassis-less circuit board substrate 702). The placement and/or structure of the features may be suitable adapted when the electrical component(s) are being cooled via liquid (e.g., one phase or two phase cooling).

As discussed above, the illustrative sled 500 includes one or more physical resources 720 mounted to a top side 750 of the chassis-less circuit board substrate 702. Although two physical resources 720 are shown in FIG. 7, it should be appreciated that the sled 500 may include one, two, or more physical resources 720 in other examples. The physical resources 720 may be implemented as any type of programmable circuitry, controller, or other compute circuit capable of performing various tasks such as compute functions and/or controlling the functions of the sled 500 depending on, for example, the type or intended functionality of the sled 500. For example, as discussed in more detail below, the physical resources 720 may be implemented as high-performance processor circuitry in examples in which the sled 500 is implemented as a compute sled, as accelerator co-processor circuitry or circuits in examples in which the sled 500 is implemented as an accelerator sled, storage controllers in examples in which the sled 500 is implemented as a storage sled, or a set of memory devices in examples in which the sled 500 is implemented as a memory sled.

The sled 500 also includes one or more additional physical resources 730 mounted to the top side 750 of the chassis-less circuit board substrate 702. In the illustrative example, the additional physical resources include a network interface controller (NIC) as discussed in more detail below. Depending on the type and functionality of the sled 500, the physical resources 730 may include additional or other electrical components, circuits, and/or devices in other examples.

The physical resources 720 are communicatively coupled to the physical resources 730 via an input/output (I/O) subsystem 722. The I/O subsystem 722 may be implemented as circuitry and/or components to facilitate input/output operations with the physical resources 720, the physical resources 730, and/or other components of the sled 500. For example, the I/O subsystem 722 may be implemented as, or otherwise include, memory controller hubs, input/output control hubs, integrated sensor hubs, firmware devices, communication links (e.g., point-to-point links, bus links, wires, cables, waveguides, light guides, printed circuit board traces, etc.), and/or other components and subsystems to facilitate the input/output operations. In the illustrative example, the I/O subsystem 722 is implemented as, or otherwise includes, a double data rate 4 (DDR4) data bus or a DDR5 data bus.

In some examples, the sled 500 may also include a resource-to-resource interconnect 724. The resource-to-resource interconnect 724 may be implemented as any type of communication interconnect capable of facilitating resource-to-resource communications. In the illustrative example, the resource-to-resource interconnect 724 is implemented as a high-speed point-to-point interconnect (e.g., faster than the I/O subsystem 722). For example, the resource-to-resource interconnect 724 may be implemented as a QuickPath Interconnect (QPI), an UltraPath Interconnect (UPI), or other high-speed point-to-point interconnect dedicated to resource-to-resource communications.

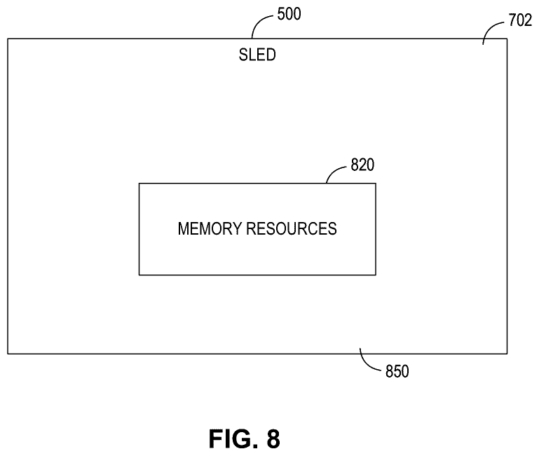

The sled 500 also includes a power connector 740 configured to mate with a corresponding power connector of the rack 340 when the sled 500 is mounted in the corresponding rack 340. The sled 500 receives power from a power supply of the rack 340 via the power connector 740 to supply power to the various electrical components of the sled 500. That is, the sled 500 does not include any local power supply (i.e., an on-board power supply) to provide power to the electrical components of the sled 500. The exclusion of a local or on-board power supply facilitates the reduction in the overall footprint of the chassis-less circuit board substrate 702, which may increase the thermal cooling characteristics of the various electrical components mounted on the chassis-less circuit board substrate 702 as discussed above. In some examples, voltage regulators are placed on a bottom side 850 (see FIG. 8) of the chassis-less circuit board substrate 702 directly opposite of programmable circuitry 920 (see FIG. 9), and power is routed from the voltage regulators to the programmable circuitry 920 by vias extending through the circuit board substrate 702. Such a configuration provides an increased thermal budget, additional current and/or voltage, and better voltage control relative to typical printed circuit boards in which processor power is delivered from a voltage regulator, in part, by printed circuit traces.

In some examples, the sled 500 may also include mounting features 742 configured to mate with a mounting arm, or other structure, of a robot to facilitate the placement of the sled 500 in a rack 340 by the robot. The mounting features 742 may be implemented as any type of physical structures that allow the robot to grasp the sled 500 without damaging the chassis-less circuit board substrate 702 or the electrical components mounted thereto. For example, in some examples, the mounting features 742 may be implemented as non-conductive pads attached to the chassis-less circuit board substrate 702. In other examples, the mounting features may be implemented as brackets, braces, or other similar structures attached to the chassis-less circuit board substrate 702. The particular number, shape, size, and/or make-up of the mounting feature 742 may depend on the design of the robot configured to manage the sled 500.

Referring now to FIG. 8, in addition to the physical resources 730 mounted on the top side 750 of the chassis-less circuit board substrate 702, the sled 500 also includes one or more memory devices 820 mounted to a bottom side 850 of the chassis-less circuit board substrate 702. That is, the chassis-less circuit board substrate 702 is implemented as a double-sided circuit board. The physical resources 720 are communicatively coupled to the memory devices 820 via the I/O subsystem 722. For example, the physical resources 720 and the memory devices 820 may be communicatively coupled by one or more vias extending through the chassis-less circuit board substrate 702. Different ones of the physical resources 720 may be communicatively coupled to different sets of one or more memory devices 820 in some examples. Alternatively, in other examples, different ones of the physical resources 720 may be communicatively coupled to the same ones of the memory devices 820.

The memory devices 820 may be implemented as any type of memory device capable of storing data for the physical resources 720 during operation of the sled 500, such as any type of volatile (e.g., dynamic random access memory (DRAM), etc.) or non-volatile memory. Volatile memory may be a storage medium that requires power to maintain the state of data stored by the medium. Non-limiting examples of volatile memory may include various types of random access memory (RAM), such as dynamic random access memory (DRAM) or static random access memory (SRAM). One particular type of DRAM that may be used in a memory module is synchronous dynamic random access memory (SDRAM). In particular examples, DRAM of a memory component may comply with a standard promulgated by JEDEC, such as JESD79F for DDR SDRAM, JESD79-2F for DDR2 SDRAM, JESD79-3F for DDR3 SDRAM, JESD79-4A for DDR4 SDRAM, JESD209 for Low Power DDR (LPDDR), JESD209-2 for LPDDR2, JESD209-3 for LPDDR3, and JESD209-4 for LPDDR4. Such standards (and similar standards) may be referred to as DDR-based standards and communication interfaces of the storage devices that implement such standards may be referred to as DDR-based interfaces.

In one example, the memory device is a block addressable memory device, such as those based on NAND or NOR technologies. A memory device may also include next-generation nonvolatile devices, such as Intel 3D XPoint™ memory or other byte addressable write-in-place nonvolatile memory devices. In one example, the memory device may be or may include memory devices that use chalcogenide glass, multi-threshold level NAND flash memory, NOR flash memory, single or multi-level Phase Change Memory (PCM), a resistive memory, nanowire memory, ferroelectric transistor random access memory (FeTRAM), anti-ferroelectric memory, magnetoresistive random access memory (MRAM) memory that incorporates memristor technology, resistive memory including the metal oxide base, the oxygen vacancy base and the conductive bridge Random Access Memory (CB-RAM), or spin transfer torque (STT)-MRAM, a spintronic magnetic junction memory based device, a magnetic tunneling junction (MTJ) based device, a DW (Domain Wall) and SOT (Spin Orbit Transfer) based device, a thyristor based memory device, or a combination of any of the above, or other memory. The memory device may refer to the die itself and/or to a packaged memory product. In some examples, the memory device may include a transistor-less stackable cross point architecture in which memory cells sit at the intersection of word lines and bit lines and are individually addressable and in which bit storage is based on a change in bulk resistance.

Referring now to FIG. 9, in some examples, the sled 500 may be implemented as a compute sled 900. The compute sled 900 is optimized, or otherwise configured, to perform compute tasks. As discussed above, the compute sled 900 may rely on other sleds, such as acceleration sleds and/or storage sleds, to perform such compute tasks. The compute sled 900 includes various physical resources (e.g., electrical components) similar to the physical resources of the sled 500, which have been identified in FIG. 9 using the same reference numbers. The description of such components provided above in regard to FIGS. 7 and 8 applies to the corresponding components of the compute sled 900 and is not repeated herein for clarity of the description of the compute sled 900.

In the illustrative compute sled 900, the physical resources 720 include programmable circuitry 920. Although only two blocks of programmable circuitry 920 are shown in FIG. 9, it should be appreciated that the compute sled 900 may include additional programmable circuits 920 in other examples. Illustratively, the programmable circuitry 920 corresponds to high-performance processor circuitry 920 and may be configured to operate at a relatively high power rating. Although the high-performance programmable circuitry 920 generates additional heat operating at power ratings greater than typical processor circuitry (which operate at around 155-230 W), the enhanced thermal cooling characteristics of the chassis-less circuit board substrate 702 discussed above facilitate the higher power operation. For example, in the illustrative example, the programmable circuitry 920 is configured to operate at a power rating of at least 250 W. In some examples, the programmable circuitry 920 may be configured to operate at a power rating of at least 350 W.

In some examples, the compute sled 900 may also include a programmable circuitry-to-programmable circuitry interconnect 942. Similar to the resource-to-resource interconnect 724 of the sled 500 discussed above, the programmable circuitry-to-programmable circuitry interconnect 942 may be implemented as any type of communication interconnect capable of facilitating programmable circuitry-to-programmable circuitry interconnect 942 communications. In the illustrative example, the programmable circuitry-to-programmable circuitry interconnect 942 is implemented as a high-speed point-to-point interconnect (e.g., faster than the I/O subsystem 722). For example, the programmable circuitry-to-programmable circuitry interconnect 942 may be implemented as a QuickPath Interconnect (QPI), an UltraPath Interconnect (UPI), or other high-speed point-to-point interconnect dedicated to programmable circuitry-to-programmable circuitry communications.

The compute sled 900 also includes a communication circuit 930. The illustrative communication circuit 930 includes a network interface controller (NIC) 932, which may also be referred to as a host fabric interface (HFI). The NIC 932 may be implemented as, or otherwise include, any type of integrated circuit, discrete circuits, controller chips, chipsets, add-in-boards, daughtercards, network interface cards, or other devices that may be used by the compute sled 900 to connect with another compute device (e.g., with other sleds 500). In some examples, the NIC 932 may be implemented as part of a system-on-a-chip (SoC) that includes one or more processor circuits, or included on a multichip package that also contains one or more processor circuits. In some examples, the NIC 932 may include a local processor circuit (not shown) and/or a local memory (not shown) that are both local to the NIC 932. In such examples, the local processor circuit of the NIC 932 may be capable of performing one or more of the functions of the programmable circuitry 920. Additionally or alternatively, in such examples, the local memory of the NIC 932 may be integrated into one or more components of the compute sled at the board level, socket level, chip level, and/or other levels.

The communication circuit 930 is communicatively coupled to an optical data connector 934. The optical data connector 934 is configured to mate with a corresponding optical data connector of the rack 340 when the compute sled 900 is mounted in the rack 340. Illustratively, the optical data connector 934 includes a plurality of optical fibers which lead from a mating surface of the optical data connector 934 to an optical transceiver 936. The optical transceiver 936 is configured to convert incoming optical signals from the rack-side optical data connector to electrical signals and to convert electrical signals to outgoing optical signals to the rack-side optical data connector. Although shown as forming part of the optical data connector 934 in the illustrative example, the optical transceiver 936 may form a portion of the communication circuit 930 in other examples.

In some examples, the compute sled 900 may also include an expansion connector 940. In such examples, the expansion connector 940 is configured to mate with a corresponding connector of an expansion chassis-less circuit board substrate to provide additional physical resources to the compute sled 900. The additional physical resources may be used, for example, by the programmable circuitry 920 during operation of the compute sled 900. The expansion chassis-less circuit board substrate may be substantially similar to the chassis-less circuit board substrate 702 discussed above and may include various electrical components mounted thereto. The particular electrical components mounted to the expansion chassis-less circuit board substrate may depend on the intended functionality of the expansion chassis-less circuit board substrate. For example, the expansion chassis-less circuit board substrate may provide additional compute resources, memory resources, and/or storage resources. As such, the additional physical resources of the expansion chassis-less circuit board substrate may include, but is not limited to, processor circuitry, memory devices, storage devices, and/or accelerator circuits including, for example, field programmable gate arrays (FPGA), application-specific integrated circuits (ASICs), security co-processor circuits, graphics processing units (GPUs), machine learning circuits, or other specialized processor circuits, controllers, devices, and/or circuits.

Referring now to FIG. 10, an illustrative example of the compute sled 900 is shown. As shown, the programmable circuitry 920, communication circuit 930, and optical data connector 934 are mounted to the top side 750 of the chassis-less circuit board substrate 702. Any suitable attachment or mounting technology may be used to mount the physical resources of the compute sled 900 to the chassis-less circuit board substrate 702. For example, the various physical resources may be mounted in corresponding sockets (e.g., a processor circuit socket), holders, or brackets. In some cases, some of the electrical components may be directly mounted to the chassis-less circuit board substrate 702 via soldering or similar techniques.

As discussed above, the separate programmable circuitry 920 and the communication circuit 930 are mounted to the top side 750 of the chassis-less circuit board substrate 702 such that no two heat-producing, electrical components shadow each other. In the illustrative example, the programmable circuitry 920 and the communication circuit 930 are mounted in corresponding locations on the top side 750 of the chassis-less circuit board substrate 702 such that no two of those physical resources are linearly in-line with others along the direction of the airflow path 708. It should be appreciated that, although the optical data connector 934 is in-line with the communication circuit 930, the optical data connector 934 produces no or nominal heat during operation.

The memory devices 820 of the compute sled 900 are mounted to the bottom side 850 of the of the chassis-less circuit board substrate 702 as discussed above in regard to the sled 500. Although mounted to the bottom side 850, the memory devices 820 are communicatively coupled to the programmable circuitry 920 located on the top side 750 via the I/O subsystem 722. Because the chassis-less circuit board substrate 702 is implemented as a double-sided circuit board, the memory devices 820 and the programmable circuitry 920 may be communicatively coupled by one or more vias, connectors, or other mechanisms extending through the chassis-less circuit board substrate 702. Different programmable circuitry 920 (e.g., different processor circuitry) may be communicatively coupled to a different set of one or more memory devices 820 in some examples. Alternatively, in other examples, different programmable circuitry 920 (e.g., different processor circuitry) may be communicatively coupled to the same ones of the memory devices 820. In some examples, the memory devices 820 may be mounted to one or more memory mezzanines on the bottom side of the chassis-less circuit board substrate 702 and may interconnect with a corresponding programmable circuitry 920 through a ball-grid array.

Different programmable circuitry 920 (e.g., different processor circuitry) include and/or is associated with corresponding heatsinks 950 secured thereto. Due to the mounting of the memory devices 820 to the bottom side 850 of the chassis-less circuit board substrate 702 (as well as the vertical spacing of the sleds 500 in the corresponding rack 340), the top side 750 of the chassis-less circuit board substrate 702 includes additional “free” area or space that facilitates the use of heatsinks 950 having a larger size relative to traditional heatsinks used in typical servers. Additionally, due to the improved thermal cooling characteristics of the chassis-less circuit board substrate 702, none of the programmable circuitry heatsinks 950 include cooling fans attached thereto. That is, the heatsinks 950 may be fan-less heatsinks. In some examples, the heatsinks 950 mounted atop the programmable circuitry 920 may overlap with the heatsink attached to the communication circuit 930 in the direction of the airflow path 708 due to their increased size, as illustratively suggested by FIG. 10.

Referring now to FIG. 11, in some examples, the sled 500 may be implemented as an accelerator sled 1100. The accelerator sled 1100 is configured, to perform specialized compute tasks, such as machine learning, encryption, hashing, or other computational-intensive task. In some examples, for example, a compute sled 900 may offload tasks to the accelerator sled 1100 during operation. The accelerator sled 1100 includes various components similar to components of the sled 500 and/or the compute sled 900, which have been identified in FIG. 11 using the same reference numbers. The description of such components provided above in regard to FIGS. 7, 8, and 9 apply to the corresponding components of the accelerator sled 1100 and is not repeated herein for clarity of the description of the accelerator sled 1100.

In the illustrative accelerator sled 1100, the physical resources 720 include accelerator circuits 1120. Although only two accelerator circuits 1120 are shown in FIG. 11, it should be appreciated that the accelerator sled 1100 may include additional accelerator circuits 1120 in other examples. For example, as shown in FIG. 12, the accelerator sled 1100 may include four accelerator circuits 1120. The accelerator circuits 1120 may be implemented as any type of processor circuitry, co-processor circuitry, compute circuit, or other device capable of performing compute or processing operations. For example, the accelerator circuits 1120 may be implemented as, for example, field programmable gate arrays (FPGA), application-specific integrated circuits (ASICs), security co-processor circuitry, graphics processing units (GPUs), neuromorphic processor units, quantum computers, machine learning circuits, or other specialized processor circuitry, controllers, devices, and/or circuits.

In some examples, the accelerator sled 1100 may also include an accelerator-to-accelerator interconnect 1142. Similar to the resource-to-resource interconnect 724 of the sled 500 discussed above, the accelerator-to-accelerator interconnect 1142 may be implemented as any type of communication interconnect capable of facilitating accelerator-to-accelerator communications. In the illustrative example, the accelerator-to-accelerator interconnect 1142 is implemented as a high-speed point-to-point interconnect (e.g., faster than the I/O subsystem 722). For example, the accelerator-to-accelerator interconnect 1142 may be implemented as a QuickPath Interconnect (QPI), an UltraPath Interconnect (UPI), or other high-speed point-to-point interconnect dedicated to programmable circuitry-to-programmable circuitry communications. In some examples, the accelerator circuits 1120 may be daisy-chained with a primary accelerator circuit 1120 connected to the NIC 932 and memory 820 through the I/O subsystem 722 and a secondary accelerator circuit 1120 connected to the NIC 932 and memory 820 through a primary accelerator circuit 1120.

Referring now to FIG. 12, an illustrative example of the accelerator sled 1100 is shown. As discussed above, the accelerator circuits 1120, the communication circuit 930, and the optical data connector 934 are mounted to the top side 750 of the chassis-less circuit board substrate 702. Again, the individual accelerator circuits 1120 and communication circuit 930 are mounted to the top side 750 of the chassis-less circuit board substrate 702 such that no two heat-producing, electrical components shadow each other as discussed above. The memory devices 820 of the accelerator sled 1100 are mounted to the bottom side 850 of the of the chassis-less circuit board substrate 702 as discussed above in regard to the sled 500. Although mounted to the bottom side 850, the memory devices 820 are communicatively coupled to the accelerator circuits 1120 located on the top side 750 via the I/O subsystem 722 (e.g., through vias). Further, the accelerator circuits 1120 may include and/or be associated with a heatsink 1150 that is larger than a traditional heatsink used in a server. As discussed above with reference to the heatsinks 950 of FIG. 9, the heatsinks 1150 may be larger than traditional heatsinks because of the “free” area provided by the memory resources 820 being located on the bottom side 850 of the chassis-less circuit board substrate 702 rather than on the top side 750.

Referring now to FIG. 13, in some examples, the sled 500 may be implemented as a storage sled 1300. The storage sled 1300 is configured, to store data in a data storage 1350 local to the storage sled 1300. For example, during operation, a compute sled 900 or an accelerator sled 1100 may store and retrieve data from the data storage 1350 of the storage sled 1300. The storage sled 1300 includes various components similar to components of the sled 500 and/or the compute sled 900, which have been identified in FIG. 13 using the same reference numbers. The description of such components provided above in regard to FIGS. 7, 8, and 9 apply to the corresponding components of the storage sled 1300 and is not repeated herein for clarity of the description of the storage sled 1300.

In the illustrative storage sled 1300, the physical resources 720 includes storage controllers 1320. Although only two storage controllers 1320 are shown in FIG. 13, it should be appreciated that the storage sled 1300 may include additional storage controllers 1320 in other examples. The storage controllers 1320 may be implemented as any type of programmable circuitry, controller, or control circuit capable of controlling the storage and retrieval of data into the data storage 1350 based on requests received via the communication circuit 930. In the illustrative example, the storage controllers 1320 are implemented as relatively low-power programmable circuitry or controllers. For example, in some examples, the storage controllers 1320 may be configured to operate at a power rating of about 75 watts.

In some examples, the storage sled 1300 may also include a controller-to-controller interconnect 1342. Similar to the resource-to-resource interconnect 724 of the sled 500 discussed above, the controller-to-controller interconnect 1342 may be implemented as any type of communication interconnect capable of facilitating controller-to-controller communications. In the illustrative example, the controller-to-controller interconnect 1342 is implemented as a high-speed point-to-point interconnect (e.g., faster than the I/O subsystem 722). For example, the controller-to-controller interconnect 1342 may be implemented as a QuickPath Interconnect (QPI), an UltraPath Interconnect (UPI), or other high-speed point-to-point interconnect dedicated to programmable circuitry-to-programmable circuitry communications.

Referring now to FIG. 14, an illustrative example of the storage sled 1300 is shown. In the illustrative example, the data storage 1350 is implemented as, or otherwise includes, a storage cage 1352 configured to house one or more solid state drives (SSDs) 1354. To do so, the storage cage 1352 includes a number of mounting slots 1356, which are configured to receive corresponding solid state drives 1354. The mounting slots 1356 include a number of drive guides 1358 that cooperate to define an access opening of the corresponding mounting slot 1356. The storage cage 1352 is secured to the chassis-less circuit board substrate 702 such that the access openings face away from (i.e., toward the front of) the chassis-less circuit board substrate 702. As such, solid state drives 1354 are accessible while the storage sled 1300 is mounted in a corresponding rack 340. For example, a solid state drive 1354 may be swapped out of a rack 340 (e.g., via a robot) while the storage sled 1300 remains mounted in the corresponding rack 340.

The storage cage 1352 illustratively includes sixteen mounting slots 1356 and is capable of mounting and storing sixteen solid state drives 1354. The storage cage 1352 may be configured to store additional or fewer solid state drives 1354 in other examples. Additionally, in the illustrative example, the solid state drives are mounted vertically in the storage cage 1352, but may be mounted in the storage cage 1352 in a different orientation in other examples. A given solid state drive 1354 may be implemented as any type of data storage device capable of storing long term data. To do so, the solid state drives 1354 may include volatile and non-volatile memory devices discussed above.

As shown in FIG. 14, the storage controllers 1320, the communication circuit 930, and the optical data connector 934 are illustratively mounted to the top side 750 of the chassis-less circuit board substrate 702. Again, as discussed above, any suitable attachment or mounting technology may be used to mount the electrical components of the storage sled 1300 to the chassis-less circuit board substrate 702 including, for example, sockets (e.g., a processor circuit socket), holders, brackets, soldered connections, and/or other mounting or securing techniques.

As discussed above, the individual storage controllers 1320 and the communication circuit 930 are mounted to the top side 750 of the chassis-less circuit board substrate 702 such that no two heat-producing, electrical components shadow each other. For example, the storage controllers 1320 and the communication circuit 930 are mounted in corresponding locations on the top side 750 of the chassis-less circuit board substrate 702 such that no two of those electrical components are linearly in-line with each other along the direction of the airflow path 708.

The memory devices 820 (not shown in FIG. 14) of the storage sled 1300 are mounted to the bottom side 850 (not shown in FIG. 14) of the chassis-less circuit board substrate 702 as discussed above in regard to the sled 500. Although mounted to the bottom side 850, the memory devices 820 are communicatively coupled to the storage controllers 1320 located on the top side 750 via the I/O subsystem 722. Again, because the chassis-less circuit board substrate 702 is implemented as a double-sided circuit board, the memory devices 820 and the storage controllers 1320 may be communicatively coupled by one or more vias, connectors, or other mechanisms extending through the chassis-less circuit board substrate 702. The storage controllers 1320 include and/or are associated with a heatsink 1370 secured thereto. As discussed above, due to the improved thermal cooling characteristics of the chassis-less circuit board substrate 702 of the storage sled 1300, none of the heatsinks 1370 include cooling fans attached thereto. That is, the heatsinks 1370 may be fan-less heatsinks.

Referring now to FIG. 15, in some examples, the sled 500 may be implemented as a memory sled 1500. The storage sled 1500 is optimized, or otherwise configured, to provide other sleds 500 (e.g., compute sleds 900, accelerator sleds 1100, etc.) with access to a pool of memory (e.g., in two or more sets 1530, 1532 of memory devices 820) local to the memory sled 1300. For example, during operation, a compute sled 900 or an accelerator sled 1100 may remotely write to and/or read from one or more of the memory sets 1530, 1532 of the memory sled 1300 using a logical address space that maps to physical addresses in the memory sets 1530, 1532. The memory sled 1500 includes various components similar to components of the sled 500 and/or the compute sled 900, which have been identified in FIG. 15 using the same reference numbers. The description of such components provided above in regard to FIGS. 7, 8, and 9 apply to the corresponding components of the memory sled 1500 and is not repeated herein for clarity of the description of the memory sled 1500.

In the illustrative memory sled 1500, the physical resources 720 include memory controllers 1520. Although only two memory controllers 1520 are shown in FIG. 15, it should be appreciated that the memory sled 1500 may include additional memory controllers 1520 in other examples. The memory controllers 1520 may be implemented as any type of programmable circuitry, controller, or control circuit capable of controlling the writing and reading of data into the memory sets 1530, 1532 based on requests received via the communication circuit 930. In the illustrative example, the memory controllers 1520 are connected to corresponding memory sets 1530, 1532 to write to and read from memory devices 820 (not shown) within the corresponding memory set 1530, 1532 and enforce any permissions (e.g., read, write, etc.) associated with sled 500 that has sent a request to the memory sled 1500 to perform a memory access operation (e.g., read or write).

In some examples, the memory sled 1500 may also include a controller-to-controller interconnect 1542. Similar to the resource-to-resource interconnect 724 of the sled 500 discussed above, the controller-to-controller interconnect 1542 may be implemented as any type of communication interconnect capable of facilitating controller-to-controller communications. In the illustrative example, the controller-to-controller interconnect 1542 is implemented as a high-speed point-to-point interconnect (e.g., faster than the I/O subsystem 722). For example, the controller-to-controller interconnect 1542 may be implemented as a QuickPath Interconnect (QPI), an UltraPath Interconnect (UPI), or other high-speed point-to-point interconnect dedicated to programmable circuitry-to-programmable circuitry communications. As such, in some examples, a memory controller 1520 may access, through the controller-to-controller interconnect 1542, memory that is within the memory set 1532 associated with another memory controller 1520. In some examples, a scalable memory controller is made of multiple smaller memory controllers, referred to herein as “chiplets”, on a memory sled (e.g., the memory sled 1500). The chiplets may be interconnected (e.g., using EMIB (Embedded Multi-Die Interconnect Bridge) technology). The combined chiplet memory controller may scale up to a relatively large number of memory controllers and I/O ports, (e.g., up to 16 memory channels). In some examples, the memory controllers 1520 may implement a memory interleave (e.g., one memory address is mapped to the memory set 1530, the next memory address is mapped to the memory set 1532, and the third address is mapped to the memory set 1530, etc.). The interleaving may be managed within the memory controllers 1520, or from CPU sockets (e.g., of the compute sled 900) across network links to the memory sets 1530, 1532, and may improve the latency associated with performing memory access operations as compared to accessing contiguous memory addresses from the same memory device.

Further, in some examples, the memory sled 1500 may be connected to one or more other sleds 500 (e.g., in the same rack 340 or an adjacent rack 340) through a waveguide, using the waveguide connector 1580. In the illustrative example, the waveguides are 74 millimeter waveguides that provide 16 Rx (i.e., receive) lanes and 16 Tx (i.e., transmit) lanes. Different ones of the lanes, in the illustrative example, are either 16 GHz or 32 GHz. In other examples, the frequencies may be different. Using a waveguide may provide high throughput access to the memory pool (e.g., the memory sets 1530, 1532) to another sled (e.g., a sled 500 in the same rack 340 or an adjacent rack 340 as the memory sled 1500) without adding to the load on the optical data connector 934.

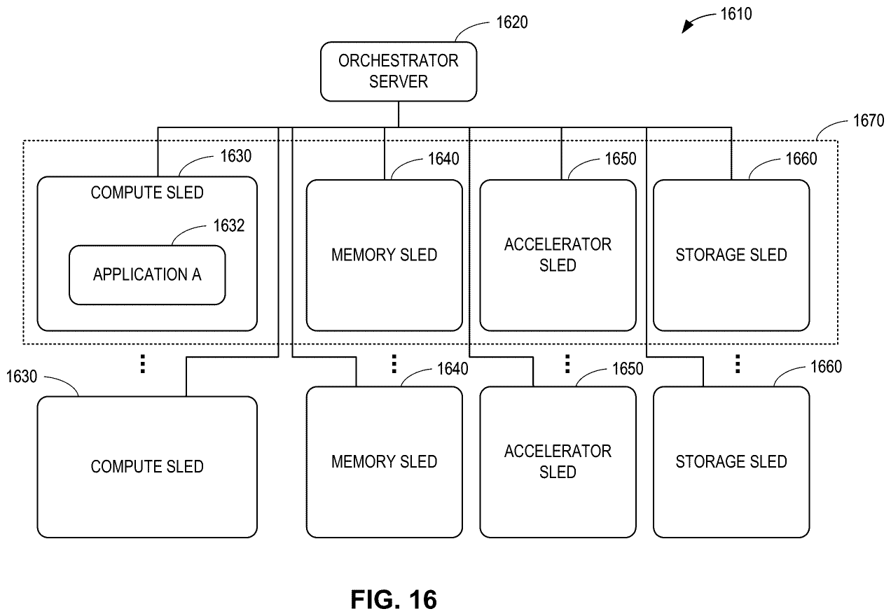

Referring now to FIG. 16, a system for executing one or more workloads (e.g., applications) may be implemented in accordance with the data center 200. In the illustrative example, the system 1610 includes an orchestrator server 1620, which may be implemented as a managed node including a compute device (e.g., programmable circuitry 920 on a compute sled 900) executing management software (e.g., a cloud operating environment, such as OpenStack) that is communicatively coupled to multiple sleds 500 including a large number of compute sleds 1630 (e.g., similar to the compute sled 900), memory sleds 1640 (e.g., similar to the memory sled 1500), accelerator sleds 1650 (e.g., similar to the memory sled 1500), and storage sleds 1660 (e.g., similar to the storage sled 1300). One or more of the sleds 1630, 1640, 1650, 1660 may be grouped into a managed node 1670, such as by the orchestrator server 1620, to collectively perform a workload (e.g., an application 1632 executed in a virtual machine or in a container). The managed node 1670 may be implemented as an assembly of physical resources 720, such as programmable circuitry 920, memory resources 820, accelerator circuits 1120, or data storage 1350, from the same or different sleds 500. Further, the managed node may be established, defined, or “spun up” by the orchestrator server 1620 at the time a workload is to be assigned to the managed node or at any other time, and may exist regardless of whether any workloads are presently assigned to the managed node. In the illustrative example, the orchestrator server 1620 may selectively allocate and/or deallocate physical resources 720 from the sleds 500 and/or add or remove one or more sleds 500 from the managed node 1670 as a function of quality of service (QoS) targets (e.g., a target throughput, a target latency, a target number of instructions per second, etc.) associated with a service level agreement for the workload (e.g., the application 1632). In doing so, the orchestrator server 1620 may receive telemetry data indicative of performance conditions (e.g., throughput, latency, instructions per second, etc.) in different ones of the sleds 500 of the managed node 1670 and compare the telemetry data to the quality of service targets to determine whether the quality of service targets are being satisfied. The orchestrator server 1620 may additionally determine whether one or more physical resources may be deallocated from the managed node 1670 while still satisfying the QoS targets, thereby freeing up those physical resources for use in another managed node (e.g., to execute a different workload). Alternatively, if the QoS targets are not presently satisfied, the orchestrator server 1620 may determine to dynamically allocate additional physical resources to assist in the execution of the workload (e.g., the application 1632) while the workload is executing. Similarly, the orchestrator server 1620 may determine to dynamically deallocate physical resources from a managed node if the orchestrator server 1620 determines that deallocating the physical resource would result in QoS targets still being met.

Additionally, in some examples, the orchestrator server 1620 may identify trends in the resource utilization of the workload (e.g., the application 1632), such as by identifying phases of execution (e.g., time periods in which different operations, having different resource utilizations characteristics, are performed) of the workload (e.g., the application 1632) and pre-emptively identifying available resources in the data center 200 and allocating them to the managed node 1670 (e.g., within a predefined time period of the associated phase beginning). In some examples, the orchestrator server 1620 may model performance based on various latencies and a distribution scheme to place workloads among compute sleds and other resources (e.g., accelerator sleds, memory sleds, storage sleds) in the data center 200. For example, the orchestrator server 1620 may utilize a model that accounts for the performance of resources on the sleds 500 (e.g., FPGA performance, memory access latency, etc.) and the performance (e.g., congestion, latency, bandwidth) of the path through the network to the resource (e.g., FPGA). As such, the orchestrator server 1620 may determine which resource(s) should be used with which workloads based on the total latency associated with different potential resource(s) available in the data center 200 (e.g., the latency associated with the performance of the resource itself in addition to the latency associated with the path through the network between the compute sled executing the workload and the sled 500 on which the resource is located).

In some examples, the orchestrator server 1620 may generate a map of heat generation in the data center 200 using telemetry data (e.g., temperatures, fan speeds, etc.) reported from the sleds 500 and allocate resources to managed nodes as a function of the map of heat generation and predicted heat generation associated with different workloads, to maintain a target temperature and heat distribution in the data center 200. Additionally or alternatively, in some examples, the orchestrator server 1620 may organize received telemetry data into a hierarchical model that is indicative of a relationship between the managed nodes (e.g., a spatial relationship such as the physical locations of the resources of the managed nodes within the data center 200 and/or a functional relationship, such as groupings of the managed nodes by the customers the managed nodes provide services for, the types of functions typically performed by the managed nodes, managed nodes that typically share or exchange workloads among each other, etc.). Based on differences in the physical locations and resources in the managed nodes, a given workload may exhibit different resource utilizations (e.g., cause a different internal temperature, use a different percentage of programmable circuitry or memory capacity) across the resources of different managed nodes. The orchestrator server 1620 may determine the differences based on the telemetry data stored in the hierarchical model and factor the differences into a prediction of future resource utilization of a workload if the workload is reassigned from one managed node to another managed node, to accurately balance resource utilization in the data center 200. In some examples, the orchestrator server 1620 may identify patterns in resource utilization phases of the workloads and use the patterns to predict future resource utilization of the workloads.

To reduce the computational load on the orchestrator server 1620 and the data transfer load on the network, in some examples, the orchestrator server 1620 may send self-test information to the sleds 500 to enable a given sled 500 to locally (e.g., on the sled 500) determine whether telemetry data generated by the sled 500 satisfies one or more conditions (e.g., an available capacity that satisfies a predefined threshold, a temperature that satisfies a predefined threshold, etc.). The given sled 500 may then report back a simplified result (e.g., yes or no) to the orchestrator server 1620, which the orchestrator server 1620 may utilize in determining the allocation of resources to managed nodes.

FIG. 17A is a block diagram of an example tank 1700 having an example first coolant pathway arrangement 1701 in accordance with teachings of this disclosure. In the illustrated example of FIG. 17A, the tank 1700 includes an example coolant 1702 and an example chassis 1704. In the illustrated example of FIG. 17A, the chassis 1704 includes an example first compute unit 1706A, an example second compute unit 1706B, an example third compute unit 1706C, an example fourth compute unit 1706D, an example first duct 1708A, and an example second duct 1708B. The tank 1700 includes an example first duct inlet 1710A, an example second duct inlet 1710B, an example first outlet 1712A, and an example second outlet 1712B. In the illustrated example of FIG. 17A, the duct 1708A defines an example first duct coolant pathway 1714A between the first duct inlet 1710A and an example first duct outlet 1716A. The duct 1708B defines an example second duct coolant pathway 1714B between the second duct inlet 1710B and an example second duct outlet 1716B. As used herein, the phrase “coolant pathway arrangement” refers to the configuration of coolant pathways within an immersion cooling tank. The term “flow path architecture” is used interchangeably with the term “coolant pathway arrangement.”

The example tank 1700 of FIG. 17A is a single-phase immersion cooling tank. In the illustrated example of FIG. 17A, the coolant 1702 enters the tank 1700 via an inlet, flows into the ducts 1708A, 1708B via the duct inlets 1710A, 1710B, and then flows along the duct coolant pathways 1714A, 1714B to the duct outlets 1716A, 1716B. After exiting the duct outlets 1716A, 1716B, the coolant 1702 flows to the outlets 1712A, 1712B via example tank coolant pathways 1717. During operation of the tank 1700, the coolant 1702 enters and leaves the tank 1700 (e.g., via natural flow, via one or more pump(s) of a coolant distribution unit (CDU), etc.) at a constant and equal or substantially constant and equal rate, thereby maintaining the coolant 1702 at a constant or substantially constant level in the tank 1700.

The chassis 1704 is disposed in (e.g., supported by, coupled within) the tank 1700. The chassis 1704 includes (e.g., carries, supports, etc.) the compute units 1706A, 1706B, 1706C, 1706D and other compute components (e.g., power supplies, permanent memory, temporary memory, etc.). The chassis 1704 can include additional or fewer compute components and/or types of compute components than the example shown in FIG. 17A (and FIG. 17B discussed below). In the illustrated example of FIG. 17A, compute components are arranged in the chassis 1704 in a shadowed form factor (e.g., the first compute unit 1706A and the second compute unit 1706B are disposed in sequence along the first duct coolant pathway 1714A, the third compute unit 1706C and the fourth compute unit 1706D are disposed in sequence along the second duct coolant pathway 1714B, etc.). In other examples, the compute units 1706A, 1706B, 1706C, 1706D of the chassis 1704 can have any suitable orientation(s)/layout(s)/form factor(s) (e.g., spreadcore, etc.). Operation of the compute components of the chassis 1704 generates heat, which is absorbed and dissipated via the circulation of the coolant 1702 through the tank 1700 and the ducts 1708A, 1708B. The tank 1700 can include additional chassis disposed in parallel to the chassis 1704. The additional chassis can include ducts similar to the ducts 1708A, 1708B and support compute components that are similarly cooled via the circulation of the coolant through the tank 1700.

In the example orientation shown in FIG. 17A, the first duct 1708A is disposed over (e.g., overlays, extends along) the first compute unit 1706A and the second compute unit 1706B. In the illustrated example of FIG. 17B, the second duct 1708B is disposed over (e.g., overlays, extends along) the third compute unit 1706C and the fourth compute unit 1706D. In the illustrated example of FIG. 17A, the coolant 1702 enters the tank 1700 via the duct inlets 1710A, 1710B and flows through the ducts 1708A, 1708B via the duct coolant pathways 1714A, 1714B and over the compute units 1706A, 1706B, 1706C, 1706D. In the coolant pathway arrangement 1701 and in the orientation shown in FIG. 17A, the duct coolant pathways 1714A, 1714B extend from a bottom of the tank 1700 to the top of the tank 1700. Also, in the illustrated example shown in FIG. 17A, the coolant pathway arrangement 1701 includes the tank coolant pathways 1717, which extend from the top of the tank 1700 to the bottom of the tank 1700. That is, the duct coolant pathways 1714A, 1714B and the tank coolant pathways 1717 are disposed in opposite directions (e.g., reverse directions, etc.).

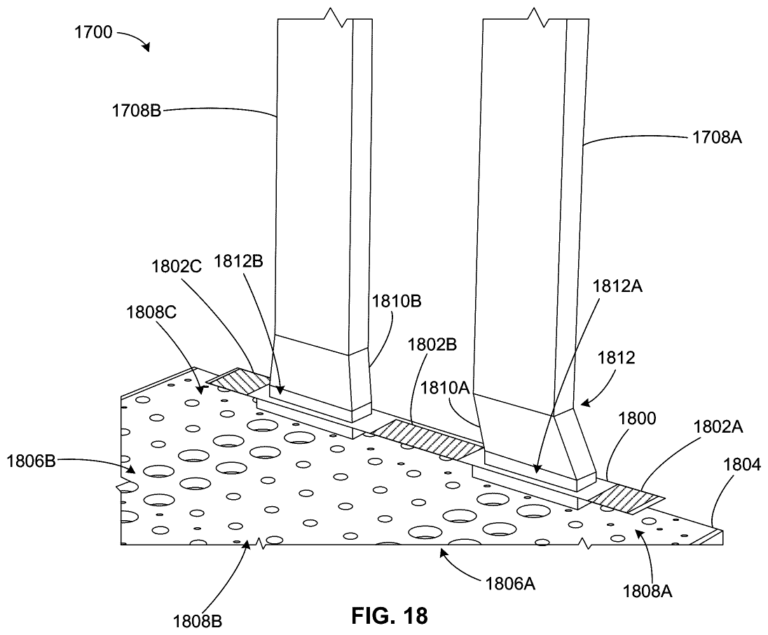

The ducts 1708A, 1708B and the coolant pathway arrangement 1701 enable a comparatively larger portion of the coolant 1702 to flow over the compute units 1706A, 1706B, 1706C, 1706D when compared to, for instance, flow paths where the ducts 1708A, 1708B are absent. That is, the ducts 1708A, 1708B direct all or substantially all of the fresh coolant (e.g., the comparatively cold coolant, etc.) over the compute units 1706A, 1706B, 1706C, 1706D. In some known examples, the impedance of the heat sinks associated with the compute units 1706A, 1706B, 1706C, 1706D (e.g., caused by fins and other high surface area structures, etc.) reduces the amount of coolant that flows over the compute units 1706A, 1706B, 1706C, 1706D. Conversely, in the example of FIG. 17A, the ducts 1708A, 1708B increase the local flow rate of the coolant 1702 over the compute units 1706A, 1706B, 1706C, 1706D. As such, the ducts 1708A, 1708B improve the efficiency of the convection cooling of the compute units 1706A, 1706B, 1706C, 1706D by the coolant 1702. The ducts 1708A, 1708B are discussed below in additional detail in conjunction with FIGS. 18-20C.

FIG. 17B is a block diagram of an example immersion tank 1703 having an example second coolant pathway arrangement 1719 including the ducts 1708A, 1708B of FIG. 17A. The immersion tank 1703 is similar to the tank 1700 of FIG. 17A except that the immersion tank 1703 includes an example first main inlet 1720A, an example second main inlet 1720B, an example third main inlet 1720C, an example first outlet 1722A, and an example second outlet 1722B. In the illustrated example of FIG. 17B, the immersion tank 1703 includes the chassis 1704 of FIG. 17A, the compute units 1706A, 1706B, 1706C, 1706D of FIG. 17A, the ducts 1708A, 1708B of FIG. 17A, and the duct inlets 1710A, 1710B of FIG. 17A.

Like the coolant pathway arrangement 1701 of FIG. 17A, in the second coolant pathway arrangement 1719 of FIG. 17B, the coolant 1702 enters the tank 1703 via the duct inlets 1710A, 1710B and flows through the ducts 1708A, 1708B via the duct coolant pathways 1714A, 1714B and over the compute units 1706A, 1706B, 1706C, 1706D. Additionally, in the second coolant pathway arrangement 1719 of FIG. 17B, the coolant also enters the tank 1703 via the inlets 1720A, 1720B, 1720C and flows along one or more example main coolant pathways 1723 over the other components of the chassis 1704. The coolant 1702 flowing along the duct coolant pathways 1714A, 1714B and the main coolant pathways 1723 and exits the tank 1700 via the outlets 1722A, 1722B. In some examples, the portion (e.g., the mass flow rate, etc.) of the coolant flowing along the duct coolant pathways 1714A, 1714B and the main coolant pathways 1723 can be controlled based on the comparative widths of the duct inlets 1710A, 1710B and the inlets 1720A, 1720B, 1720C. For example, 70% of the coolant 1702 can be directed through the ducts 1708A, 1708B (e.g., 35% through each of the ducts 1708A, 1708B, etc.) and over the compute units 1706A, 1706B, 1706C, 1706D via the duct coolant pathways 1714A, 1714B and 30% can be directed over the other components of the chassis 1704 via the main coolant pathways 1723.

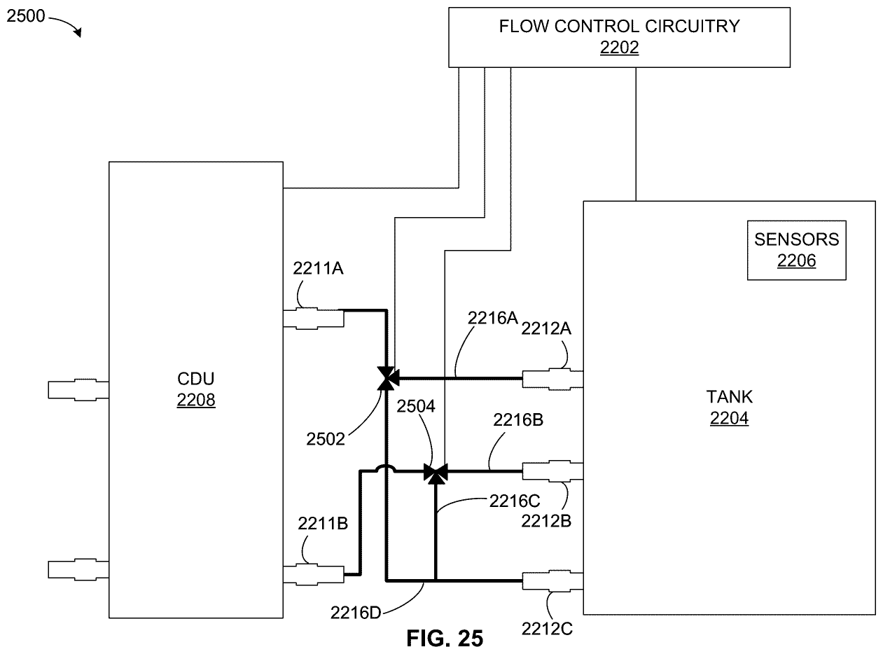

The portions of the coolant flowing through the duct coolant pathways 1714A, 1714B and the main coolant pathways 1723 can be regulated via the operation of one or more valves. Example systems including flow control immersion cooling tanks having ducts similar to the ducts 1708A, 1708B and flow control valves are disclosed below in conjunction with FIGS. 22 and 25. In the second coolant pathway arrangement 1719 and in the orientation shown in FIG. 17B, the duct coolant pathways 1714A, 1714B flow from a bottom of the tank 1700 to the top of the tank 1700 and the main coolant pathways 1723 extends from the bottom of the tank 1700 to the top of the tank 1700. That is, the duct coolant pathways 1714A, 1714B and the main coolant pathways 1723 are disposed in parallel directions.

FIG. 18 is a perspective view of the example ducts 1708A, 1708B of FIGS. 17A and 17B. In the illustrated example of FIG. 18, the duct 1708A, 1708B are coupled to an example back plate 1800 that includes an example first opening 1802A, an example second opening 1802B, and an example third opening 1802C. In the illustrated example of FIG. 18, a second plate, or a bottom plate 1804 includes example first holes 1806A, example second holes 1806B, example third holes 1808A, example fourth holes 1808B, and example fifth holes 1808C.

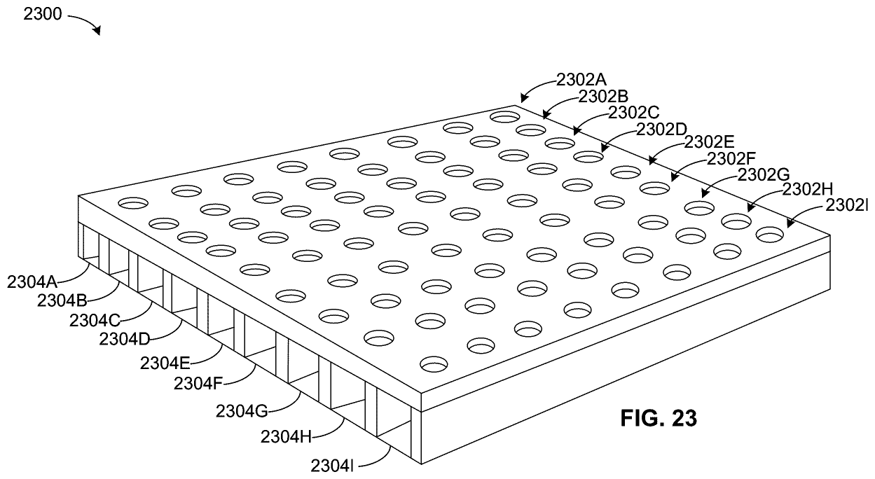

The bottom plate 1804 is a component of a cooling tank (e.g., the tank 1700, 1703 of FIGS. 17A and 17B, etc.) that is disposed between an inlet and/outlet of the tank (e.g., a junction of the tank 1700, 1703, etc.) and the chassis of the tank. In the illustrated example of FIG. 18, the holes 1806A, 1806B, 1808A, 1808B, 1808C of the bottom plate 1804 control the flow of coolant through the tank and/or the ducts 1708A, 1708B. For example, in some coolant pathway arrangements, such as the second coolant pathway arrangement 1719 of FIG. 17B, the relative sizes of the holes 1806A, 1806B, 1808A, 1808B, 1808C can control the relative amounts of the coolant flowing through the main coolant pathways 1723 through the tank and the ducts 1708A, 1708B. In the illustrated example, the holes 1806A, 1806B, which are aligned with the ducts 1708A, 1708B, respectively, are larger than the holes 1808A, 1808B, 1808B, which are aligned with the openings 1802A, 1802B, 1802C, respectively. In the illustrated example of FIG. 18, the larger size of the holes 1806A, 1806B (e.g., the larger combined area of the holes 1806A, 1806B, etc.) when compared to the smaller size of the holes 1808A, 1808B, 1808C (e.g., the smaller combined area of the holes 1808A, 1808B, 1808C, etc.) causes a larger amount of the fluid to flow through the ducts 1708A, 1708B than through the other portions of the tank 1700. In other examples, the holes 1806A, 1806B, 1808A, 1808B, 1808C can have different size(s), including a same size. Another example plate (e.g., a bottom plate) that can be used in conjunction with the examples of this disclosure is discussed below in conjunction with FIG. 23. Additionally or alternatively, the relative portions of coolant flowing through the ducts 1708A, 1708B and flowing externally to the ducts can be controlled by one or more valves associated with the tank 1700. Example system including such valves are disclosed below in conjunction with FIGS. 22 and 25.

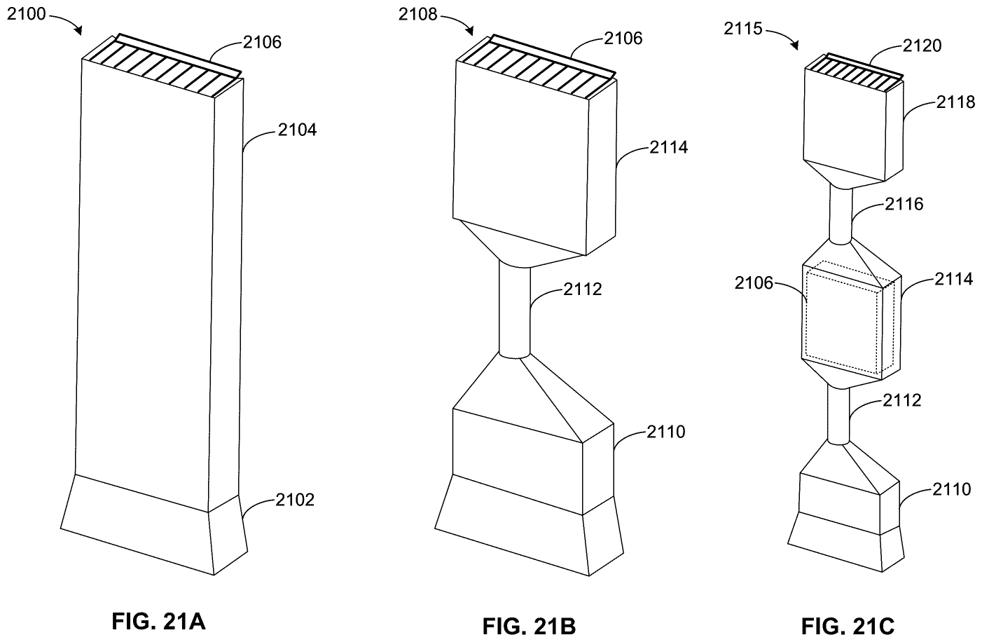

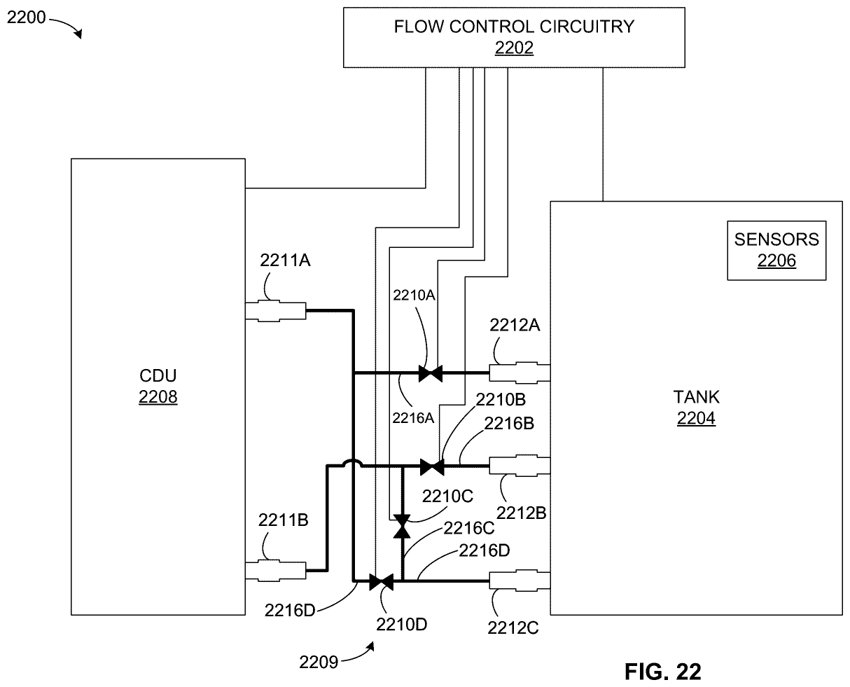

In the illustrated example of FIG. 18, the ducts 1708A, 1708B extend vertically from the bottom plate 1804 and are disposed over components of a chassis (e.g., the chassis 1704 of FIGS. 17A and 17B, etc.). In the illustrated example of FIG. 18, the first duct 1708A and the second duct 1708B include an example first inlet portion 1810A and an example second inlet portion 1810B, respectively. In the illustrated example of FIG. 18, the first inlet portion 1810A and the second inlet portion 1810B are different shapes. That is, in the illustrated example of FIG. 18, the first inlet portion 1810A includes an example bend 1812 and the second inlet portion 1810B is shaped as an isosceles trapezoidal prism substantially as an isosceles trapezoidal prism. The second inlet portion 1810B can have other shapes. In some examples, the bend 1812 of the first inlet portion 1810A can accommodate an off center alignment of the chassis associated with the ducts 1708A, 1708B (e.g., the chassis 1704 of FIGS. 17A, 17B, the chassis associated with the back plate 1800, etc.). In other examples, the first inlet portion 1810A and the second inlet portion 1810B can have a same size and shape. Other example ducts that can be used to implement the ducts 1708A, 1708B are discussed below in conjunction with FIGS. 21A-21C.

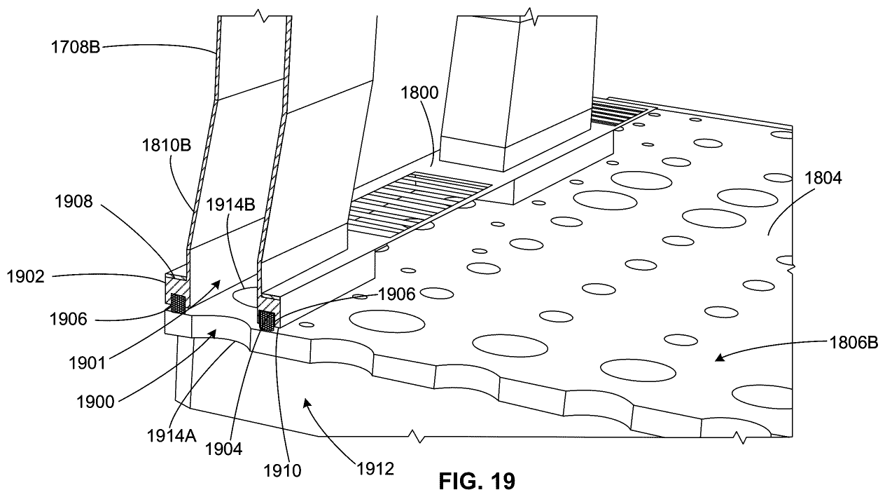

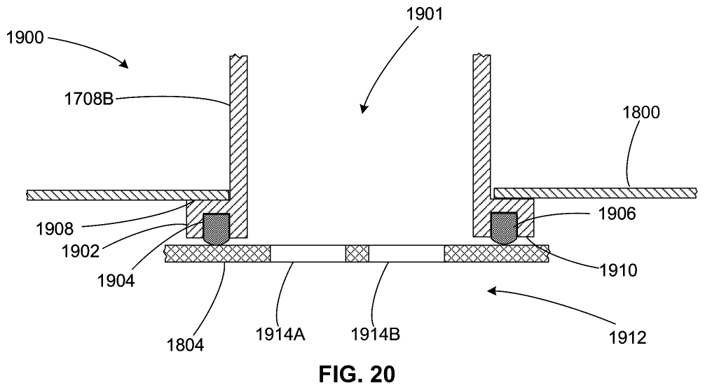

The back plate 1800 is a back plate of a chassis (not illustrated in FIG. 18 for visual clarity, see the chassis 1704 of FIGS. 17A and 17B, etc.). In the illustrated example of FIG. 18, the back plate 1800 includes an example first opening 1812A and an example second opening 1812B. The openings 1812A, 1812B surround the inlet portions 1810A, 1810B of the ducts 1708A, 1708B, respectively. In some examples, the back plate 1800 can exert a force (e.g., a compression force, a weight, etc.) on flange(s) of the ducts 1708A, 1708B, which retains an interface between the ducts 1708A, 1708B, respectively. The interface between the ducts 1708A, 1708B and the bottom plate 1804 is discussed below in conjunction with FIGS. 19 and 20.

In the illustrated example of FIG. 18, the bottom plate 1804 includes the example openings 1802A, 1802B, 1802C. The openings 1802A, 1802B, 1802C enable coolant (e.g., the coolant 1702 of FIGS. 17A and 17B, etc.) to flow into and/or out of the tank 1700. For example, if the tank 1700 is in the first coolant pathway arrangement 1701 and orientation of FIG. 17A, the openings 1802A, 1802B, 1802C can be downstream of the flow of coolant through the ducts 1708A, 1708B and fluidly coupled to an outlet of the tank 1700. That is, in the first coolant pathway arrangement 1701 of FIG. 17A, some of the openings 1802A, 1802B, 1802C can be upstream of the outlet 1712A, 1712B of FIG. 17A. As another example, if the tank 1700 is in the orientation of FIG. 17B, the openings 1802A, 1802B, 1802C can be fluidly coupled to an inlet of the tank 1700 and disposed in a flow path parallel to the flow of coolant through the ducts 1708A, 1708B. That is, in the second coolant pathway arrangement 1719 of FIG. 17B, some of the openings 1802A, 1802B, 1802C can implement the inlets 1720A, 1720B, 1720C of FIG. 17B, respectively. In some examples, some or all of the openings 1802A, 1802B, 1802C are absent.

FIGS. 19 and 20 depict an example interface 1900 between the second duct 1708B of FIGS. 17A-18 and the bottom plate 1804 of FIG. 18. FIG. 19 is a perspective cross-sectional view of the interface 1900. FIG. 20 is a schematic cross-sectional front view of the interface 1900. In the illustrated example of FIGS. 19 and 20, the second duct 1708B includes an example flange 1902, an example groove 1904, an example seal 1906, and the example back plate 1800 of FIGS. 19 and 20. In some examples, the first duct 1708A can be coupled to the bottom plate 1804 via an interface similar to the interface 1900. In other examples, the first duct 1708A can be coupled to the bottom plate 1804 in any other suitable manner.

In the illustrated example of FIGS. 19 and 20, the flange 1902 extends from and is adjacent to the second inlet portion 1810B of the second duct 1708B. The flange 1902 surrounds the second inlet portion 1810B. In the orientation shown in FIGS. 19 and 20, the back plate 1800 is adjacent to an example top surface 1908 of the flange 1902 (e.g., spaced from, abuts, coupled to, etc.) and the bottom plate 1804 is adjacent to an example bottom surface 1910 (e.g., spaced from, abuts, coupled to, etc.) of the flange 1902. In the illustrated example of FIGS. 19 and 20, the top surface 1908 abuts the back plate 1800. In other examples, one or more intervening components (e.g., seals, adhesive layers, etc.) can be disposed between the top surface 1908 and the back plate 1800, Additionally or alternatively, the back plate 1800 and the flange 1902 can be integral components.

In the illustrated example of FIGS. 19 and 20, the bottom surface 1910 of the flange 1902 includes the groove 1904, which extends around the flange 1902. The seal 1906 reduces (e.g., prevents, mitigates, etc.) leaks between an interior 1901 of the second duct 1708B and the exterior of the second duct 1708B. In the illustrated example of FIGS. 19 and 20, the seal 1906 is disposed within the groove 1904. In some examples, the seal 1906 can be coupled within the groove 1904 via one or more chemical adhesives, one or more fasteners, and/or one or more interference fits. In other examples, the seal 1906 can be retained within the groove 1904 via the interface 1900 (e.g., the abutment of the duct 1708A and the bottom plate 1804, etc.). The seal 1906 can be composed of any flexible and compliant material, including natural rubber, a synthetic rubber, and/or a plastic.

In the illustrated example and orientation of FIGS. 19 and 20, the interface 1900 enables fluid communication between an example chamber 1912 beneath the bottom plate 1804 and the interior 1901. Fluid within the chamber 1912 of the bottom plate 1804 can enter the interior 1901 of the second duct 1708B via an example first hole 1914A and an example second hole 1914B of the second holes 1808B of FIG. 18. In the illustrated example of FIGS. 19 and 20, the interface 1900 is aligned with the holes 1914A, 1914B such that coolant exiting the bottom plate 1804 via the holes 1914A, 1914B enters the second duct 1708B. In the illustrated examples of FIGS. 19 and 20, the holes 1914A, 1914B are arranged in a linear row. In other examples, the second duct 1708B can be aligned with a different number of holes (e.g., one hole, two holes, etc.) having any suitable geometric configuration.

In the illustrated example of FIG. 19, the interface 1900 (e.g., the abutment of the seal 1906 and the bottom plate 1804, etc.) is maintained in compression between the bottom plate 1804 and the back plate 1800 via the weight of the chassis to which the second duct 1708B is coupled. That is, in the illustrated example of FIGS. 19 and 20, the interface 1900 is a gravity-retained interface (e.g., a weight-retained interface, etc.), that is retained via the weight of the chassis 1704. In some examples, the interface 1900 enables the coupling of the second duct 1708B over the holes 1914A, 1914B regardless of the size of the holes 1914A, 1914B (e.g., the interface 1900 enables the second duct 1708B to be coupled to a hole of any size that is smaller than the duct 1708A, etc.). The interface 1900 reduces the required tolerance control needed for the second duct 1708B and the holes 1914A, 1914B. In other examples, the interface 1900 can be retained in compression between the bottom plate 1804 and the back plate 1800 via one or more separate couplings between the chassis 1704 and the bottom plate 1804 and/or the chassis 1704 and the tank 1700 of FIGS. 17A and 17B (e.g., a quick-release interface between the chassis 1704 and the bottom plate 1804, etc.). In other examples, the interface 1900 can be implemented via one or more fasteners (e.g., extending through the flanges 1902, etc.), one or more chemical adhesives, one or more interference fits, one or more welds, etc.

FIG. 21A is a schematic view of an example first duct 2100 that can be used to implement one or both of the ducts 1708A, 1708B of FIGS. 17A-19. In the illustrated example of FIG. 21A, the first duct 2100 includes an example inlet portion 2102 and an example main portion 2104. In the illustrated example of FIG. 21A, the main portion 2104 has a constant or substantially constant area along the length of the first duct 2100. In other examples, the geometry of the main portion 2104 can vary along the length of the first duct 2100. In the illustrated example of FIG. 21A, the inlet portion 2102 is similar to the first inlet portion 1810A of FIG. 18. The inlet portion 2102 can be disposed adjacent to an inlet of the first duct 2100 (e.g., the interface 1900 of FIGS. 19 and 20, etc.). The inlet portion 2102 is tapered (e.g., having a first width distal to the main portion 2104 and a second width smaller than the first width adjacent to the main portion 2104, etc.). In some examples, the taper of the inlet portion 2102 increases the relative size of a flange of the first duct 2100 (e.g., such as the flange 1902 of FIGS. 19 and 20 or a similar flange, etc.) compared to the size of the main portion 2104. In other examples, the inlet portion 2102 can have any other suitable geometry (e.g., flush with the main portion 2104, etc.).

In the illustrated example of FIG. 21A, the interior surfaces of the main portion 2104 are adjacent to an example heat sink 2106. The heat sink 2106 can be coupled to a compute unit (e.g., one of the compute units 1706A, 1706B, 1706C, 1706D of FIGS. 17A and 17B, etc.). In the illustrated example of FIG. 21A, the interior surfaces of the main portion 2104 are spaced via a small gap of the heat sink 2106. In other examples, the interior surfaces of the main portion 2104 can abut the heat sink 2106. During operation, heat generated by the compute unit is absorbed by the heat sink 2106. Coolant flowing through the first duct 2100 flows through the heat sink 2106 (e.g., through the fins of the heat sink 2106, etc.) and absorbs heat therefrom via convection. In some examples, additional heat sinks (not illustrated) can be disposed within the main portion 2104.

In the illustrated example of FIG. 21A, the first duct 2100 is an integral component (e.g., composed of a unitary material, etc.). In other examples, the first duct 2100 can include multiple discrete components, which can be coupled via one or more welds, one or more fasteners, one or more chemical adhesives, and/or one or more interference fits. The first duct 2100 can be composed of any suitable rigid material, such as a metal (e.g., aluminum, copper, steel, etc.), a rigid plastic, a composite, and/or a ceramic. In some examples, the first duct 2100 can be insulated to reduce the rate of heat transfer between the coolant within the first duct 2100 (e.g., flowing along one of the duct coolant pathways 1714A, 1714B of FIGS. 17A and 17B, etc.) and coolant outside of the first duct 2100 (e.g., flowing along one of the tank coolant pathways 1717 of FIG. 17A, flowing along one of the main coolant pathways 1723 of FIG. 17B, etc.). In the illustrated example of FIG. 21A, the flow path through the first duct 2100 ends after the heat sink 2106 (e.g., the coolant within the first duct 2100 exits the first duct 2100 after flowing through the heat sink 2106, etc.). In other examples, the first duct 2100 can continue after flowing through the first duct 2100 (e.g., to another compute unit downstream of the compute nit associated with the heat sink 2106.

FIG. 21B is a schematic view of an example second duct 2108 that can be used to implement one or both of the ducts 1708A, 1708B of FIGS. 17A-19. In the illustrated example of FIG. 21B, the second duct 2108 includes an example inlet portion 2110, an example tube portion 2112, and an example main portion 2114. In the illustrated example of FIG. 21B, coolant enters the second duct 2108 at the inlet portion 2110 (e.g., via an interface such as the interface 1900 of FIGS. 19 and 20 or a similar interface, etc.) and flows sequentially through the tube portion 2112 and the main portion 2114. The main portion 2114 of the second duct 2108 is similar to the main portion 2104 of FIG. 21A. That is, the main portion 2114 surrounds the heat sink 2106 of FIG. 21B and directs coolant flowing through the second duct 2108 therethrough. In the illustrated example of FIG. 21B, the flow path through second duct 2108 ends after the heat sink 2106 (e.g., the coolant within the second duct 2108 exits the second duct 2108 after flowing through the heat sink 2106, etc.). In other examples, the second duct 2108 can continue after flowing through the second duct 2108 (e.g., to another compute unit downstream of the compute unit associated with the heat sink 2106, etc.). In some such examples, the main portion 2114 can extend downstream of the heat sink 2106. In other examples, another tube portion similar to the tube portion 2112 can extend downstream of the main portion 2114. An example duct including another tube portion is disclosed below in conjunction with FIG. 21C.

The tube portion 2112 can be composed of a flexible material (e.g., rubber, a plastic, etc.). In other examples, the tube portion 2112 can be a rigid material (e.g., a metal, a ceramic, a composite, a rigid plastic, etc.). In the illustrated example of FIG. 21B, the tube portion 2112 is cylindrical (e.g., has a circular cross-section, etc.). In other examples, the tube portion 2112 can have any other suitable geometry (e.g., ovoid, prism-shaped, etc.). In some examples, the tube portion 2112 can have a same shape as the main portion 2114. In some examples, the smaller size of the tube portion 2112 enables the components of a chassis to be disposed on an exterior of the second duct 2108 adjacent to the second duct 2108 and/or enables the placement of components that are larger than the interior of the second duct 2108 on the chassis near the main portion 2114. In some examples, the tube portion 2112 can prevent unwanted heat transfer from other components of the chassis (e.g., memory, power supplies, etc.) into the coolant flowing through the ducts (e.g., heat produced by components other than the compute units disposed within the duct, etc.).

In the illustrated example of FIG. 21B, the inlet portion 2110 and the main portion 2114 are coupled to respective ends of the tube portion 2112. For example, the inlet portion 2110 and the main portion 2114 can be coupled the tube portion 2112 via one or more chemical adhesives, one or more fasteners, one or more interference fits, and/or any other suitable fasteners. In other examples, some or all of the inlet portion 2110, the tube portion 2112, and/or the main portion 2114 can be integral components (e.g., formed from a same sheet and/or blank, etc.). The main portion 2114 and/or the inlet portion 2110 can be composed of any suitable rigid material, such as a metal (e.g., aluminum, copper, steel, etc.), a rigid plastic, a composite, and/or a ceramic. In some examples, the main portion 2114 and/or the inlet portion 2110 can be insulated to reduce the rate of heat transfer between the coolant within the second duct 2108 and coolant outside of the second duct 2108.

FIG. 21C is a schematic view of an example third duct 2115 that can be used to implement the duct of FIGS. 17A-19. In the illustrated example of FIG. 21C, the third duct 2115 includes the example inlet portion 2110 of FIG. 21B, the example tube portion 2112 of FIG. 21B (referred to in conjunction with FIG. 21C as a “first tube portion 2112”), and the example main portion 2114 of FIG. 21B (referred to in conjunction with FIG. 21C as a “first main portion 2114”). In the illustrated example of FIG. 21C, the first main portion 2114 surrounds the example heat sink 2106 of FIGS. 21A and 21B (referred to in conjunction with FIG. 21C as a “first heat sink 2106.”) and directs coolant flowing through the third duct 2115 therethrough. In the illustrated example of FIG. 21C, the third duct 2115 is similar to the second duct 2108 of FIG. 21B, except that the third duct 2115 further includes an example second tube portion 2116 downstream of the first main portion 2114 within the third duct 2115 and an example second main portion 2118 downstream of the second tube portion 2116. In the illustrated example of FIG. 21C, the second main portion 2118 surrounds an example second heat sink 2120 and directs coolant flowing through the third duct 2115 therethrough. The third duct 2115 can be used for chassis including compute units in a shadowed configuration, such as the chassis 1704 of FIGS. 17A and 17B.

In the illustrated example of FIG. 21C, the second tube portion 2116 has a same size and shape as the first tube portion 2112. In other examples, the second tube portion 2116 can have any other suitable size or shape to accommodate the flow of coolant between the main portions 2114, 2118. For example, the second tube portion 2116 can include one or more bends and/or deformations to accommodate components of the chassis to which the third duct 2115 is coupled. In the illustrated example of FIG. 21C, the second main portion 2118 has a same size and shape as the first main portion 2114. In other examples, the second main portion 2118 can have any other suitable size or shape to accommodate the flow of coolant through the second heat sink 2120. For example, the second main portion 2118 can have a size and shape that is complementary to the size and shape of the second heat sink 2120.

In the illustrated example of FIG. 21C, coolant enters the third duct 2115 at the inlet portion 2110 (e.g., via an interface similar to the interface 1900 of FIGS. 19 and 20, etc.) and flows sequentially (1) through the first tube portion 2112, (2) into the first main portion 2114 and through the first heat sink 2106, (3) through the second tube portion 2116, and (4) into the second main portion 2118 and through the second heat sink 2120. In the illustrated example of FIG. 21C, the flow path through the third duct 2115 ends after the second heat sink 2120 (e.g., the coolant within the third duct 2115 exits the third duct 2115 after flowing through the heat sink 2106, etc.). In other examples, the third duct 2108 can include additional components that direct flow downstream of the second heat sink 2120 (e.g., to another compute unit downstream of the compute unit associated with the second heat sink 2120, etc.). In some such examples, the second main portion 2118 can continue downstream of the heat sink 2106. In other examples, another tube portion similar to the tube portions 2112, 2116 can be coupled to the second main portion 2118 and extend downstream of the second main portion 2118.

FIG. 22 is an example side schematic view of example system 2200 including example flow control circuitry 2202 in accordance with teachings of this disclosure. In the illustrated example of FIG. 22, the system 2200 includes an example tank 2204 having example sensor(s) 2206, an example CDU 2208, and example piping 2209. In the illustrated example of FIG. 22, the system 2200 includes an example first valve 2210A, an example second valve 2210B, an example third valve 2210C, and an example fourth valve 2210D, which control the flow of coolant through various portions of the piping 2209. The flow control circuitry 2202 can control the operation of one or more of the valves 2210A, 2210B, 2210C, 2210D to cause the system 2200 to operate in one or more coolant pathway arrangements or flow path architectures Another example system having different coolant pathway arrangements or flow path architectures is described below in conjunction with FIG. 25.

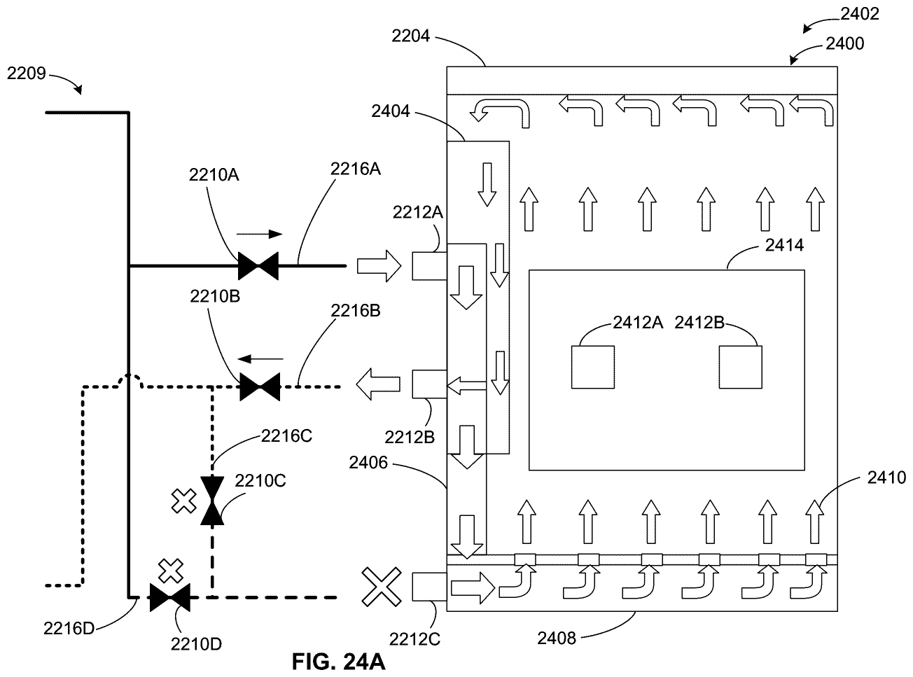

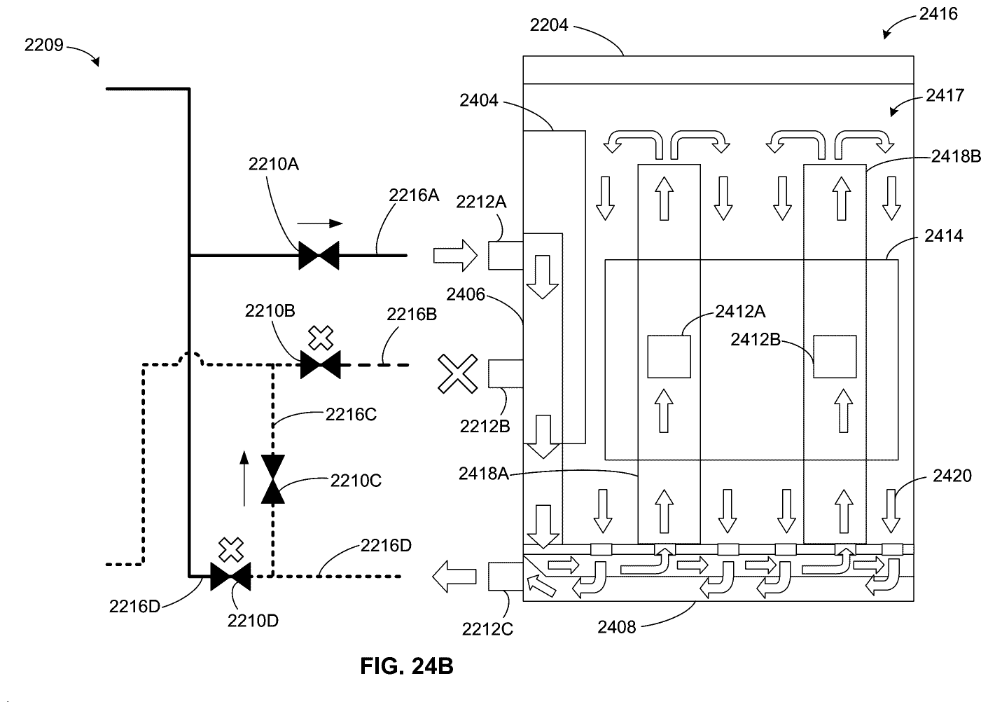

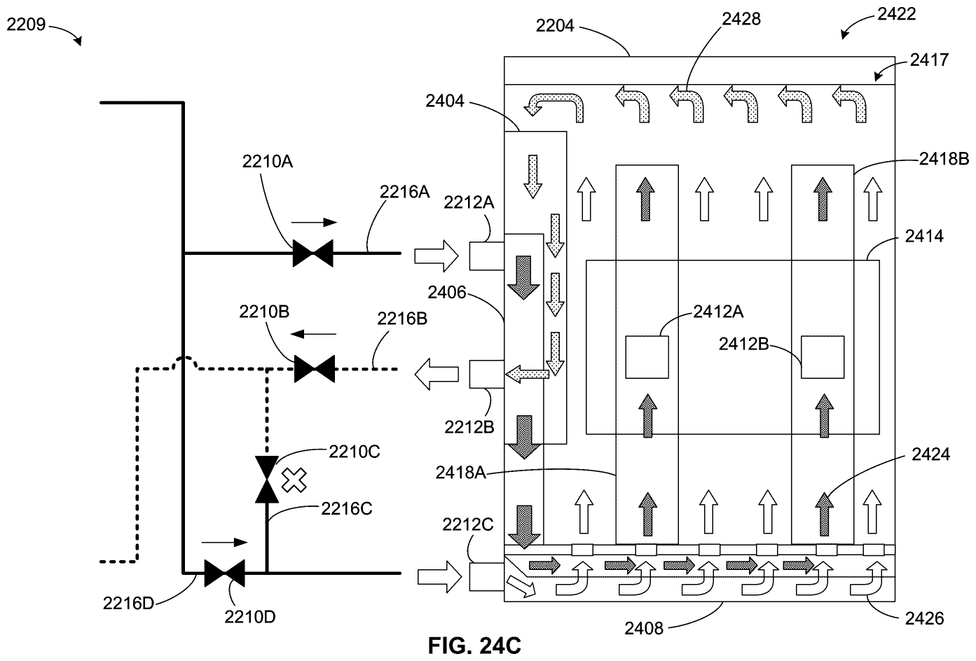

The tank 2204 is similar to the tanks 1700, 1703 of FIGS. 17A and 17B, except that the tank 2204 includes an example first junction 2212A, an example second junction 2212B, and an example third junction 2212C and as otherwise noted. In some examples, the tank 2204 can include one or more ducts similar to the ducts 1708A, 1708B of FIGS. 17A-21. An example plate (e.g., a bottom plate) that can be used in conjunction with the tank 2204 is disclosed below in conjunction with FIG. 23. Example internal features of the tank 2204 are disclosed below in conjunction with FIGS. 24A-24C. In some examples, the internal features of the tank 2204 can be changed in different coolant pathway arrangements of the tank 2204 (e.g., the ducts 1708A, 1708B can be installed and/or removed from the tank 2204, etc.).

In the illustrated example of FIGS. 22, the tank 2204 includes the sensor(s) 2206, which output one or more sensor outputs to the flow control circuitry 2202. Additionally, in some examples, the CDU 2208, the piping 2209, and/or the valves 2210A, 2210B, 2210C, 2210D can include sensor(s) that output information of the flow control circuitry 2202. In some examples, the sensor(s) 2206 can include one or more flowmeters that measure the flow of coolant through one or more portions of the tank 2204 (e.g., the flow of coolant through one or more ducts of the tank 2204, through one or more chambers of a bottom plate of the tank 2204, through one or more of the valves 2210A, 2210B, 2210C, 2210D, etc.). In some such examples, the sensor(s) 2206 can include one or more thermal mass flow sensor(s), one or more Coriolis flow sensor(s), one or more differential pressure flow sensor(s), one or more magnetic flowmeter(s), one or more multiphase flowmeter(s), one or more ultrasonic flowmeter(s), and/or one or more vortex flowmeter(s). In some examples, the sensor(s) 2206 can include one or more temperature sensors that measure the temperature of the coolant at various locations in the system (e.g., an inlet of the tank 2204, an outlet of the tank 2204, an outlet of a duct of the tank 2204, etc.) and/or the temperature of one or more compute units disposed within the tank 2204. In some such examples, the sensor(s) 2206 can be implemented by one or more thermocouple(s), one or more resistance temperature detector(s), one or more thermistor(s), one or more infrared optical sensor(s), one or more semiconductor-based sensor(s).

The CDU 2208 cools, pumps, and distributes the coolant into one or more immersion cooling tanks (e.g., the tank 2204, etc.). The example CDU 2208 can include one or more heat exchanger(s) that cools the coolant via the flow of another fluid (e.g., a shell and tube heat exchanger with facility tap water, a tube-in-tube heat exchanger with facility tap water, etc.). In some such examples, the CDU 2208 can include a connection to a municipal water supply to access and discharge water used to regulate the temperature of the coolant. In some examples, the CDU 2208 can include one or more radiators to cool the coolant and/or the heat exchange fluid via air convection. Additionally or alternatively, the CDU 2208 can include one or more pumps to drive the coolant into and out of the tank 2204. In the illustrated example of FIG. 22, fresh coolant (e.g., cold coolant, etc.) leaves the CDU 2208 via an example coolant inlet 2211A and stale coolant (e.g., warmed coolant, etc.) reenters the CDU 2208 via an example coolant outlet 2211B to be cooled and recirculated through the tank 2204.

The piping 2209 extends between the tank 2204 and the CDU 2208. In some examples, some or all of the piping 2209 can be flexible tubes (e.g., rubber tubes, plastic tubes, etc.). Additionally or alternatively, some or all of the piping 2209 can be rigid or substantially rigid tubes (e.g., metal piping, plastic tubes, etc.). In some examples, some or all of the piping 2209 can be insulated to reduce heat transfer between the coolant in the corresponding ones of the piping 2209 and the ambient environment.

The valves 2210A, 2210B, 2210C, 2210D are control valves that regulate the flow of coolant between the CDU 2208 and one or more of the junctions 2212A, 2212B, 2212C. In the illustrated example of FIG. 22, the first valve 2210A regulates the flow of coolant through a first piping portion 2216A of the piping 2209, the second valve 2210B regulates the flow of coolant through a second piping portion 2216B of the piping 2209, the third valve 2210C regulates the flow of coolant through a third piping portion 2216C of the piping 2209, and the fourth valve 2210D regulates the flow of coolant through a fourth piping portion 2216D of the piping 2209. In some examples, some or all of the valves 2210A, 2210B, 2210C, 2210D are shutoff valves (e.g., can alternate between a fully open position and a fully closed position, etc.). In some such examples, some or all of the valves 2210A, 2210B, 2210C, 2210D can be implemented by a globe valve, a straight-through diaphragm valve, a gate valve, and/or another type of shut-off valve. Additionally or alternatively, some or all of the valves 2210A, 2210B, 2210C, 2210D can be modulated valves (e.g., have a fully open position, a plurality of partially open positions, and a closed positions, etc.). Some or all of the valves 2210A, 2210B, 2210C, 2210D can be implemented by a butterfly valve, a ball valve, a weir-diaphragm valve, a needle valve, and/or another type of modulated valve. In the illustrated example of FIG. 22, the valves 2210A, 2210B, 2210C, 2210D are two-way valves. An example system including three-way valves is disclosed below in conjunction with FIG. 25.

The junctions 2212A, 2212B, 2212C are ports that enable the egress and ingress of the coolant from the tank 2204. In some examples, depending on the position of the valves 2210A, 2210B, 2210C, 2210D, ones of the junctions 2212A, 2212B, 2212C can be coolant inlet(s) for the tank 2204 and ones of the junctions 2212A, 2212B, 2212C can be coolant outlet(s) for the tank 2204. The junctions 2212A, 2212B, 2212C can be implemented by any suitable ports.

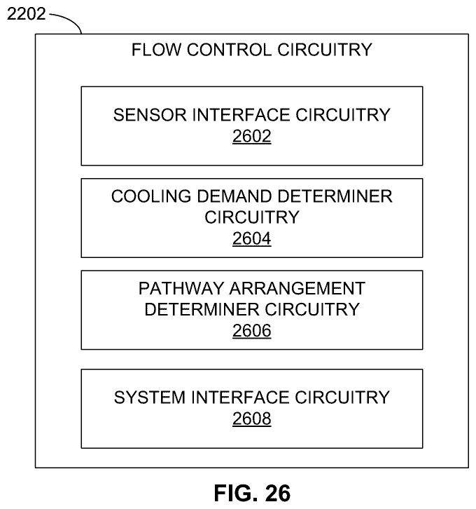

During operation, the flow control circuitry 2202 can cause the position of one or more of the valves 2210A, 2210B, 2210C, 2210D to change to articulate the system 2200 between different coolant pathway arrangements. In some examples, the flow control circuitry 2202 can identify a cooling demand of the tank 2204 and/or one or more of the compute units disposed within the tank 2204 to determine which coolant pathway arrangement to operate the tank 2204 (e.g., where the cooling demand reflects an increase in heat generated at the tank and/or by one or more of the compute units disposed therein). An example implementation of the flow control circuitry 2202 is disclosed below in conjunction with FIG. 26. In some examples, the position of some or all of the valves 2210A, 2210B, 2210C, 2210D can additionally or alternatively be manually controlled by an operator of the system 2200 to articulate the system 2200 between different coolant pathway arrangements or flow path architectures.

FIG. 23 is a perspective view of an example bottom plate 2300 that can be used in conjunction with the system 2200 of FIG. 22 and/or the tank 1700 of FIGS. 17A and 17B. In the illustrated example of FIG. 23, the bottom plate 2300 includes an example first row of holes 2302A, an example second row of holes 2302B, an example third row of holes 2302C, an example fourth row of holes 2302D, an example fifth row of holes 2302E, an example sixth row of holes 2302F, an example seventh row of holes 2302G, an example eighth row of holes 2302H, and an example ninth row of holes 2302I. In the illustrated example of FIG. 23, the bottom plate 2300 includes an example first chamber 2304A, an example second chamber 2304B, an example third chamber 2304C, an example fourth chamber 2304D, an example fifth chamber 2304E, an example sixth chamber 2304F, an example seventh chamber 2304G, an example eighth chamber 2304H, and an example ninth chamber 2304I. The bottom plate 2300 of FIG. 23 is similar to the bottom plate 1804 of FIGS. 18 and 19, except as noted otherwise.

In the illustrated example of FIG. 23, the chambers 2304A, 2304B, 2304C, 2304D, 2304E, 2304F, 2304G, 2304H, 2304I divide the bottom plate 2300 into several channels, which are aligned or substantially aligned with the rows of holes 2302A, 2302B, 2302C, 2302D, 2302E, 2302F, 2302G, 2302H, 2302I. That is, the first chamber 2304A is fluidly coupled to the tank 2204 via the first row of holes 2302A, the second chamber 2304B is fluidly coupled to the tank 2204 via the second row of holes 2302B, etc. Some or all of the chambers 2304A, 2304B, 2304C, 2304D, 2304E, 2304F, 2304G, 2304H, 2304I can be coupled to different ones of the junctions 2212A, 2212B, 2212C, and which enables the bottom plate 2300 to support different flow configurations. In some examples, some or all of the holes of the rows of holes 2302A, 2302B, 2302C, 2302D, 2302E, 2302F, 2302G, 2302H, 2302I can be coupled to one or more of the ducts 1708A, 1708B via one or more interfaces similar to the interface 1900 of FIG. 19. In some examples, the holes 2302A, 2302B, 2302C, 2302D, 2302E, 2302F, 2302G, 2302H, 2302I rectify the flow of coolant through the bottom plate 2300 (e.g., make the coolant more uniform, etc.).

FIG. 24A is a schematic view of the system 2200 of FIG. 22 in an example first coolant pathway arrangement 2400 (e.g., a first flow path architecture, etc.). In the illustrated example of FIG. 24A and the first coolant pathway arrangement, the immersion cooling tank 2204 has an example first internal configuration 2402. The first internal configuration 2402 is similar to prior internal tank configurations, except that the internal configuration include components (e.g., the valves 2210A, 2210B, 2210C, 2210D, the junctions 2212A, 2212B, 2212C, etc.) that enable the tank 2204 to assume different internal configurations. In the first internal configuration 2402, the tank 2204 includes an example overflow chamber 2404, an example first inlet manifold 2406, and an example second inlet manifold 2408. In the first coolant pathway arrangement 2400, the first valve 2210A is open, the second valve 2210B is open, the third valve 2210C is closed, and the fourth valve 2210D is open. In the illustrated example of FIG. 24A, because the first valve 2210A is open, coolant flows through the first piping portion 2216A and because the second valve 2210B is open, coolant flows through the second piping portion 2216B. In the illustrated example of FIG. 24A, the first junction 2212A is the inlet to the tank 2204 and the second junction 2212B is the outlet of the tank 2204. In the illustrated example of FIG. 24A, because the third valve 2210C and the fourth valve 2210D are closed, coolant does not flow through the third piping portion 2216C and the fourth piping portion 2216D and the third junction 2212C is closed.

In the illustrated example of FIG. 24A, the first inlet manifold 2406 is fluidly coupled to the first junction 2212A, the overflow chamber 2404 is fluidly coupled to the second junction 2212B, and the example second inlet manifold 2408 is fluidly coupled to the third junction 2212C. In the first coolant pathway arrangement 2400 of FIG. 24A, coolant flows via an example flow path 2410 through the tank 2204. In the illustrated example of FIG. 24A, the flow path 2410 begins within the tank 2204 via the first junction 2212A and flows along the first inlet manifold 2406 to a bottom of the tank 2204 (e.g., the bottom relative to the orientation depicted in FIG. 24A, etc.). From the bottom of the tank 2204, the flow path 2410 flows through the tank 2204 to the top of the tank 2204 (e.g., the top relative to orientation depicted in FIG. 24A, etc.), which cools an example first compute unit 2412A and an example second compute unit 2412B, which are disposed on an example chassis 2414. The compute unit 2412A, 2412B and the chassis 2414 are similar to the compute units 1706A, 1706B, 1706C, 1706D and the chassis 1704 of FIGS. 17A and 17B, except that the chassis 1704 includes two compute units in a shadowed configuration. After reaching the top of the tank 2204, the flow path 2410 extends into the overflow chamber 2404 and exits the tank via the second junction 2212B.

FIG. 24B is a schematic view of the system 2200 of FIG. 22 in an example second coolant pathway arrangement 2416 (e.g., a second flow path architecture, etc.). In the illustrated example of FIG. 24B, the immersion cooling tank 2204 has an example second internal configuration 2417. In the second internal configuration 2417, the tank 2204 includes the overflow chamber 2404 of FIG. 24A, the first inlet manifold 2406 of FIG. 24A, the second inlet manifold 2408 of FIG. 24A, an example first duct 2418A, and an example second duct 2418B. In the illustrated example of FIG. 24B, the first compute unit 2412A is disposed within the first duct 2418A and the second compute unit 2412B is disposed within the second duct 2418B. The first duct 2418A and the second duct 2418B can be implemented by one or more of the ducts 1708A, 1708B of FIGS. 17A-18, the first duct 2100 of FIG. 21A, the second duct 2108 of FIG. 21B, and/or the third duct 2115 of FIG. 21C.

In the second coolant pathway arrangement 2416, the first valve 2210A is open, the second valve 2210B is closed, the third valve 2210C is opened, and the fourth valve 2210D is closed. In the illustrated example of FIG. 24B, because the first valve 2210A is open, coolant flows through the first piping portion 2216A. In the illustrated example of FIG. 24B, because the third valve 2210C is open, coolant flows through the third piping portion 2216C. In the illustrated example of FIG. 24B, the first junction 2212A is the inlet to the tank 2204 and the third junction 2212C is the outlet of the tank 2204. In the illustrated example of FIG. 24B, because the second valve 2210B and the fourth valve 2210D are closed, coolant does not flow through the second piping portion 2216B and the fourth piping portion 2216D and the second junction 2212B is closed.

In the second coolant pathway arrangement 2416 of FIG. 24B, coolant flows through an example coolant pathway 2420 through the tank 2204. In the illustrated example of FIG. 24B, the coolant pathway 2420 begins within the tank 2204 at the first junction 2212A and flows along the first inlet manifold 2406 to a bottom of the tank 2204 (e.g., the bottom relative to the orientation depicted in FIG. 24B, etc.). From the bottom of the tank 2204, the coolant pathway 2420 enters the ducts 2418A, 2418B and flows over the compute units 2412A, 2412B, which cools the compute units via convection. The coolant pathway 2420 exits the ducts 2418A, 2418B at the top of the tank 2204 (e.g., the top relative to the orientation depicted in FIG. 24A, etc.). After reaching the top of the tank 2204, the coolant pathway 2420 reverses direction and flows to the bottom of the tank 2204, which cools the other components of the chassis 2414. At the bottom of the tank 2204, the coolant pathway 2420 enters the second inlet manifold 2408 and then exits the tank 2204 via the third junction 2212C. It should be appreciated that the second coolant pathway arrangement 2416 is a reverse coolant pathway arrangement, similar to the first coolant pathway arrangement 1701 of FIG. 17A. In the illustrated example of FIG. 24B, the coolant pathway 2420 of the second coolant pathway arrangement 2416 does not extend through the overflow chamber 2404. In some such examples, the overflow chamber 2404 is absent.

FIG. 24C is a schematic view of the system 2200 of FIG. 22 in an example third coolant pathway arrangement 2422 (e.g., a third flow path architecture, etc.). In the illustrated example of FIG. 24B, the immersion cooling tank 2204 has the second internal configuration 2417 of FIG. 24B (e.g., the system 2200 includes the overflow chamber 2404 of FIGS. 24A and 24B, the first inlet manifold 2406 of FIGS. 24A and 24B, the second inlet manifold 2408 of FIGS. 24A and 24B, the first duct 2418A of FIG. 24B, and an example second duct 2418B of FIG. 24B, etc.).

In the third coolant pathway arrangement 2422, the first valve 2210A is open, the second valve 2210B is opened, the third valve 2210C is closed, and the fourth valve 2210D is opened. In the illustrated example of FIG. 24C, because the first valve 2210A is open, coolant flows through the first piping portion 2216A and the first junction 2212A is an inlet (e.g., a first inlet, etc.) for the tank 2204. In the illustrated example of FIG. 24C, because the second valve 2210B is open, coolant flows through the second piping portion 2216B and the second junction 2212B is the outlet for the tank 2204. In the illustrated example of FIG. 24C, because the fourth valve 2210D is open and the third valve 2210C is closed, coolant flows through the fourth piping portion 2216D and the third junction 2212C is an inlet (e.g., the second inlet, etc.) for the tank 2204. In the illustrated example of FIG. 24C, the third valve 2210C is closed and coolant does not flow through the third piping portion 2216C, which prevents direct fluid communication between the second piping portion 2216B and the fourth piping portion 2216D.

In the third coolant pathway arrangement 2422 of FIG. 24C, coolant flows through an example first coolant pathway 2424, an example second coolant pathway 2426, and an example third coolant pathway 2428 through the tank 2204. In the illustrated example of FIG. 24C, the first coolant pathway 2424 is represented with arrows with a high-density dot filling, the second coolant pathway 2426 is represented with arrows having no dot filing, and the third coolant pathway 2428 is represented with arrows having a low-density dot filling. The schematic differences of the arrows representing the coolant pathways 2424, 2426, 2428 is for visual clarity only and do not represent the qualities of coolant flowing through the coolant pathways 2424, 2426, 2428.

In the illustrated example of FIG. 24C, the first coolant pathway 2424 begins within the tank 2204 at the first junction 2212A and flows along the first inlet manifold 2406 to a bottom of the tank 2204 (e.g., the bottom relative to the orientation depicted in FIG. 24B, etc.). From the bottom of the tank 2204, the first coolant pathway 2424 extends through the ducts 2418A, 2418B and flows over the compute units 2412A, 2412B, which cools the compute units 2412A, 2412B via convection. The first coolant pathway 2424 exits the ducts 2418A, 2418B at the top of the tank 2204 (e.g., the top relative to the orientation depicted in FIG. 24A, etc.) and joins the third coolant pathway 2428. The second coolant pathway 2426 begins within the tank 2204 via the third junction 2212C and flows along the second inlet manifold 2408 along a bottom of the tank 2204 (e.g., the bottom relative to the orientation depicted in FIG. 24A, etc.). From the bottom of the tank 2204, the second coolant pathway 2426 flows through the tank 2204 to the top of the tank 2204 (e.g., the top relative to the orientation depicted in FIG. 24A, etc.) along an exterior of the ducts 2418A, 2418B, which cools the other components of the chassis 2414 via convection. At the top of the tank 2204, the second coolant pathway 2426 joins the third coolant pathway 2428. The third coolant pathway 2428 (e.g., a combination of the first coolant pathway 2424 and the second coolant pathway 2426, etc.) extends into the overflow chamber 2404 and exits the tank 2204 via the second junction 2212B. It should be appreciated that the third coolant pathway arrangement 2422 is a split coolant pathway arrangement, similar to the second coolant pathway arrangement 1719 of FIG. 17B.

In some examples, the relative portions of coolant flowing through the first coolant pathway 2424 and the second coolant pathway 2426 can be regulated via the sizing of the piping portions 2216A, 2216B, 2216C, 2216D and/or the position of the first valve 2210A and the fourth valve 2210D. For example, the relative portions of the coolant flowing through the first coolant pathway 2424 and the second coolant pathway 2426 can be changed by changing the relative size of the first piping portion 2216A and the fourth piping portion 2216D (e.g., increasing the relative size of the first piping portion 2216A increases the relative portion of coolant flowing through the first coolant pathway 2424, increasing the relative size of the fourth piping portion 2216D increases the relative size of the coolant flowing through the second coolant pathway 2426, etc.). Additionally or alternatively, the portions of coolant flowing through the first coolant pathway 2424 and the second coolant pathway 2426 can be actively controlled via the positions of the first valves 2210A and the fourth valve 2210D (e.g., if the first valve 2210A and the fourth valve 2210D are modulated valves, etc.). In some such examples, the flow control circuitry 2202 can control the relative portions of coolant flowing through the first coolant pathway 2424 and the second coolant pathway 2426 based on a cooling demand of the compute units 2412A, 2412B (e.g., increasing the portion flowing through the first coolant pathway 2424 if the cooling demand of the compute units is increased due to heat generated by the compute units as a result of operation of the compute units, etc.). As used herein, the comparative distribution of coolant flowing through the first coolant pathway 2424 and the second coolant pathway 2426 in the third coolant pathway arrangement 2422 of FIG. 24C is referred to as the “flow distribution ratio,” which is the ratio of the volume coolant flowing through the first coolant pathway 2424 and the second coolant pathway 2426. In some examples, the flow distribution ratio can be between 1:1 and 10:1. In some examples, the flow distribution ratio is 7:3. Other flow distribution ratios can be used.

FIG. 25 is an example side schematic view of another example system 2500 including the flow control circuitry 2202 of FIG. 22 in accordance with teachings of this disclosure. In the illustrated example of FIG. 25, the system 2500 includes the flow control circuitry 2202 of FIG. 22, the tank 2204 of FIG. 22, the sensors 2206 of FIG. 22, the CDU 2208 of FIG. 22, the junctions 2212A, 2212B, 2212C of FIG. 22, and the piping portions 2216A, 2216B, 2216C, 2216D of FIG. 22. The system 2500 is similar to the system 2200 except that the system 2500 includes an example first valve 2502 and an example second valve 2504 instead of the valves 2210A, 2210B, 2210C, 2210D. In the illustrated example of FIG. 25, the first valve 2502 and the second valve 2504 are three-way valves, which control the flow of coolant through the piping portions 2216A, 2216B, 2216C, 2216D. In some examples, the flow control circuitry 2202 can control the flow of coolant from the CDU 2208 and the tank 2204 via controlling the position of the valves 2502, 2504.

The flow control circuitry 2202 can control cause the system 2500 to change between the second coolant pathway arrangement 2416 of FIG. 24B and the third coolant pathway arrangement 2422. For example, the flow control circuitry 2202 can cause the system to have the second coolant pathway arrangement 2416 of FIG. 24B by outputting instructions to cause: opening the first valve 2502 between the coolant outlet 2211A and the first junction 2212A, closing the first valve 2502 between the coolant outlet 2211A and the third junction 2212C, opening the second valve 2504 between the coolant inlet 2211B and the third junction 2212C, and closing the second valve 2504 between the coolant inlet 2211B and the second junction 2212B. For example, the flow control circuitry 2202 can cause the system to have the third coolant pathway arrangement 2422 of FIG. 24C by outputting instructions to cause: opening the first valve 2502 between the coolant outlet 2211A and the first junction 2212A, opening the first valve 2502 between the coolant outlet 2211A and the third junction 2212C, closing the second valve 2504 between the coolant inlet 2211B and the third junction 2212C, and opening the second valve 2504 between the coolant inlet 2211B and the second junction 2212B.

FIG. 26 is a block diagram of an example implementation of the flow control circuitry 2202 of FIG. 22 to regulate the flow of coolant through the system 2200 of FIG. 22 and/or the flow of coolant through the system 2500 of FIG. 25. In the illustrated example of FIG. 26, the flow control circuitry 2202 includes example sensor interface circuitry 2602, example cooling demand determiner circuitry 2604, example pathway arrangement determiner circuitry 2606, and example system interface circuitry 2608. The flow control circuitry 2202 of FIG. 26 may be instantiated (e.g., creating an instance of, bring into being for any length of time, materialize, implement, etc.) by programmable circuitry such as a Central Processor Unit (CPU) executing first instructions. Additionally or alternatively, the flow control circuitry 2202 of FIG. 26 may be instantiated (e.g., creating an instance of, bring into being for any length of time, materialize, implement, etc.) by (i) an Application Specific Integrated Circuit (ASIC) and/or (ii) a Field Programmable Gate Array (FPGA) structured and/or configured in response to execution of second instructions to perform operations corresponding to the first instructions. It should be understood that some or all of the circuitry of FIG. 26 may, thus, be instantiated at the same or different times. Some or all of the circuitry of FIG. 26 may be instantiated, for example, in one or more threads executing concurrently on hardware and/or in series on hardware. Moreover, in some examples, some or all of the circuitry of FIG. 26 may be implemented by microprocessor circuitry executing instructions and/or FPGA circuitry performing operations to implement one or more virtual machines and/or containers.

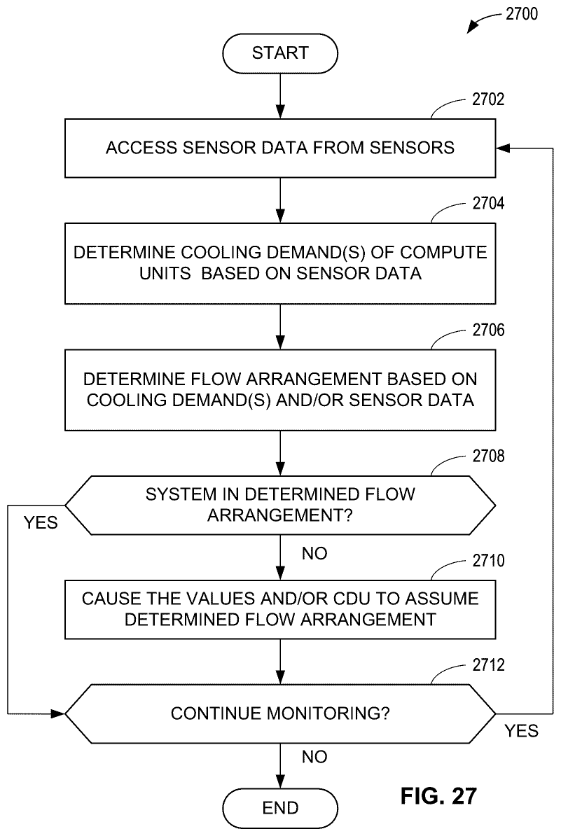

The sensor interface circuitry 2602 receives and/or accesses sensor data from the sensor(s) 2206. For example, the sensor interface circuitry 2602 can retrieve, receive, and/or otherwise access the output(s) of the sensor(s) 2206 of FIGS. 22 and 25 and/or one or more other sensor(s) of the system 2200 of FIG. 22 and/or the system 2500 of FIG. 25. For example, the sensor interface circuitry 2602 can access sensor output(s) corresponding to data related to the temperature of the coolant in portions of the tank 2204, a temperature of the compute units 2412A, 2412B, a flow rate of coolant, etc. In some examples, the sensor interface circuitry 2602 can interface with one or more of the valves 2210A, 2210B, 2210C, 2210D of the system 2200 and/or the valves 2502, 2504 of the system 2500 to determine a current position of one or more of the 2210A, 2210B, 2210C, 2210D and/or the valves 2502, 2504. In some examples, the sensor interface circuitry 2602 can convert the received sensor outputs to a human-readable format (e.g., converting a voltage output to a floating point number, etc.). In some examples, the sensor interface circuitry 2602 is instantiated by programmable circuitry executing sensor interface instructions and/or configured to perform operations such as those represented by the flowchart of FIG. 27.

The cooling demand determiner circuitry 2604 determines the cooling demand (e.g., the cooling needs, the heat output, etc.) of one or more of the compute unit(s) of the system 2200 and/or the system 2500. For example, the cooling demand determiner circuitry 2604 can determine the cooling demand of the compute units 2412A, 2412B via the sensor data accessed by the sensor interface circuitry 2602. For example, the cooling demand determiner circuitry 2604 can measure the temperature and/or thermal output of the compute units 2412A, 2412B via a temperature sensor of the sensors 2206 (e.g., a temperature sensor disposed on and/or incorporated into one of the compute units 2412A, 2412B, a temperature sensor disposed in a flow path downstream of the compute units 2412A, 2412B, etc.). Additionally or alternatively, the cooling demand determiner circuitry 2604 can determine the cooling demand of one or both of the compute units 2412A, 2412B based on a current processing load (e.g., the utilization of the processing resources, a number of queued computation tasks, etc.) of the compute units 2412A, 2412B. In other examples, the cooling demand determiner circuitry 2604 can estimate the cooling needs of one or both of the compute units 2412A, 2412B by any other suitable means. Additionally or alternatively, the cooling demand determiner circuitry 2604 can determine (e.g., calculate, estimate, predict) the associated fluid property values of the tank 2204 and/or the compute units 2412A, 2412B based on the sensor data via fluid mechanics and/or thermodynamic principles. In some examples, the cooling demand determiner circuitry 2604 is instantiated by programmable circuitry executing cooling demand determiner instructions and/or configured to perform operations such as those represented by the flowchart of FIG. 27.

The pathway arrangement determiner circuitry 2606 determines the flow configuration, arrangement, and/or architecture based on the cooling demand(s) of the compute unit 2412A, 2412B and/or the sensor data. For example, the pathway arrangement determiner circuitry 2606 can determine whether to operate in the second coolant pathway arrangement 2416 of FIG. 24B and/or the third coolant pathway arrangement 2422 of FIG. 24C. In some examples, the pathway arrangement determiner circuitry 2606 can also determine a position (e.g., open, closed) of the valves in the third coolant pathway arrangement 2422 of FIG. 24C (or any other selected coolant pathway arrangement). For example, if the cooling demand of the compute units 2412A, 2412B are not being met by the system 2200 in a particular flow pathway arrangement (e.g., as determined based on monitoring temperature and/or performance of the compute unit(s), temperature of the coolant, etc.), the pathway arrangement determiner circuitry 2606 can determine to switch of the third coolant pathway arrangement 2422 of FIG. 24C and/or to increase the flow distribution ratio of the third coolant pathway arrangement 2422. In some examples, if the cooling demand of the compute units 2412A, 2412B are being over being over served (e.g., the compute units 2412A, 2412B, etc.), the pathway arrangement determiner circuitry 2606 can cause the system 2200 and/or the system 2500 to change in to coolant pathway arrangement that reduces the energy demand on the CDU 2208 (e.g., the second coolant pathway arrangement 2416 of FIG. 24B can have a lower energy demand than the third coolant pathway arrangement 2422 of FIG. 24C, higher flow distribution ratios of the third coolant pathway arrangement 2422 of FIG. 24C having a higher energy demand than the third coolant pathway arrangement 2422, etc.). In some examples, the pathway arrangement determiner circuitry 2606 is instantiated by programmable circuitry executing flow configuration instructions and/or configured to perform operations such as those represented by the flowchart of FIG. 27.

The system interface circuitry 2608 causes the system 2200 and/or the system 2500 to implement the coolant pathway arrangement determined by the pathway arrangement determiner circuitry 2606. For example, the system interface circuitry 2608 can cause one or more of the valves 2210A, 2210B, 2210C, 2210D of FIG. 22 and/or the CDU 2208 to assume the coolant pathway arrangement determined by the pathway arrangement determiner circuitry 2606 (e.g., by outputting instructions that are transmitted to valve control mechanisms). As used herein, “causing” a valve to move to a target position (e.g., an open position, a closed position, a partially open position, etc.) encompasses causing a valve to remain in a current position. For example, the system interface circuitry 2608 can cause a closed valve to close by causing the valve to remain closed (e.g., maintain a current signal to the valve, not sending an updated signal, etc.). For example, if the second coolant pathway arrangement 2416 of FIG. 24B was determined or selected by the pathway arrangement determiner circuitry 2606, the system interface circuitry 2608 can cause the first valve 2210A to open, cause the second valve 2210B to close, cause the third valve 2210C to open, and/or cause the fourth valve 2210D to close. For example, if the third coolant pathway arrangement 2422 of FIG. 24C was determined during the execution of block 2706, the system interface circuitry 2608 can cause the first valve 2210A to open, cause the second valve 2210B to close, cause the third valve 2210C to close, and/or cause the fourth valve 2210D to open. In some such examples, the system interface circuitry 2608 can cause the first valve 2210A and/or the fourth valve 2210D to move to different partially open positions to change the flow distribution ratio. In some examples, the system interface circuitry 2608 can adjust the power output of a pump of the CDU 2208 to adjust a flow rate of coolant through the tank 2204. In some examples, the system interface circuitry 2608 is instantiated by programmable circuitry executing system interface instructions and/or configured to perform operations such as those represented by the flowchart of FIG. 27.

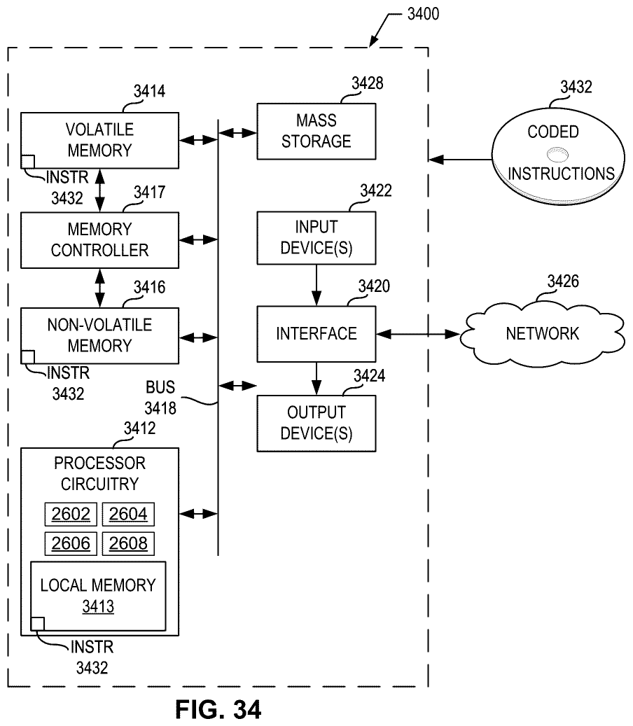

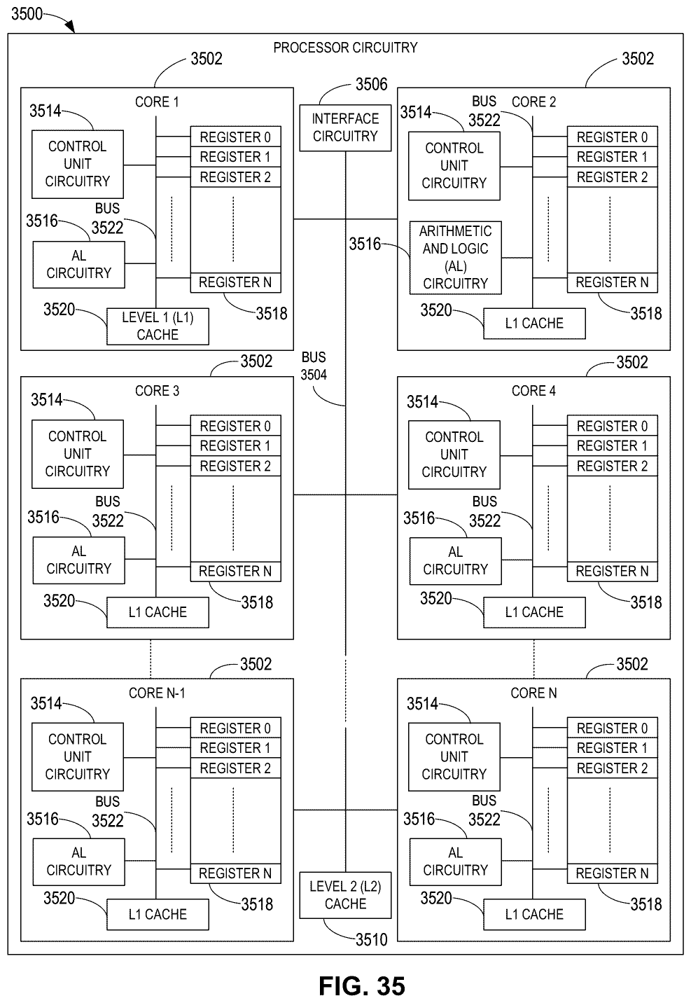

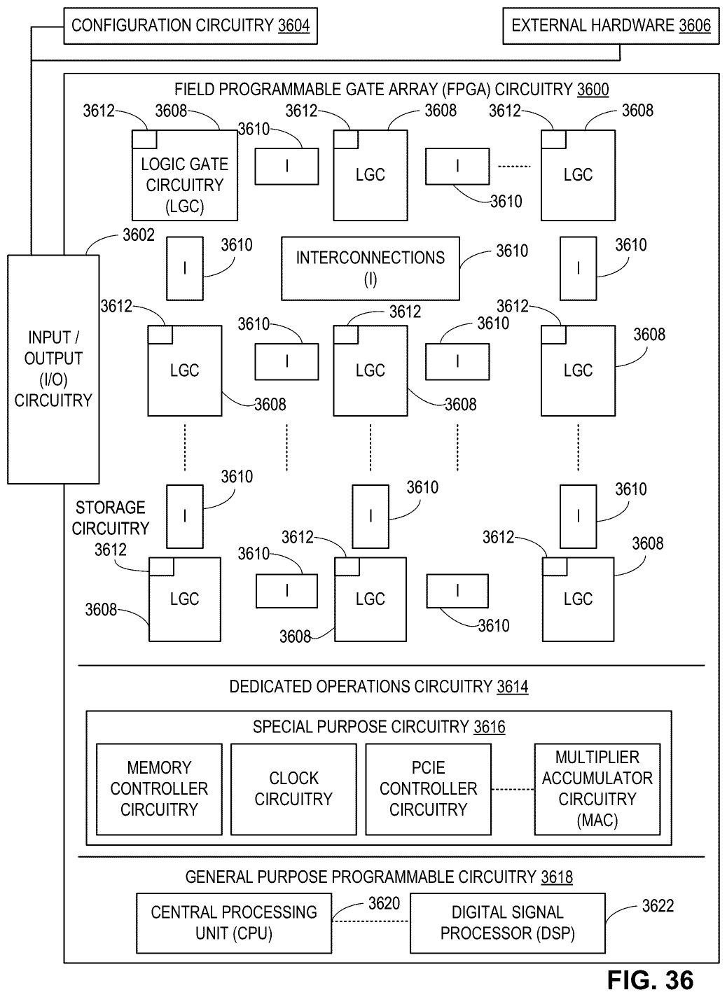

In some examples, the flow control circuitry 2202 includes means for interfacing with a sensor. For example, the means for interfacing with a sensor may be implemented by the sensor interface circuitry 2602. In some examples, the sensor interface circuitry 2602 may be instantiated by programmable circuitry such as the example programmable circuitry 3412 of FIG. 34. For instance, the sensor interface circuitry 2602 may be instantiated by the example microprocessor 3500 of FIG. 35 executing machine executable instructions such as those implemented by at least blocks 2702 of FIG. 27. In some examples, the sensor interface circuitry 2602 may be instantiated by hardware logic circuitry, which may be implemented by an ASIC, XPU, or the FPGA circuitry 3600 of FIG. 36 configured and/or structured to perform operations corresponding to the machine readable instructions. Additionally or alternatively, the sensor interface circuitry 2602 may be instantiated by any other combination of hardware, software, and/or firmware. For example, the sensor interface circuitry 2602 may be implemented by at least one or more hardware circuits (e.g., processor circuitry, discrete and/or integrated analog and/or digital circuitry, an FPGA, an ASIC, an XPU, a comparator, an operational-amplifier (op-amp), a logic circuit, etc.) configured and/or structured to execute some or all of the machine readable instructions and/or to perform some or all of the operations corresponding to the machine readable instructions without executing software or firmware, but other structures are likewise appropriate.

In some examples, the flow control circuitry 2202 includes means for determining a cooling demand. For example, the means for determining a cooling demand may be implemented by the cooling demand determiner circuitry 2604. In some examples, the cooling demand determiner circuitry 2604 may be instantiated by programmable circuitry such as the example programmable circuitry 3412 of FIG. 34. For instance, the cooling demand determiner circuitry 2604 may be instantiated by the example microprocessor 3500 of FIG. 35 executing machine executable instructions such as those implemented by at least blocks 2704 of FIG. 27. In some examples, the cooling demand determiner circuitry 2604 may be instantiated by hardware logic circuitry, which may be implemented by an ASIC, XPU, or the FPGA circuitry 3600 of FIG. 36 configured and/or structured to perform operations corresponding to the machine readable instructions. Additionally or alternatively, the cooling demand determiner circuitry 2604 may be instantiated by any other combination of hardware, software, and/or firmware. For example, the cooling demand determiner circuitry 2604 may be implemented by at least one or more hardware circuits (e.g., processor circuitry, discrete and/or integrated analog and/or digital circuitry, an FPGA, an ASIC, an XPU, a comparator, an operational-amplifier (op-amp), a logic circuit, etc.) configured and/or structured to execute some or all of the machine readable instructions and/or to perform some or all of the operations corresponding to the machine readable instructions without executing software or firmware, but other structures are likewise appropriate.

In some examples, the flow control circuitry 2202 includes means for determining a flow configuration. For example, the means for determining a flow configuration may be implemented by the pathway arrangement determiner circuitry 2606. In some examples, the pathway arrangement determiner circuitry 2606 may be instantiated by programmable circuitry such as the example programmable circuitry 3412 of FIG. 34. For instance, the pathway arrangement determiner circuitry 2606 may be instantiated by the example microprocessor 3500 of FIG. 35 executing machine executable instructions such as those implemented by at least blocks 2706 of FIG. 27. In some examples, the pathway arrangement determiner circuitry 2606 may be instantiated by hardware logic circuitry, which may be implemented by an ASIC, XPU, or the FPGA circuitry 3600 of FIG. 36 configured and/or structured to perform operations corresponding to the machine readable instructions. Additionally or alternatively, the pathway arrangement determiner circuitry 2606 may be instantiated by any other combination of hardware, software, and/or firmware. For example, the pathway arrangement determiner circuitry 2606 may be implemented by at least one or more hardware circuits (e.g., processor circuitry, discrete and/or integrated analog and/or digital circuitry, an FPGA, an ASIC, an XPU, a comparator, an operational-amplifier (op-amp), a logic circuit, etc.) configured and/or structured to execute some or all of the machine readable instructions and/or to perform some or all of the operations corresponding to the machine readable instructions without executing software or firmware, but other structures are likewise appropriate.

In some examples, the flow control circuitry 2202 includes means for interfacing with a CDU and/or valves. For example, the means for interfacing with a CDU and/or valves may be implemented by the system interface circuitry 2608. In some examples, the system interface circuitry 2608 may be instantiated by programmable circuitry such as the example programmable circuitry 3412 of FIG. 34. For instance, the system interface circuitry 2608 may be instantiated by the example microprocessor 3500 of FIG. 35 executing machine executable instructions such as those implemented by at least blocks 2708, 2710, 2712 of FIG. 27. In some examples, the system interface circuitry 2608 may be instantiated by hardware logic circuitry, which may be implemented by an ASIC, XPU, or the FPGA circuitry 3600 of FIG. 36 configured and/or structured to perform operations corresponding to the machine readable instructions. Additionally or alternatively, the system interface circuitry 2608 may be instantiated by any other combination of hardware, software, and/or firmware. For example, the system interface circuitry 2608 may be implemented by at least one or more hardware circuits (e.g., processor circuitry, discrete and/or integrated analog and/or digital circuitry, an FPGA, an ASIC, an XPU, a comparator, an operational-amplifier (op-amp), a logic circuit, etc.) configured and/or structured to execute some or all of the machine readable instructions and/or to perform some or all of the operations corresponding to the machine readable instructions without executing software or firmware, but other structures are likewise appropriate.

While an example manner of implementing the flow control circuitry 2202 of FIG. 22 is illustrated in FIG. 26, one or more of the elements, processes, and/or devices illustrated in FIG. 26 may be combined, divided, re-arranged, omitted, eliminated, and/or implemented in any other way. Further, the sensor interface circuitry 2602, the cooling demand determiner circuitry 2604, the pathway arrangement determiner circuitry 2606, the system interface circuitry 2608 and/or, more generally, the example flow control circuitry 2202 of FIG. 26, may be implemented by hardware alone or by hardware in combination with software and/or firmware. Thus, for example, any of the sensor interface circuitry 2602, the cooling demand determiner circuitry 2604, the pathway arrangement determiner circuitry 2606, the system interface circuitry 2608, and/or, more generally, the example flow control circuitry 2202, could be implemented by programmable circuitry in combination with machine readable instructions (e.g., firmware or software), processor circuitry, analog circuit(s), digital circuit(s), logic circuit(s), programmable processor(s), programmable microcontroller(s), graphics processing unit(s) (GPU(s)), digital signal processor(s) (DSP(s)), ASIC(s), programmable logic device(s) (PLD(s)), and/or field programmable logic device(s) (FPLD(s)) such as FPGAs. Further still, the example flow control circuitry of FIG. 26 may include one or more elements, processes, and/or devices in addition to, or instead of, those illustrated in FIG. 26, and/or may include more than one of any or all of the illustrated elements, processes and devices.

A flowchart representative of example machine readable instructions, which may be executed by programmable circuitry to implement and/or instantiate the flow control circuitry of FIG. 26 and/or representative of example operations which may be performed by programmable circuitry to implement and/or instantiate the flow control circuitry 2202 of FIG. 26, are shown in FIG. 27. The machine readable instructions may be one or more executable programs or portion(s) of one or more executable programs for execution by programmable circuitry such as the programmable circuitry 3412 shown in the example programmable circuitry platform 3400 discussed below in connection with FIG. 34 and/or may be one or more function(s) or portion(s) of functions to be performed by the example programmable circuitry (e.g., an FPGA) discussed below in connection with FIGS. 35 and/or 36. In some examples, the machine readable instructions cause an operation, a task, etc., to be carried out and/or performed in an automated manner in the real world. As used herein, “automated” means without human involvement.

The program may be embodied in instructions (e.g., software and/or firmware) stored on one or more non-transitory computer readable and/or machine readable storage medium such as cache memory, a magnetic-storage device or disk (e.g., a floppy disk, a Hard Disk Drive (HDD), etc.), an optical-storage device or disk (e.g., a Blu-ray disk, a Compact Disk (CD), a Digital Versatile Disk (DVD), etc.), a Redundant Array of Independent Disks (RAID), a register, ROM, a solid-state drive (SSD), SSD memory, non-volatile memory (e.g., electrically erasable programmable read-only memory (EEPROM), flash memory, etc.), volatile memory (e.g., Random Access Memory (RAM) of any type, etc.), and/or any other storage device or storage disk. The instructions of the non-transitory computer readable and/or machine readable medium may program and/or be executed by programmable circuitry located in one or more hardware devices, but the entire program and/or parts thereof could alternatively be executed and/or instantiated by one or more hardware devices other than the programmable circuitry and/or embodied in dedicated hardware. The machine readable instructions may be distributed across multiple hardware devices and/or executed by two or more hardware devices (e.g., a server and a client hardware device). For example, the client hardware device may be implemented by an endpoint client hardware device (e.g., a hardware device associated with a human and/or machine user) or an intermediate client hardware device gateway (e.g., a radio access network (RAN)) that may facilitate communication between a server and an endpoint client hardware device. Similarly, the non-transitory computer readable storage medium may include one or more mediums. Further, although the example program is described with reference to the flowchart illustrated in FIG. 27, many other methods of implementing the example flow control circuitry may alternatively be used. For example, the order of execution of the blocks of the flowchart may be changed, and/or some of the blocks described may be changed, eliminated, or combined. Additionally or alternatively, any or all of the blocks of the flow chart may be implemented by one or more hardware circuits (e.g., processor circuitry, discrete and/or integrated analog and/or digital circuitry, an FPGA, an ASIC, a comparator, an operational-amplifier (op-amp), a logic circuit, etc.) structured to perform the corresponding operation without executing software or firmware. The programmable circuitry may be distributed in different network locations and/or local to one or more hardware devices (e.g., a single-core processor (e.g., a single core CPU), a multi-core processor (e.g., a multi-core CPU, an XPU, etc.)). For example, the programmable circuitry may be a CPU and/or an FPGA located in the same package (e.g., the same integrated circuit (IC) package or in two or more separate housings), one or more processors in a single machine, multiple processors distributed across multiple servers of a server rack, multiple processors distributed across one or more server racks, etc., and/or any combination(s) thereof.

The machine readable instructions described herein may be stored in one or more of a compressed format, an encrypted format, a fragmented format, a compiled format, an executable format, a packaged format, etc. Machine readable instructions as described herein may be stored as data (e.g., computer-readable data, machine-readable data, one or more bits (e.g., one or more computer-readable bits, one or more machine-readable bits, etc.), a bitstream (e.g., a computer-readable bitstream, a machine-readable bitstream, etc.), etc.) or a data structure (e.g., as portion(s) of instructions, code, representations of code, etc.) that may be utilized to create, manufacture, and/or produce machine executable instructions. For example, the machine readable instructions may be fragmented and stored on one or more storage devices, disks and/or computing devices (e.g., servers) located at the same or different locations of a network or collection of networks (e.g., in the cloud, in edge devices, etc.). The machine readable instructions may require one or more of installation, modification, adaptation, updating, combining, supplementing, configuring, decryption, decompression, unpacking, distribution, reassignment, compilation, etc., in order to make them directly readable, interpretable, and/or executable by a computing device and/or other machine. For example, the machine readable instructions may be stored in multiple parts, which are individually compressed, encrypted, and/or stored on separate computing devices, wherein the parts when decrypted, decompressed, and/or combined form a set of computer-executable and/or machine executable instructions that implement one or more functions and/or operations that may together form a program such as that described herein.

In another example, the machine readable instructions may be stored in a state in which they may be read by programmable circuitry, but require addition of a library (e.g., a dynamic link library (DLL)), a software development kit (SDK), an application programming interface (API), etc., in order to execute the machine-readable instructions on a particular computing device or other device. In another example, the machine readable instructions may need to be configured (e.g., settings stored, data input, network addresses recorded, etc.) before the machine readable instructions and/or the corresponding program(s) can be executed in whole or in part. Thus, machine readable, computer readable and/or machine readable media, as used herein, may include instructions and/or program(s) regardless of the particular format or state of the machine readable instructions and/or program(s).

The machine readable instructions described herein can be represented by any past, present, or future instruction language, scripting language, programming language, etc. For example, the machine readable instructions may be represented using any of the following languages: C, C++, Java, C#, Perl, Python, JavaScript, HyperText Markup Language (HTML), Structured Query Language (SQL), Swift, etc.

As mentioned above, the example operations of FIG. 27 may be implemented using executable instructions (e.g., computer readable and/or machine readable instructions) stored on one or more non-transitory computer readable and/or machine readable media. As used herein, the terms non-transitory computer readable medium, non-transitory computer readable storage medium, non-transitory machine readable medium, and/or non-transitory machine readable storage medium are expressly defined to include any type of computer readable storage device and/or storage disk and to exclude propagating signals and to exclude transmission media. Examples of such non-transitory computer readable medium, non-transitory computer readable storage medium, non-transitory machine readable medium, and/or non-transitory machine readable storage medium include optical storage devices, magnetic storage devices, an HDD, a flash memory, a read-only memory (ROM), a CD, a DVD, a cache, a RAM of any type, a register, and/or any other storage device or storage disk in which information is stored for any duration (e.g., for extended time periods, permanently, for brief instances, for temporarily buffering, and/or for caching of the information). As used herein, the terms “non-transitory computer readable storage device” and “non-transitory machine readable storage device” are defined to include any physical (mechanical, magnetic and/or electrical) hardware to retain information for a time period, but to exclude propagating signals and to exclude transmission media. Examples of non-transitory computer readable storage devices and/or non-transitory machine readable storage devices include random access memory of any type, read only memory of any type, solid state memory, flash memory, optical discs, magnetic disks, disk drives, and/or redundant array of independent disks (RAID) systems. As used herein, the term “device” refers to physical structure such as mechanical and/or electrical equipment, hardware, and/or circuitry that may or may not be configured by computer readable instructions, machine readable instructions, etc., and/or manufactured to execute computer-readable instructions, machine-readable instructions, etc.

FIG. 27 is a flowchart representative of example machine readable instructions and/or example operations 2700 that may be executed, instantiated, and/or performed by programmable circuitry to regulate the flow of coolant through the system 2200 of FIG. 22 and/or the system 2500 of FIG. 25. The example machine-readable instructions and/or the example operations 2700 of FIG. 3 begin at block 2702, at which the sensor interface circuitry 2602 accesses sensor data from the sensors 2206. For example, the sensor interface circuitry 2602 can retrieve, receive, and/or otherwise the output(s) of the sensors 2206 of FIGS. 22 and 26 and/or one or more sensors of the system 2200 of FIG. 22 and/or the system 2500 of FIG. 25. For example, the sensor interface circuitry 2602 can access data related to the temperature of the coolant in portions of the tank 2204, a temperature of the compute units 2412A, 2412B, a flow rate of coolant, etc. In some examples, the sensor interface circuitry 2602 can interface with one or more of the valves 2210A, 2210B, 2210C, 2210D of the system 2200 and/or the valves 2502, 2504 of the system 2500 to determine a current position of one or more of the 2210A, 2210B, 2210C, 2210D and/or the valves 2502, 2504.

At block 2704, the cooling demand determiner circuitry 2604 determines the cooling demand (e.g., the cooling needs, the heat output, etc.) of one or more of the compute unit(s) of the system 2200 and/or the system 2500. For example, the cooling demand determiner circuitry 2604 can determine the cooling demand of the compute units 2412A, 2412B via the sensor data accessed by the sensor interface circuitry 2602. For example, cooling demand determiner circuitry 2604 can measure the temperature and/or thermal output of the compute units 2412A, 2412B via a temperature sensor of the sensors 2206 (e.g., a temperature sensor disposed on and/or incorporated into one of the compute units 2412A, 2412B, a temperature sensor disposed in a flow path downstream of the compute units 2412A, 2412B, etc.). Additionally or alternatively, the cooling demand determiner circuitry 2604 can determine the cooling demand of one or both of the compute units 2412A, 2412B based on a current processing load (e.g., the utilization of the processing resources, a number of queued computation tasks, etc.) of the compute units 2412A, 2412B.

At block 2706, the pathway arrangement determiner circuitry 2606 determines the flow configuration, arrangement, or architecture based on the cooling demand(s) of the compute unit 2412A, 2412B, and/or the sensor data. For example, the pathway arrangement determiner circuitry 2606 can determine whether to operate in the second coolant pathway arrangement 2416 of FIG. 24B and/or the third coolant pathway arrangement 2422 of FIG. 24C. In some examples, the pathway arrangement determiner circuitry 2606 can also determine a position of the valves (e.g., open, closed) in the selected coolant pathway arrangement.

At block 2708, the system interface circuitry 2608 determines if the system 2200 (or the system 2500 of FIG. 25, etc.) is in the determined coolant pathway arrangement. For example, the system interface circuitry 2608 can determine if one or more of the valves 2210A, 2210B, 2210C, 2210D of the system 2200 of FIG. 22 and/or the valves 2502, 2504 of the system 2500 of FIG. 25 are in positions associated with the coolant pathway arrangement determined, selected, or otherwise identified during the execution of block 2706. If the system interface circuitry 2608 determines that the system 2200 (or the system 2500 of FIG. 25) is in the selected coolant pathway arrangement, the operations 2700 advance to block 2712. If the system interface circuitry 2608 determines the system 2200 (or the system 2500 of FIG. 25) is not in the determined coolant pathway arrangement, the operations 2700 advance to block 2712.

At block 2710, the system interface circuitry 2608 causes the valves 2210A, 2210B, 2210C, 2210D (or the valves 2502, 2504) and/or the CDU 2208 to assume the determined coolant pathway arrangement. For example, if the second coolant pathway arrangement 2416 of FIG. 24B was determined or selected during the execution of block 2706, the system interface circuitry 2608 can cause the first valve 2210A to open, cause the second valve 2210B to close, cause the third valve 2210C to open, and/or cause the fourth valve 2210D to close. For example, if the third coolant pathway arrangement 2422 of FIG. 24C was determined during the execution of block 2706, the system interface circuitry 2608 can cause the first valve 2210A to open, cause the second valve 2210B to close, cause the third valve 2210C to close, and/or cause the fourth valve 2210D to open. In some such examples, the system interface circuitry 2608 can cause the first valve 2210A and/or the fourth valve 2210D to move to different partially open positions to change the flow distribution ratio. In some examples, the system interface circuitry 2608 can adjust the power output of a pump of the CDU 2208 to adjust a flow rate of coolant through the tank 2204.

At block 2712, the system interface circuitry 2608 determines if the system 2200 and/or the system 2500 are to continue to be monitored. For example, the system interface circuitry 2608 can determine if the system 2200 and/or the system 2500 is still operating (e.g., in a powered on state, etc.). For example, the system interface circuitry 2608 can determine whether the system 2200 and/or the system 2500 has reached a steady state condition (e.g., no substantial changes in the output of the sensors 2206, etc.). If the system interface circuitry 2608 determines monitoring is to be continued, the operations 2700 return to block 2702. If the system interface circuitry 2608 determines monitoring is not to be continued, the operations 2700 end.

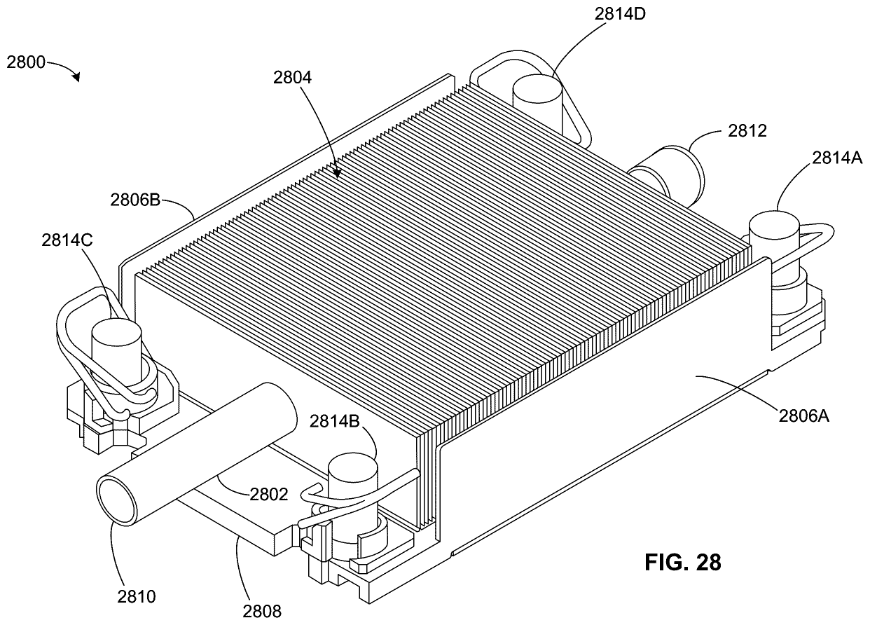

FIG. 28 is a perspective view of an example heat sink assembly 2800 in accordance with teachings of this disclosure. In the illustrated example of FIG. 28, the heat sink assembly 2800 includes an example tube 2802, example fins 2804, an example first side wall 2806A, an example second side wall 2806B, and an example base plate 2808. In the illustrated example of FIG. 28, the tube 2802 includes an example inlet 2810 and an example end 2812. In the illustrated example of FIG. 28, the heat sink assembly 2800 includes an example first fastener 2814A, an example second fastener 2814B, an example third fastener 2814C, and an example third fastener 2814D. The heat sink assembly 2800 can be coupled to an integrated circuit (IC) package, a compute component, and/or a chassis via the fasteners 2814A, 2814B, 2814C, 2814D to dissipate heat therefrom.

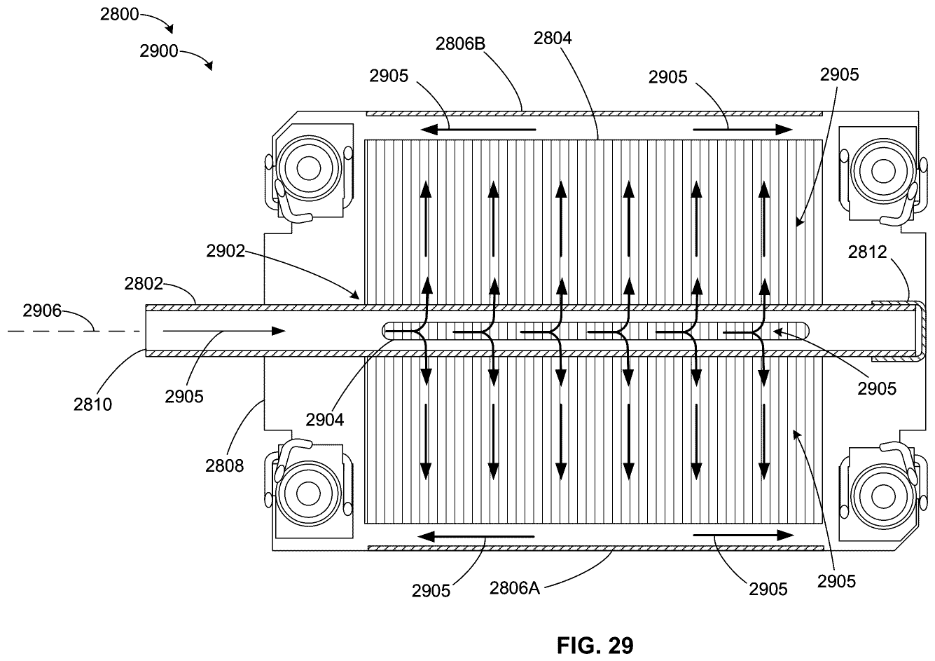

The tube 2802 receives coolant and directs the coolant into the heat sink assembly 2800. In the illustrated example of FIG. 28, the tube 2802 extends through the fins 2804 between the inlet 2810 and the end 2812. The tube 2802 includes one or more internal openings (see FIGS. 29-31) that distribute coolant into the fins 2804. In the illustrated example of FIG. 28, the tube 2802 has a generally circular cross-section. In other examples, the tube 2802 can have any suitable shape. In some examples, the tube 2802 is a flexible tube (e.g., a rubber tube, a plastic tube, etc.). Additionally or alternatively, the tube 2802 can be rigid or substantially rigid (e.g., a metal pipe, a rigid plastic tube, etc.). In some examples, the tube 2802 can be insulated to reduce heat transfer between the coolant in the corresponding ones of the tube 2802 and the ambient environment (e.g., the flow through a tank, the flow the interior of the chassis, etc.).

In some examples, the inlet 2810 of the tube 2802 can be coupled to a coolant manifold of an immersion cooling tank and/or directly to an inlet of the immersion cooling tank coupled to a CDU. Additionally or alternatively, the inlet 2810 of the tube 2802 can receive coolant from any suitable coolant location that is upstream within an immersion cooling tank. In some examples, the tube 2802 can be coupled to a pump to drive coolant through the heat sink assembly 2800 (e.g., a pump incorporated into the heat sink assembly 2800, a pump of a CDU, a pump of the immersion cooling tank including the heat sink assembly 2800, etc.). Example internal structures of the tube 2802 are disclosed below in conjunction with FIGS. 29-31.

The fins 2804 absorb heat from the base plate 2808 (e.g., vapor chamber of incorporated into the base plate 2808, heat pipes in the base plate 2808, etc.) and dissipate the heat into the coolant flowing through the heat sink assembly 2800 and the ambient environment. In the illustrated example of FIG. 28, the fins 2804 extend from the base plate 2808. In the illustrated example of FIG. 28, the fins 2804 define a plurality of channels between individual ones of the fins. In the illustrated example of FIG. 28, the fins 2804 include 44 fins, each having a uniform thickness of 0.3 millimeters (mm) and a uniform spacing (e.g., pitch, etc.) of 1.8 mm.

In other examples, the fins 2804 can include another suitable number of fins (e.g., 5 fins, 10 fins, 50 fins, 100 fins, etc.) that can have a non-uniform spacing (e.g., ones of the fins 2804 distal to the inlet 2810 can have a greater spacing than ones of the fins adjacent to the inlet 2810 to reduce flow impedance of coolant flowing through the heat sink assembly 2800, etc.) and/or a non-uniform thickness. In some examples, the spacing and height of the fins 2804 can be determined based on the thermal design power of the integrated circuit and the desired head loss of coolant flowing through the heat sink. In some examples, the fins 2804 can be dimensioned based on the dimensions of a chassis containing the heat sink assembly 2800 (e.g., abutting a front wall of the chassis, forming a small gap with the front chassis, etc.). In some examples, the fins 2804 are composed of a thermally conductive material, such as copper and/or aluminum.

The side walls 2806A, 2806B direct the flow of coolant exiting the fins 2804. In the illustrated example of FIG. 28, the side walls 2806A, 2806B extend from the base plate 2808. In the illustrated example of FIG. 28, the fins 2804 are disposed between the side walls 2806A, 2806B. In some examples, one or more of the side walls 2806A, 2806B are absent. In some such examples, the coolant can directly enter the ambient flow of coolant through the immersion cooling tank and/or the interior of a chassis containing the heat sink assembly 2800 after flowing through the fins 2804.

In the example of FIG. 28, the base plate 2808 of the heat sink assembly 2800 abuts an integrated circuit (IC) package (e.g., a CPU, etc.). For example, the base plate 2808 can be in thermal contact with the integrated heat sink IHS of an IC package. In some examples, a thermally conductive paste (e.g., a thermal interface material 1 (TIM1), etc.) is disposed between the base plate 2808 and the IHS to facilitate (e.g., increase, etc.) the rate of conduction between the IC package and the heat sink assembly 2800. In some examples, the base plate 2808 can include one or more heat-spreading devices (e.g., heat pipes, a vapor chamber, etc.) to increase the heat transfer between the IC package and the components of the heat sink assembly 2800. In some such examples, a thermal interface material 2 (TIM2) can be disposed between the heat-spreading device and the base plate 2808. In some examples, the base plate 2808 is composed of a thermally conductive material (e.g., copper, aluminum, etc.).

In the illustrated example of FIG. 28, the fins 2804, the side walls 2806A, 2806B, and the base plate 2808 are integrally defined. In some such examples, the fins 2804, the side walls 2806A, 2806B, and the base plate 2808 can be manufactured via machining (e.g., milling a blank, etc.), extrusion, and/or via additive manufacturing. In other examples, the fins 2804, the side walls 2806A, 2806B, and the base plate 2808 can be discrete components that are coupled together via one or more welds, one or more interference fits, one or more fasteners, and/or one or more mechanical retainers.

The fasteners 2814A, 2814B, 2814C, 2814D can couple the heat sink assembly 2800 to a chassis and/or other components associated with a compute node (e.g., the bolster plate of a CPU, the back plate of a CPU, etc.). In the illustrated example of FIG. 28, the fasteners 2814A, 2814B, 2814C, 2814D are coupled to the base plate 2808. In other examples, the fasteners 2814A, 2814B, 2814C, 2814D can be fixedly coupled to any other portion of the heat sink assembly 2800. In the illustrated example of FIG. 28, the fasteners 2814A, 2814B, 2814C, 2814D are polyetheretherketone (PEEK) nuts including anti-tilt features. In other examples, the fasteners 2814A, 2814B, 2814C, 2814D be implemented by any other suitable fasteners.

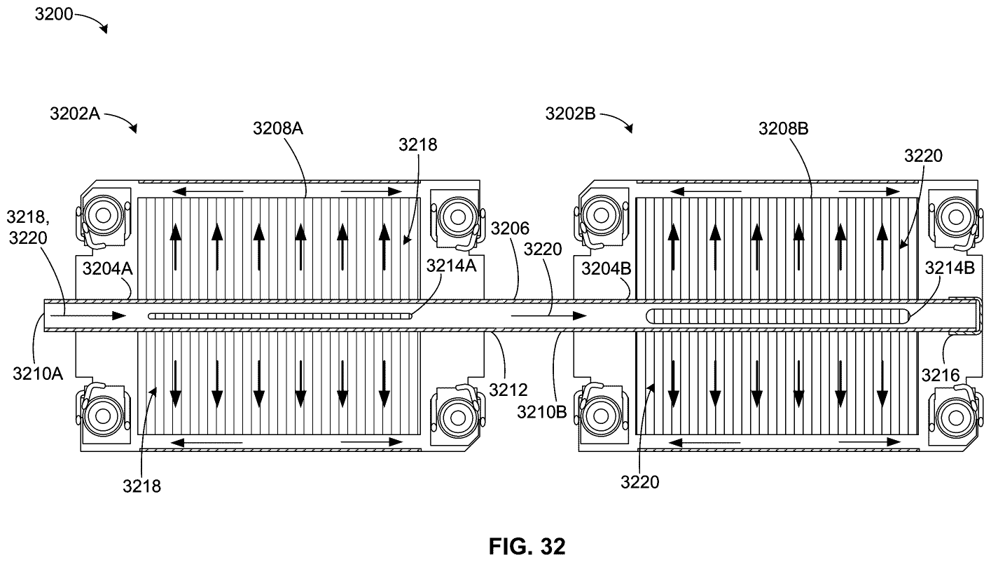

The heat sink assembly 2800 can be disposed with the free flow of coolant through the immersion cooling tank and/or within an interior of a chassis disposed within an immersion cooling tank. During operation, coolant enters the heat sink assembly 2800 through the inlet 2810. The coolant flows through tube 2802 and then through the plurality of channels between the fins 2804. Heat in the fins 2804 is absorbed via convection into the coolant, thereby cooling the heat sink assembly 2800 (e.g., via convection, via conduction, etc.) and the integrated circuit coupled thereto. After exiting the channels between the fins 2804, the coolant is guided by the side walls 2806A, 2806B into the ambient flow of coolant through the immersion cooling tank and/or the chassis including the heat sink assembly 2800. It should be appreciated that a portion of the coolant can leave the heats sink assembly 2800 via a top of the fins 2804 (e.g., the portion of the fins 2804 opposite the base plate 2808, etc.). In the illustrated example of FIG. 28, the end 2812 of the tube 2802 is closed (e.g., sealed, etc.). For example, the closed portion of the end 2812 can include a discrete cap and/or can be formed integrally with the tube 2802. As such, all coolant that enters the tube 2802 via the inlet 2810 exits the heat sink assembly 2800 by flowing through the fins 2804. In other examples, the end 2812 can be coupled to another heat sink assembly downstream of the heat sink assembly 2800. An example system including two heat sink assemblies is described below in conjunction with FIG. 32.

FIG. 29 is a cross-sectional top view of the example heat sink assembly 2800 of FIG. 28 depicting an example first internal structure 2900 of the fins 2804 of FIG. 28 and the tube 2802 of FIG. 28. In the illustrated example of FIG. 29, the tube 2802 extends through an example hole 2902 defined in the first internal structure 2900. In the illustrated example of FIG. 29, the tube 2802 includes an example slot 2904. In the illustrated example of FIG. 29, the inlet 2810, the tube 2802, the slot 2904, the fins 2804, and the side walls 2806A, 2806B sequentially define an example coolant pathway 2905.

In the illustrated example of FIG. 29, the hole 2902 extends through the fins 2804. In the illustrated example of FIG. the hole 2902 and the tube 2802 inserted therein are disposed along an example centerline axis 2906 of the heat sink assembly 2800. However, in other examples, the hole 2902 and the tube 2802 can be offset from the centerline axis 2906. In some examples, the tube 2802 can be fixed coupled within the hole 2902 via one or more welds and/or chemical adhesives. For example, an example outer diameter of the tube 2802 can be welded and/or soldered to fins located along or proximate to the hole 2902. In the illustrated example of FIG. 29, the centerline axis 2906 extends perpendicularly through the fins 2804.

The slot 2904 is an egress slot that enables the coolant flowing through the tube 2802 to exit (e.g., egress, etc.) the tube 2802 and enter the channels from between the fins 2804. In the illustrated example of FIG. 29, the slot 2904 is formed on the tube 2802 in the portion of the tube 2802 within the hole 2902 (e.g., the slot 2904 is fully within the fins 2804, etc.). In the illustrated example of FIG. 29, the tube 2802, the hole 2902, and slot 2904 are aligned with the centerline axis 2906. In some examples, because an IC can cause a center of a bottom plate (e.g., the core, etc.) of the IC to increase in temperature (e.g., become the hottest part) more than other parts if the IC, the slot 2904 distributes coolant to the portion of the heat sink assembly 2800 with the most heat (e.g., the hottest portion, etc.), which can increase the efficacy of the heat sink assembly 2800 (e.g., the coldest coolant is directed to the hottest part of the heat sink assembly 2800 by the tube 2802 and the slot 2904, etc.).

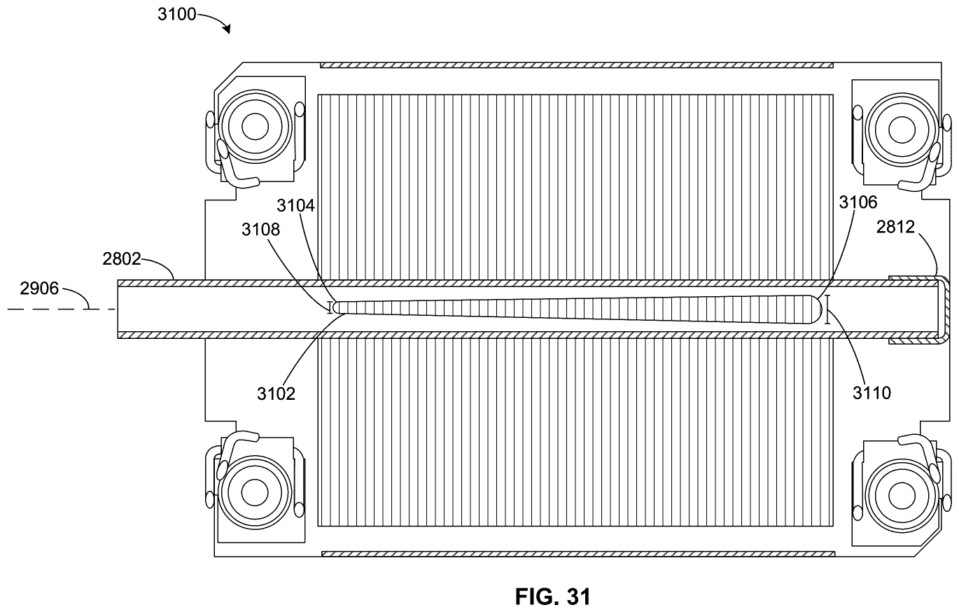

In the illustrated example of FIG. 29, the slot 2904 is stadium shaped (e.g., pilled shaped, disco-rectangular, etc.). In the illustrated example of FIG. 29, the slot 2904 is 3 mm wide and formed in a ⅜ inch copper tube. In other examples, the slot 2904 can have any other suitable size and shape. For example, the slot 2904 can be shaped to change the distribution of coolant between ones of the fins 2804. An example heat sink assembly including a differently shaped slot is disclosed below in conjunction with FIG. 31. In the illustrated example of FIG. 29, the slot 2904 is disposed on a portion of the tube 2802 that is adjacent to the base plate 2808. Additionally or alternatively, the tube 2802 can include one or more slot(s) disposed on a portion of the tube 2802 that is distal to the base plate 2808 (e.g., a portion of the tube opposite the slot 2904, etc.), a portion of the tube 2802 adjacent to the first side wall 2806A, and/or a portion of the tube 2802 adjacent to the second side wall 2806B.

In the illustrated example of FIG. 29, the coolant pathway 2905 defines the flow path of coolant through the internal structure 2900. In the illustrated example of FIG. 29, the coolant pathway 2905 is illustrated as thick black lines. In the illustrated example of FIG. 29, the coolant pathway 2905 begins at the inlet 2810, through the tube 2802, leaves the tube 2802 via the slot 2904, and flows through the fins 2804. After leaving the fins 2804, the coolant pathway 2905 extends along the side walls 2806A, 2806B and leaves the heat sink assembly 2800. It should be appreciated that a portion of the coolant pathway 2905 can leave via a top of the fins 2804 (e.g., out of the page, etc.).

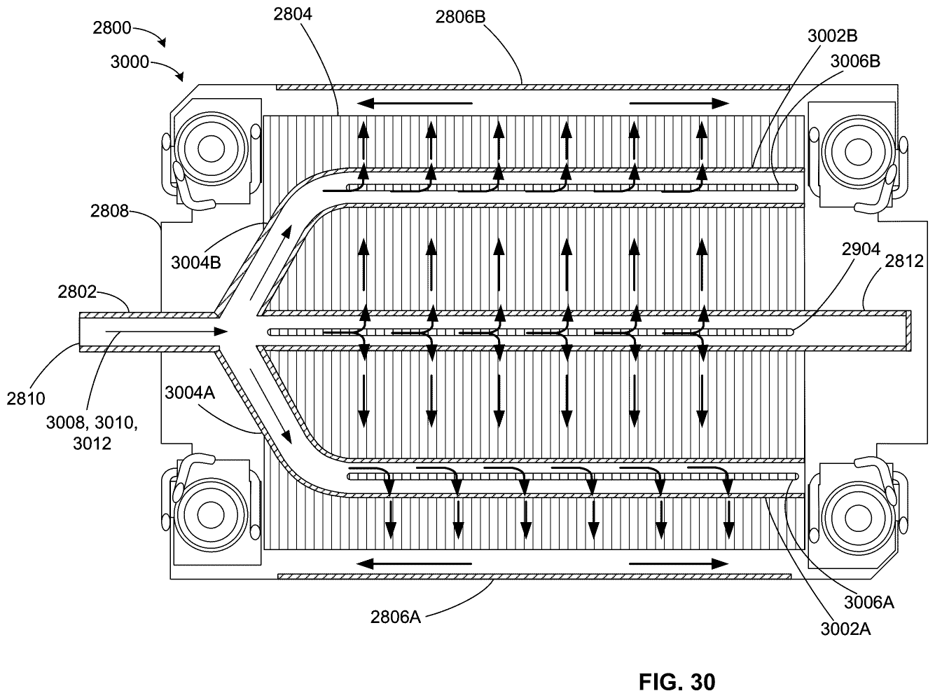

FIG. 30 is a cross-sectional top view of another example second internal structure 3000 that can be used with the heat sink assembly 2800 of FIG. 28. In the illustrated example of FIG. 30, the second internal structure 3000 includes the slot 2904 of FIG. 29. The second internal structure 3000 is similar to the first internal structure 2900 of FIG. 29, except that the second internal structure 3000 includes an example first arm 3002A and an example second arm 3002B and as otherwise noted. In the illustrated example of FIG. 30, the arms 3002A, 3002B are coupled to the tube 2802 (referred to as the “main tube” in conjunction with FIG. 30) via an example first joint 3004A and an example second joint 3004B, respectively. In the illustrated example of FIG. 30, the arms 3002A, 3002B include an example first arm slot 3006A and an example second arm slot 3006B.

The arms 3002A, 3002B, also referred to herein as “branch tubes” or “branches,” distribute the coolant to other locations within the heat sink assembly 2800 and/or the fins 2804. In some examples, the arms 3002A, 3002B and/or the joints 3004A, 3004B can be flexible members, which are fed through holes in the fins 2804. In the illustrated example of FIG. 30, the arms 3002A, 3002B have the same size (e.g., ¾ inch outer diameter, etc.) and shape (e.g., cylindrical, etc.) as the tube 2802. In other examples, the arms 3002A, 3002B can have a different size than the tube 2802 (e.g., smaller than the tube 2802, etc.). In the illustrated example of FIG. 30, the arms 3002A, 3002B are disposed at a same vertical height relative to the base plate 2808 as the tube 2802. In other examples, the arms 3002A, 3002B can be vertically displaced from the tube 2802. For example, the first arm 3002A is located closer to the base plate 2808 than the tube 2802 and the second arm 3002B can be further from the base plate 2808 and downward from the tube 2802. The joints 3004A, 3004B couple the arms 3002A, 3002B, respectively, to the tube 2802. In the illustrated example of FIG. 30, the joints 3004A, 3004B do not include the slots 3006A, 3006B, respectively. In other examples, the joints 3004A, 3004B can include slots. In some examples, the slots 3006A, 3006B and the slot 2904 can be continuous.

The arm slots 3006A, 3006B are egress slots that enable the distribution of coolant throughout the fins 2804. In the illustrated example of FIG. 30, the arm slots 3006A, 3006B are parallel and the arms 3002A, 3002B are parallel. In the illustrated example of FIG. 30, the arm slots 3006A, 3006B are stadium-shaped and have a uniform width along the length of the arms 3002A, 3002B. In other examples, the arm slots 3006A, 3006B can have any other suitable size and shape and the slots 3006A, 3006B can have any other suitable geometric relationship with the slot 2904. For example, the arm slots 3006A, 3006B can be shaped to change the distribution of coolant between ones of the fins 2804. In the illustrated example of FIG. 30, the arm slots 3006A, 3006B are disposed on portions of the arms 3002A, 3002B that is adjacent to the base plate 2808. In other examples, one or both of the arm slots 3006A, 3006B can be disposed on any other suitable location of the arms 3002A, 3002B.

During operation, coolant enters the tube 2802 via the inlet 2810. An example first portion 3008 of the coolant flows through the tube 2802 exits the first tube 2802 via the first slot 2904 and flows through the fins 2804 (e.g., primarily cooling the center of the heat sink 2800, etc.). An example second portion 3010 exits the tube 2802 via the second joint 3004B and enters the second arm 3002B. The second portion 3010 of coolant exits the first arm 3002B via the second arm slot 3006B and flows through the fins 2804 (e.g., primarily cooling the heat sink 2800 near the second side wall 2806B, etc.). An example third portion 3012 exits the tube 2802 via the second joint 3004B and enters the second arm 3002B. The third portion 3012 of coolant exits the second arm 3002B via the third arm slot 3006A and flows through the fins 2804 (e.g., primarily cooling the heat sink 2800 near the first side wall 2806A, etc.). While flow exiting the arm slots 3006A, 3006B is depicted as flowing toward the side walls 2806A, 2806B, respectively, in the illustrated example of FIG. 30, it should be appreciated that flow existing the arm slots 3006A, 3006B can flow in other directions (e.g., toward the tube 2802, out of the page via a top of the fins 2804, etc.).

FIG. 31 is a cross-sectional top view of an example third internal structure 3100 that can be used in conjunction with the heat sink assembly 2800 of FIG. 28. The third internal structure 3100 is similar to the first internal structure 2900 of FIG. 29, except that the third internal structure 3100 includes an example slot 3102. In the illustrated example of FIG. 31, the slot 3102 is disposed on a bottom portion of the tube 2802 and is aligned with the centerline axis 2906 of the tube 2802 and heat sink assembly 2800. In other examples, the slot 3102 can be disposed on another portion of the tube 2802 and can have any other suitable relationship with the centerline axis 2906.

In the illustrated example of FIG. 31, the slot 3102 is tapered along the length of the tube 2802. That is, the slot 3102 includes an example first end 3104 having an example first width 3106 and an example second end 3108 having an example second width 3110 that is greater than the first width 3106 (e.g., the first width 3106 is lesser than the second width 3110, etc.). In some examples, given that coolant exits the tube 2802 via the slot 3102 as the coolant flows through the tube 2802, the pressure and volume of coolant decreases along the length the tube 2802 to the end 2812 of the tube 2802. In some examples, because the second width 3110 is greater than the first width 3106, the increased size of the slot 3102 can equalize the volume of coolant exiting the slot 3102 at each location along the tube 2802 (e.g., equal volumes of coolant leave the slot 3102 at the first end 3104, the second end 3108, and at the center of the slot 3102, etc.). In the illustrated example of FIG. 31, the width of the slot 3102 increases linearly between the first end 3104 and the second end 3108. In other examples, the width of the slot 3102 can increase via a series of discrete steps, exponentially, and/or logarithmically along the length of the slot 3102.

FIG. 32 is a cross-sectional top view of an example system 3200 including a plurality of heat sink assemblies in accordance with teachings of this disclosure. In the illustrated example of FIG. 32, the system 3200 includes an example first heat sink assembly 3202A and an example second heat sink assembly 3202B. In the illustrated example of FIG. 32, the heat sink assemblies 3202A, 3202B include an example first tube 3204A and an example second tube 3204B, respectively, and are coupled via an example inter-assembly tube 3206 (e.g., a third tube, etc.). In the illustrated example of FIG. 32, the heat sink assemblies 3202A, 3202B are similar to the heat sink assembly 2800 of FIG. 28 and include example first fins 3208A and example second fins 3208B, respectively. In the illustrated example of FIG. 32, the first tube 3204A includes an example first inlet 3210A, an example outlet 3212, and an example first slot 3214A. In the illustrated example of FIG. 32, the second tube 3204B includes an example second inlet 3210B, an example second slot 3214B, and an example end 3216.

In the illustrated example of FIG. 32, the heat sink assemblies 3202A, 3202B include internal structures similar to the first internal structure 2900 of FIG. 29. In other examples, one or both the heat sink assemblies can be similar to the second internal structure 3000 of FIG. 30 (e.g., includes multiple tubes within the fins 3208A, 3208B, etc.) and/or similar to the third internal structure 3100 of FIG. 31 (e.g., includes a taper slot, etc.).

The inter-assembly tube 3206 fluidly couples the first tube 3204A to the second tube 3204B. In the illustrated example of FIG. 32, the inter-assembly tube 3206 extends between and is coupled to the outlet 3212 of the first tube 3204A and the second inlet 3210B of the second tube 3204B. During operation, coolant enters the first tube 3204A via the first inlet 3210A. An example first portion 3218 of the coolant exits the first tube 3204A via the first slot 3214A and flows through the first fins 3208A, which cools the first heat sink assembly 3202A. An example second portion 3220 of the coolant exits the first tube 3204A via the first outlet 3212 and enters the inter-assembly tube 3206. The second portion 3220 exits the inter-assembly tube 3206 and enters the second tube 3204B of the second heat sink assembly 3202B via the second inlet 3210B. Because the end 3216 of the second tube 3204B is closed (e.g., sealed, etc.), the second portion 3220 of the coolant exits the second tube 3204B via the second slot 3214B and flows through the second fins 3208B, which cools the second heat sink assembly 3202B.

The size (e.g., the area, etc.) of the slots 3214A, 3214B regulates the relative size of the relative volumes (e.g., flow rates, etc.) of the portions 3218, 3220. In the illustrated example of FIG. 32, the second slot 3214B is wider than the first slot 3214A. It should be appreciated that because the loss of pressure (e.g., caused by the first portion 3218 existing the first slot 3214A and friction within the tubes 3204A, 3204B, 3206, etc.), the second slot 3214B is larger than the first slot 3214A to cause the first portion 3218 to be approximately equal to the second portion 3220. In other examples, the first slot 3214A and the second slot 3214B can be approximately equal in size, which causes the first portion 3218 to be greater than the second portion 3220. In other examples, the first slot 3214A and the second slot 3214B can have any other suitable sizes. In the illustrated example of FIG. 32, the slots 3214A, 3214B are illustrated as having constant widths along the length of the tubes 3204A, 3204B, respectively. In other examples, one or both of the slots 3214A, 3214B can have variable lengths (e.g., one or both of the slots 3214A, 3214B can be tapered in a similar manner as the slot 3102 of FIG. 31, etc.).

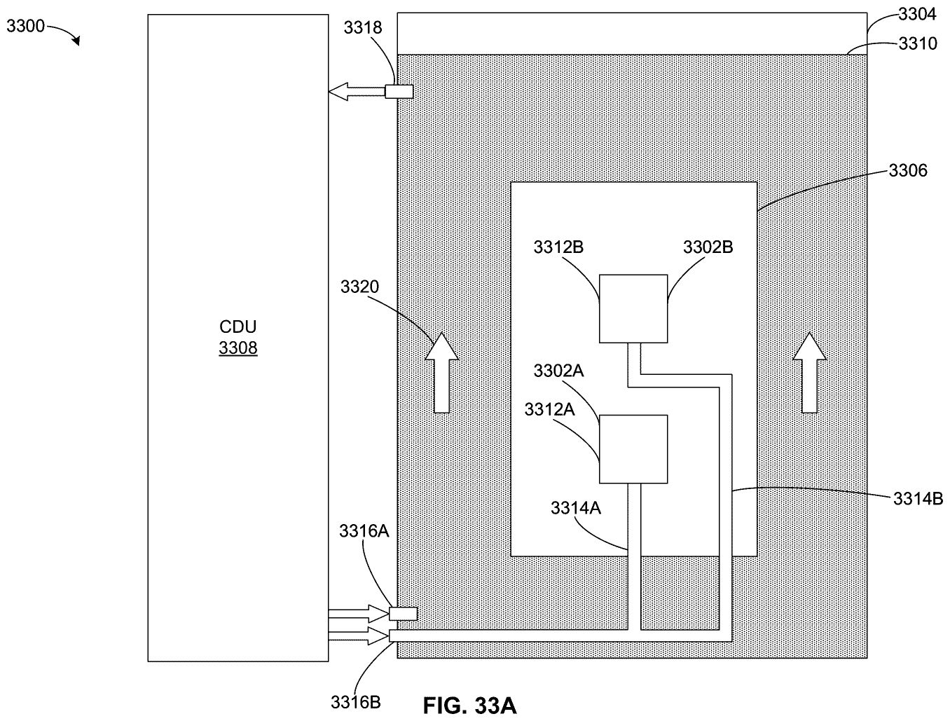

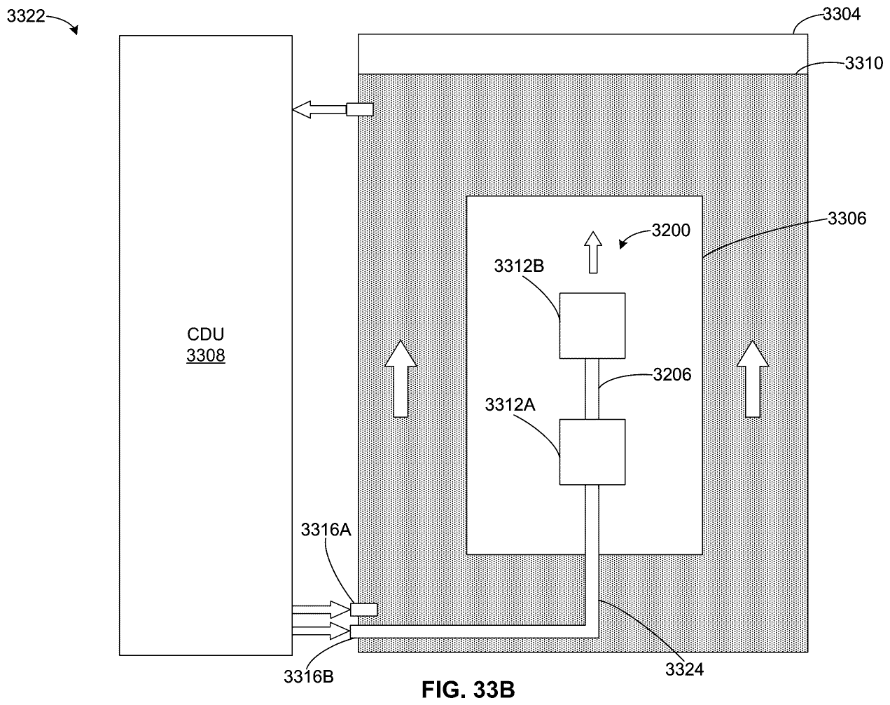

The system 3200 can be used in systems with multiple compute units. For example, the system 3200 can be used with a chassis having a shadowed compute unit form factor (e.g., the chassis 1704 of FIGS. 17A and 17B, etc.). In some such examples, the first heat sink assembly 3202A can be coupled to a first compute unit and the second heat sink assembly 3202B can be coupled to a second compute unit that is downstream in the immersion cooling tank relative to the first compute unit. An example cooling system including the system 3200 is described below in conjunction with FIG. 33B. While the system 3200 of FIG. 32 includes two heat sink assemblies (e.g., the heat sink assemblies 3202A, 3202B, etc.), in other examples, the system 3200 can include additional heat sink assemblies (e.g., three heat sink assemblies, four heat sink assemblies, ten heat sink assemblies, etc.). In some such examples, the system 3200 can include additional inter-assembly tubes, which can be coupled to the end 3216.

FIG. 33A is a schematic view of an example first cooling system 3300 that includes an example first heat sink assembly 3302A and an example second heat sink assembly 3302B. In the illustrated example of FIG. 33A, the first cooling system 3300 includes an example tank 3304, an example chassis 3306, an example CDU 3308, and example coolant 3310. In the illustrated example of FIG. 33A, the chassis 3306 includes an example first compute unit 3312A and an example compute unit 3312B, which are cooled via the first heat sink assembly 3302A and the second heat sink assembly 3302B, respectively. The heat sink assemblies 3302A, 3302B receive coolant via example first piping 3314A and example second piping 3314B, respectively.

In the illustrated example of FIG. 32A, the first compute unit 3312A and the second compute unit 3312B of the chassis 3306 are in a shadowed form factor (e.g., the first compute unit 3312A and the second compute unit 3312B are disposed at different locations along the flow path of the coolant 3310 within the tank 3304. In other examples, the compute units in the chassis 3306 can have any other suitable configuration (e.g., spreadcore, etc.). One or both of the heat sink assembly 3302A and the second heat sink assembly 3302B can be implemented by the heat sink assembly 2800 of FIG. 28, which can have the first internal structure 2900 of FIG. 29, the second internal structure 3000 of FIG. 30, and/or the third internal structure 3100 of FIG. 31.

In the illustrated example of FIG. 33A, the tank 3304 include an example first inlet 3316A, an example second inlet 3316B, and an example outlet 3318. In the illustrated example of FIG. 33A, the first inlet 3316A directs coolant from the CDU 3308 into an example main flow path 3320 through the tank 3304, which is exhausted from the tank 3304 via the outlet 3318. In the illustrated example of FIG. 33B, the second inlet 3316B directs coolant from the CDU 3308 into the piping 3314A, 3314B, which are coupled to the heat sink assembly 3302A, 3302B, respectively. After flowing through the heat sink assemblies 3302A, 3302B and cooling the compute units 3312A, 3312B, the coolant is returned into the main flow path 3320 and exhausted from the tank 3304 via the outlet 3318. In the illustrated example of FIG. 33A, both of the piping 3314A, 3314B are coupled to a same inlet (e.g., the second inlet 3316B, etc.). In other examples, the piping 3314A, 3314B can be coupled to separate outlets.

FIG. 33B is a schematic view of an example second cooling system 3322. In the illustrated example of FIG. 33B, the second cooling system 3322 includes the tank 3304 of FIG. 33A, the chassis 3306 of FIG. 33A, the CDU 3308 of FIG. 33A, the coolant 3310 of FIG. 33, the first compute unit 3312A of FIG. 33A, the second compute unit 3312B of FIG. 33A, the first inlet 3316A of FIG. 33A, the second inlet 3316B of FIG. 33A, and the outlet 3318 of FIG. 33A. In the illustrated example of FIG. 33B, the second cooling system 3322 includes the example system 3200 of FIG. 32, which includes the first heat sink assembly 3202A coupled to the first compute unit 3312A and the second heat sink assembly 3302B coupled to the second compute unit 3312B, respectively. In the illustrated example of FIG. 33B, the second cooling system includes example piping 3324.

In the illustrated example of FIG. 33B, the first inlet 3316A directs coolant from the CDU 3308 into the main flow path 3320 through the tank 3304, which is exhausted from the tank 3304 via the outlet 3318. In the illustrated example of FIG. 33B, the second inlet 3316B directs coolant from the CDU 3308 into the piping 3324, which sequentially flows through the heat sink assemblies 3202A, 3202B. A first portion of the coolant flowing (e.g., similar to the first portion 3218 of FIG. 32, etc.) is exhausted into the main flow path 3320 after entering the first heat sink assembly 3202A, which cools the first compute unit 3312A. A second portion of the coolant flowing (e.g., similar to the second portion 3220 of FIG. 32, etc.) exits the first heat sink assembly 3202A via the inter-assembly tube 3206 of FIG. 32 and enters the second heat sink assembly 3202B. A second portion of the coolant is exhausted into the main flow path 3320 after entering the second heat sink assembly 3202B, which cools the second compute unit 3312B. After flowing through the heat sink assemblies 3202A, 3202B and cooling the compute units 3312A, 3312B, the coolant is returned into the main flow path 3320 and exhausted from the tank 3304 via the outlet 3318.

FIG. 34 is a block diagram of an example programmable circuitry platform 3400 structured to execute and/or instantiate the example machine-readable instructions and/or the example operations of FIG. 27 to implement the flow control circuitry of FIG. 26. The programmable circuitry platform 3400 can be, for example, a server, a personal computer, a workstation, a self-learning machine (e.g., a neural network), a mobile device (e.g., a cell phone, a smart phone, a tablet such as an iPad™), a personal digital assistant (PDA), an Internet appliance, a headset (e.g., an augmented reality (AR) headset, a virtual reality (VR) headset, etc.) or other wearable device, or any other type of computing and/or electronic device.

The programmable circuitry platform 3400 of the illustrated example includes programmable circuitry 3412. The programmable circuitry 3412 of the illustrated example is hardware. For example, the programmable circuitry 3412 can be implemented by one or more integrated circuits, logic circuits, FPGAs, microprocessors, CPUs, GPUs, DSPs, and/or microcontrollers from any desired family or manufacturer. The programmable circuitry 3412 may be implemented by one or more semiconductor based (e.g., silicon based) devices. In this example, the programmable circuitry 3412 implements the sensor interface circuitry 2602, the cooling demand determiner circuitry 2604, the pathway arrangement determiner circuitry 2606, and/or the system interface circuitry 2608.

The programmable circuitry 3412 of the illustrated example includes a local memory 3413 (e.g., a cache, registers, etc.). The programmable circuitry 3412 of the illustrated example is in communication with main memory 3414, 3416, which includes a volatile memory 3414 and a non-volatile memory 3416, by a bus 3418. The volatile memory 3414 may be implemented by Synchronous Dynamic Random Access Memory (SDRAM), Dynamic Random Access Memory (DRAM), RAMBUS® Dynamic Random Access Memory (RDRAM®), and/or any other type of RAM device. The non-volatile memory 3416 may be implemented by flash memory and/or any other desired type of memory device. Access to the main memory 3414, 3416 of the illustrated example is controlled by a memory controller 3417. In some examples, the memory controller 3417 may be implemented by one or more integrated circuits, logic circuits, microcontrollers from any desired family or manufacturer, or any other type of circuitry to manage the flow of data going to and from the main memory 3414, 3416.

The programmable circuitry platform 3400 of the illustrated example also includes interface circuitry 3420. The interface circuitry 3420 may be implemented by hardware in accordance with any type of interface standard, such as an Ethernet interface, a universal serial bus (USB) interface, a Bluetooth® interface, a near field communication (NFC) interface, a Peripheral Component Interconnect (PCI) interface, and/or a Peripheral Component Interconnect Express (PCIe) interface.

In the illustrated example, one or more input devices 3422 are connected to the interface circuitry 3420. The input device(s) 3422 permit(s) a user (e.g., a human user, a machine user, etc.) to enter data and/or commands into the programmable circuitry 3412. The input device(s) 3422 can be implemented by, for example, an audio sensor, a microphone, a camera (still or video), a keyboard, a button, a mouse, a touchscreen, a trackpad, a trackball, an isopoint device, and/or a voice recognition system.

One or more output devices 3424 are also connected to the interface circuitry 3420 of the illustrated example. The output device(s) 3424 can be implemented, for example, by display devices (e.g., a light emitting diode (LED), an organic light emitting diode (OLED), a liquid crystal display (LCD), a cathode ray tube (CRT) display, an in-place switching (IPS) display, a touchscreen, etc.), a tactile output device, a printer, and/or speaker. The interface circuitry 3420 of the illustrated example, thus, typically includes a graphics driver card, a graphics driver chip, and/or graphics processor circuitry such as a GPU.

The interface circuitry 3420 of the illustrated example also includes a communication device such as a transmitter, a receiver, a transceiver, a modem, a residential gateway, a wireless access point, and/or a network interface to facilitate exchange of data with external machines (e.g., computing devices of any kind) by a network 3426. The communication can be by, for example, an Ethernet connection, a digital subscriber line (DSL) connection, a telephone line connection, a coaxial cable system, a satellite system, a beyond-line-of-sight wireless system, a line-of-sight wireless system, a cellular telephone system, an optical connection, etc.

The programmable circuitry platform 3400 of the illustrated example also includes one or more mass storage discs or devices 3428 to store firmware, software, and/or data. Examples of such mass storage discs or devices 3428 include magnetic storage devices (e.g., floppy disk, drives, HDDs, etc.), optical storage devices (e.g., Blu-ray disks, CDs, DVDs, etc.), RAID systems, and/or solid-state storage discs or devices such as flash memory devices and/or SSDs.

The machine readable instructions 3432, which may be implemented by the machine readable instructions of FIG. 27, may be stored in the mass storage device 3428, in the volatile memory 3414, in the non-volatile memory 3416, and/or on at least one non-transitory computer readable storage medium such as a CD or DVD which may be removable.

FIG. 35 is a block diagram of an example implementation of the programmable circuitry 3412 of FIG. 34. In this example, the programmable circuitry 3412 of FIG. 34 is implemented by a microprocessor 3500. For example, the microprocessor 3500 may be a general-purpose microprocessor (e.g., general-purpose microprocessor circuitry). The microprocessor 3500 executes some or all of the machine-readable instructions of the flowcharts of FIG. 27 to effectively instantiate the circuitry of FIG. 2 as logic circuits to perform operations corresponding to those machine readable instructions. In some such examples, the circuitry of FIG. 26 is instantiated by the hardware circuits of the microprocessor 3500 in combination with the machine-readable instructions. For example, the microprocessor 3500 may be implemented by multi-core hardware circuitry such as a CPU, a DSP, a GPU, an XPU, etc. Although it may include any number of example cores 3502 (e.g., 1 core), the microprocessor 3500 of this example is a multi-core semiconductor device including N cores. The cores 3502 of the microprocessor 3500 may operate independently or may cooperate to execute machine readable instructions. For example, machine code corresponding to a firmware program, an embedded software program, or a software program may be executed by one of the cores 3502 or may be executed by multiple ones of the cores 3502 at the same or different times. In some examples, the machine code corresponding to the firmware program, the embedded software program, or the software program is split into threads and executed in parallel by two or more of the cores 3502. The software program may correspond to a portion or all of the machine readable instructions and/or operations represented by the flowcharts of FIG. 27.

The cores 3502 may communicate by a first example bus 3504. In some examples, the first bus 3504 may be implemented by a communication bus to effectuate communication associated with one(s) of the cores 3502. For example, the first bus 3504 may be implemented by at least one of an Inter-Integrated Circuit (I2C) bus, a Serial Peripheral Interface (SPI) bus, a PCI bus, or a PCIe bus. Additionally or alternatively, the first bus 3504 may be implemented by any other type of computing or electrical bus. The cores 3502 may obtain data, instructions, and/or signals from one or more external devices by example interface circuitry 3506. The cores 3502 may output data, instructions, and/or signals to the one or more external devices by the interface circuitry 3506. Although the cores 3502 of this example include example local memory 3520 (e.g., Level 1 (L1) cache that may be split into an L1 data cache and an L1 instruction cache), the microprocessor 3500 also includes example shared memory 3510 that may be shared by the cores (e.g., Level 2 (L2 cache)) for high-speed access to data and/or instructions. Data and/or instructions may be transferred (e.g., shared) by writing to and/or reading from the shared memory 3510. The local memory 3520 of each of the cores 3502 and the shared memory 3510 may be part of a hierarchy of storage devices including multiple levels of cache memory and the main memory (e.g., the main memory 3414, 3416 of FIG. 34). Typically, higher levels of memory in the hierarchy exhibit lower access time and have smaller storage capacity than lower levels of memory. Changes in the various levels of the cache hierarchy are managed (e.g., coordinated) by a cache coherency policy.

Each core 3502 may be referred to as a CPU, DSP, GPU, etc., or any other type of hardware circuitry. Each core 3502 includes control unit circuitry 3514, arithmetic and logic (AL) circuitry 3516 (sometimes referred to as an ALU), a plurality of registers 3518, the local memory 3520, and a second example bus 3522. Other structures may be present. For example, each core 3502 may include vector unit circuitry, single instruction multiple data (SIMD) unit circuitry, load/store unit (LSU) circuitry, branch/jump unit circuitry, floating-point unit (FPU) circuitry, etc. The control unit circuitry 3514 includes semiconductor-based circuits structured to control (e.g., coordinate) data movement within the corresponding core 3502. The AL circuitry 3516 includes semiconductor-based circuits structured to perform one or more mathematic and/or logic operations on the data within the corresponding core 3502. The AL circuitry 3516 of some examples performs integer based operations. In other examples, the AL circuitry 3516 also performs floating-point operations. In yet other examples, the AL circuitry 3516 may include first AL circuitry that performs integer-based operations and second AL circuitry that performs floating-point operations. In some examples, the AL circuitry 3516 may be referred to as an Arithmetic Logic Unit (ALU).

The registers 3518 are semiconductor-based structures to store data and/or instructions such as results of one or more of the operations performed by the AL circuitry 3516 of the corresponding core 3502. For example, the registers 3518 may include vector register(s), SIMD register(s), general-purpose register(s), flag register(s), segment register(s), machine-specific register(s), instruction pointer register(s), control register(s), debug register(s), memory management register(s), machine check register(s), etc. The registers 3518 may be arranged in a bank as shown in FIG. 35. Alternatively, the registers 3518 may be organized in any other arrangement, format, or structure, such as by being distributed throughout the core 3502 to shorten access time. The second bus 3522 may be implemented by at least one of an I2C bus, a SPI bus, a PCI bus, or a PCIe bus.

Each core 3502 and/or, more generally, the microprocessor 3500 may include additional and/or alternate structures to those shown and described above. For example, one or more clock circuits, one or more power supplies, one or more power gates, one or more cache home agents (CHAs), one or more converged/common mesh stops (CMSs), one or more shifters (e.g., barrel shifter(s)) and/or other circuitry may be present. The microprocessor 3500 is a semiconductor device fabricated to include many transistors interconnected to implement the structures described above in one or more integrated circuits (ICs) contained in one or more packages.

The microprocessor 3500 may include and/or cooperate with one or more accelerators (e.g., acceleration circuitry, hardware accelerators, etc.). In some examples, accelerators are implemented by logic circuitry to perform certain tasks more quickly and/or efficiently than can be done by a general-purpose processor. Examples of accelerators include ASICs and FPGAs such as those discussed herein. A GPU, DSP and/or other programmable device can also be an accelerator. Accelerators may be on-board the microprocessor 3500, in the same chip package as the microprocessor 3500 and/or in one or more separate packages from the microprocessor 3500.

FIG. 36 is a block diagram of another example implementation of the programmable circuitry 3412 of FIG. 34. In this example, the programmable circuitry 3412 is implemented by FPGA circuitry 3600. For example, the FPGA circuitry 3600 may be implemented by an FPGA. The FPGA circuitry 3600 can be used, for example, to perform operations that could otherwise be performed by the example microprocessor 3500 of FIG. 35 executing corresponding machine readable instructions. However, once configured, the FPGA circuitry 3600 instantiates the operations and/or functions corresponding to the machine readable instructions in hardware and, thus, can often execute the operations/functions faster than they could be performed by a general-purpose microprocessor executing the corresponding software.

More specifically, in contrast to the microprocessor 3500 of FIG. 35 described above (which is a general purpose device that may be programmed to execute some or all of the machine readable instructions represented by the flowchart of FIG. 27 but whose interconnections and logic circuitry are fixed once fabricated), the FPGA circuitry 3600 of the example of FIG. 36 includes interconnections and logic circuitry that may be configured, structured, programmed, and/or interconnected in different ways after fabrication to instantiate, for example, some or all of the operations/functions corresponding to the machine readable instructions represented by the flowchart of FIG. 27. In particular, the FPGA circuitry 3600 may be thought of as an array of logic gates, interconnections, and switches. The switches can be programmed to change how the logic gates are interconnected by the interconnections, effectively forming one or more dedicated logic circuits (unless and until the FPGA circuitry 3600 is reprogrammed). The configured logic circuits enable the logic gates to cooperate in different ways to perform different operations on data received by input circuitry. Those operations may correspond to some or all of the instructions (e.g., the software and/or firmware) represented by the flowchart of FIG. 27. As such, the FPGA circuitry 3600 may be configured and/or structured to effectively instantiate some or all of the operations/functions corresponding to the machine readable instructions of the flowchart of FIG. 27 as dedicated logic circuits to perform the operations/functions corresponding to those software instructions in a dedicated manner analogous to an ASIC. Therefore, the FPGA circuitry 3600 may perform the operations/functions corresponding to the some or all of the machine readable instructions of FIG. 27 faster than the general-purpose microprocessor can execute the same.

In the example of FIG. 36, the FPGA circuitry 3600 is configured and/or structured in response to being programmed (and/or reprogrammed one or more times) based on a binary file. In some examples, the binary file may be compiled and/or generated based on instructions in a hardware description language (HDL) such as Lucid, Very High Speed Integrated Circuits (VHSIC) Hardware Description Language (VHDL), or Verilog. For example, a user (e.g., a human user, a machine user, etc.) may write code or a program corresponding to one or more operations/functions in an HDL; the code/program may be translated into a low-level language as needed; and the code/program (e.g., the code/program in the low-level language) may be converted (e.g., by a compiler, a software application, etc.) into the binary file. In some examples, the FPGA circuitry 3600 of FIG. 36 may access and/or load the binary file to cause the FPGA circuitry 3600 of FIG. 36 to be configured and/or structured to perform the one or more operations/functions. For example, the binary file may be implemented by a bit stream (e.g., one or more computer-readable bits, one or more machine-readable bits, etc.), data (e.g., computer-readable data, machine-readable data, etc.), and/or machine-readable instructions accessible to the FPGA circuitry 3600 of FIG. 36 to cause configuration and/or structuring of the FPGA circuitry 3600 of FIG. 36, or portion(s) thereof.

In some examples, the binary file is compiled, generated, transformed, and/or otherwise output from a uniform software platform utilized to program FPGAs. For example, the uniform software platform may translate first instructions (e.g., code or a program) that correspond to one or more operations/functions in a high-level language (e.g., C, C++, Python, etc.) into second instructions that correspond to the one or more operations/functions in an HDL. In some such examples, the binary file is compiled, generated, and/or otherwise output from the uniform software platform based on the second instructions. In some examples, the FPGA circuitry 3600 of FIG. 36 may access and/or load the binary file to cause the FPGA circuitry 3600 of FIG. 36 to be configured and/or structured to perform the one or more operations/functions. For example, the binary file may be implemented by a bit stream (e.g., one or more computer-readable bits, one or more machine-readable bits, etc.), data (e.g., computer-readable data, machine-readable data, etc.), and/or machine-readable instructions accessible to the FPGA circuitry 3600 of FIG. 36 to cause configuration and/or structuring of the FPGA circuitry 3600 of FIG. 36, or portion(s) thereof.

The FPGA circuitry 3600 of FIG. 36, includes example input/output (I/O) circuitry 3602 to obtain and/or output data to/from example configuration circuitry 3604 and/or external hardware 3606. For example, the configuration circuitry 3604 may be implemented by interface circuitry that may obtain a binary file, which may be implemented by a bit stream, data, and/or machine-readable instructions, to configure the FPGA circuitry 3600, or portion(s) thereof. In some such examples, the configuration circuitry 3604 may obtain the binary file from a user, a machine (e.g., hardware circuitry (e.g., programmable or dedicated circuitry) that may implement an Artificial Intelligence/Machine Learning (AI/ML) model to generate the binary file), etc., and/or any combination(s) thereof). In some examples, the external hardware 3606 may be implemented by external hardware circuitry. For example, the external hardware 3606 may be implemented by the microprocessor 3500 of FIG. 35.

The FPGA circuitry 3600 also includes an array of example logic gate circuitry 3608, a plurality of example configurable interconnections 3610, and example storage circuitry 3612. The logic gate circuitry 3608 and the configurable interconnections 3610 are configurable to instantiate one or more operations/functions that may correspond to at least some of the machine readable instructions of FIG. 27 and/or other desired operations. The logic gate circuitry 3608 shown in FIG. 36 is fabricated in blocks or groups. Each block includes semiconductor-based electrical structures that may be configured into logic circuits. In some examples, the electrical structures include logic gates (e.g., And gates, Or gates, Nor gates, etc.) that provide basic building blocks for logic circuits. Electrically controllable switches (e.g., transistors) are present within each of the logic gate circuitry 3608 to enable configuration of the electrical structures and/or the logic gates to form circuits to perform desired operations/functions. The logic gate circuitry 3608 may include other electrical structures such as look-up tables (LUTs), registers (e.g., flip-flops or latches), multiplexers, etc.

The configurable interconnections 3610 of the illustrated example are conductive pathways, traces, vias, or the like that may include electrically controllable switches (e.g., transistors) whose state can be changed by programming (e.g., using an HDL instruction language) to activate or deactivate one or more connections between one or more of the logic gate circuitry 3608 to program desired logic circuits.

The storage circuitry 3612 of the illustrated example is structured to store result(s) of the one or more of the operations performed by corresponding logic gates. The storage circuitry 3612 may be implemented by registers or the like. In the illustrated example, the storage circuitry 3612 is distributed amongst the logic gate circuitry 3608 to facilitate access and increase execution speed.

The example FPGA circuitry 3600 of FIG. 36 also includes example dedicated operations circuitry 3614. In this example, the dedicated operations circuitry 3614 includes special purpose circuitry 3616 that may be invoked to implement commonly used functions to avoid the need to program those functions in the field. Examples of such special purpose circuitry 3616 include memory (e.g., DRAM) controller circuitry, PCIe controller circuitry, clock circuitry, transceiver circuitry, memory, and multiplier-accumulator circuitry. Other types of special purpose circuitry may be present. In some examples, the FPGA circuitry 3600 may also include example general purpose programmable circuitry 3618 such as an example CPU 3620 and/or an example DSP 3622. Other general purpose programmable circuitry 3618 may additionally or alternatively be present such as a GPU, an XPU, etc., that can be programmed to perform other operations.

Although FIGS. 35 and 36 illustrate two example implementations of the programmable circuitry 3412 of FIG. 34, many other approaches are contemplated. For example, FPGA circuitry may include an on-board CPU, such as one or more of the example CPU 3620 of FIG. 35. Therefore, the programmable circuitry 3412 of FIG. 34 may additionally be implemented by combining at least the example microprocessor 3500 of FIG. 35 and the example FPGA circuitry 3600 of FIG. 36. In some such hybrid examples, one or more cores 3502 of FIG. 35 may execute a first portion of the machine readable instructions represented by the flowchart of FIG. 27 to perform first operation(s)/function(s), the FPGA circuitry 3600 of FIG. 36 may be configured and/or structured to perform second operation(s)/function(s) corresponding to a second portion of the machine readable instructions represented by the flowcharts of FIG. [Flowcharts], and/or an ASIC may be configured and/or structured to perform third operation(s)/function(s) corresponding to a third portion of the machine readable instructions represented by the flowcharts of FIG. 27.

It should be understood that some or all of the circuitry of FIG. 26 may, thus, be instantiated at the same or different times. For example, same and/or different portion(s) of the microprocessor 3500 of FIG. 35 may be programmed to execute portion(s) of machine-readable instructions at the same and/or different times. In some examples, same and/or different portion(s) of the FPGA circuitry 3600 of FIG. 36 may be configured and/or structured to perform operations/functions corresponding to portion(s) of machine-readable instructions at the same and/or different times.

In some examples, some or all of the circuitry of FIG. 26 may be instantiated, for example, in one or more threads executing concurrently and/or in series. For example, the microprocessor 3500 of FIG. 35 may execute machine readable instructions in one or more threads executing concurrently and/or in series. In some examples, the FPGA circuitry 3600 of FIG. 36 may be configured and/or structured to carry out operations/functions concurrently and/or in series. Moreover, in some examples, some or all of the circuitry of FIG. 26 may be implemented within one or more virtual machines and/or containers executing on the microprocessor 3500 of FIG. 35.

In some examples, the programmable circuitry 3412 of FIG. 34 may be in one or more packages. For example, the microprocessor 3500 of FIG. 35 and/or the FPGA circuitry 3600 of FIG. 36 may be in one or more packages. In some examples, an XPU may be implemented by the programmable circuitry 3412 of FIG. 34, which may be in one or more packages. For example, the XPU may include a CPU (e.g., the microprocessor 3500 of FIG. 35, the CPU 3620 of FIG. 36, etc.) in one package, a DSP (e.g., the DSP 3622 of FIG. 36) in another package, a GPU in yet another package, and an FPGA (e.g., the FPGA circuitry 3600 of FIG. 36) in still yet another package.

“Including” and “comprising” (and all forms and tenses thereof) are used herein to be open ended terms. Thus, whenever a claim employs any form of “include” or “comprise” (e.g., comprises, includes, comprising, including, having, etc.) as a preamble or within a claim recitation of any kind, it is to be understood that additional elements, terms, etc., may be present without falling outside the scope of the corresponding claim or recitation. As used herein, when the phrase “at least” is used as the transition term in, for example, a preamble of a claim, it is open-ended in the same manner as the term “comprising” and “including” are open ended. The term “and/or” when used, for example, in a form such as A, B, and/or C refers to any combination or subset of A, B, C such as (1) A alone, (2) B alone, (3) C alone, (4) A with B, (5) A with C, (6) B with C, or (7) A with B and with C. As used herein in the context of describing structures, components, items, objects and/or things, the phrase “at least one of A and B” is intended to refer to implementations including any of (1) at least one A, (2) at least one B, or (3) at least one A and at least one B. Similarly, as used herein in the context of describing structures, components, items, objects and/or things, the phrase “at least one of A or B” is intended to refer to implementations including any of (1) at least one A, (2) at least one B, or (3) at least one A and at least one B. As used herein in the context of describing the performance or execution of processes, instructions, actions, activities, etc., the phrase “at least one of A and B” is intended to refer to implementations including any of (1) at least one A, (2) at least one B, or (3) at least one A and at least one B. Similarly, as used herein in the context of describing the performance or execution of processes, instructions, actions, activities, etc., the phrase “at least one of A or B” is intended to refer to implementations including any of (1) at least one A, (2) at least one B, or (3) at least one A and at least one B.

As used herein, singular references (e.g., “a”, “an”, “first”, “second”, etc.) do not exclude a plurality. The term “a” or “an” object, as used herein, refers to one or more of that object. The terms “a” (or “an”), “one or more”, and “at least one” are used interchangeably herein. Furthermore, although individually listed, a plurality of means, elements, or actions may be implemented by, e.g., the same entity or object. Additionally, although individual features may be included in different examples or claims, these may possibly be combined, and the inclusion in different examples or claims does not imply that a combination of features is not feasible and/or advantageous.

As used herein, unless otherwise stated, the term “above” describes the relationship of two parts relative to Earth. A first part is above a second part, if the second part has at least one part between Earth and the first part. Likewise, as used herein, a first part is “below” a second part when the first part is closer to the Earth than the second part. As noted above, a first part can be above or below a second part with one or more of: other parts therebetween, without other parts therebetween, with the first and second parts touching, or without the first and second parts being in direct contact with one another.

As used in this patent, stating that any part (e.g., a layer, film, area, region, or plate) is in any way on (e.g., positioned on, located on, disposed on, or formed on, etc.) another part, indicates that the referenced part is either in contact with the other part, or that the referenced part is above the other part with one or more intermediate part(s) located therebetween.

As used herein, connection references (e.g., attached, coupled, connected, and joined) may include intermediate members between the elements referenced by the connection reference and/or relative movement between those elements unless otherwise indicated. As such, connection references do not necessarily infer that two elements are directly connected and/or in fixed relation to each other. As used herein, stating that any part is in “contact” with another part is defined to mean that there is no intermediate part between the two parts.

Unless specifically stated otherwise, descriptors such as “first,” “second,” “third,” etc., are used herein without imputing or otherwise indicating any meaning of priority, physical order, arrangement in a list, and/or ordering in any way, but are merely used as labels and/or arbitrary names to distinguish elements for ease of understanding the disclosed examples. In some examples, the descriptor “first” may be used to refer to an element in the detailed description, while the same element may be referred to in a claim with a different descriptor such as “second” or “third.” In such instances, it should be understood that such descriptors are used merely for identifying those elements distinctly within the context of the discussion (e.g., within a claim) in which the elements might, for example, otherwise share a same name.

As used herein, “approximately” and “about” modify their subjects/values to recognize the potential presence of variations that occur in real world applications. For example, “approximately” and “about” may modify dimensions that may not be exact due to manufacturing tolerances and/or other real world imperfections as will be understood by persons of ordinary skill in the art. For example, “approximately” and “about” may indicate such dimensions may be within a tolerance range of +/−10% unless otherwise specified herein.

As used herein “substantially real time” refers to occurrence in a near instantaneous manner recognizing there may be real world delays for computing time, transmission, etc. Thus, unless otherwise specified, “substantially real time” refers to real time+1 second.

As used herein, the phrase “in communication,” including variations thereof, encompasses direct communication and/or indirect communication through one or more intermediary components, and does not require direct physical (e.g., wired) communication and/or constant communication, but rather additionally includes selective communication at periodic intervals, scheduled intervals, aperiodic intervals, and/or one-time events.

As used herein, “programmable circuitry” is defined to include (i) one or more special purpose electrical circuits (e.g., an application specific circuit (ASIC)) structured to perform specific operation(s) and including one or more semiconductor-based logic devices (e.g., electrical hardware implemented by one or more transistors), and/or (ii) one or more general purpose semiconductor-based electrical circuits programmable with instructions to perform specific functions(s) and/or operation(s) and including one or more semiconductor-based logic devices (e.g., electrical hardware implemented by one or more transistors). Examples of programmable circuitry include programmable microprocessors such as Central Processor Units (CPUs) that may execute first instructions to perform one or more operations and/or functions, Field Programmable Gate Arrays (FPGAs) that may be programmed with second instructions to cause configuration and/or structuring of the FPGAs to instantiate one or more operations and/or functions corresponding to the first instructions, Graphics Processor Units (GPUs) that may execute first instructions to perform one or more operations and/or functions, Digital Signal Processors (DSPs) that may execute first instructions to perform one or more operations and/or functions, XPUs, Network Processing Units (NPUs) one or more microcontrollers that may execute first instructions to perform one or more operations and/or functions and/or integrated circuits such as Application Specific Integrated Circuits (ASICs). For example, an XPU may be implemented by a heterogeneous computing system including multiple types of programmable circuitry (e.g., one or more FPGAs, one or more CPUs, one or more GPUs, one or more NPUs, one or more DSPs, etc., and/or any combination(s) thereof), and orchestration technology (e.g., application programming interface(s) (API(s)) that may assign computing task(s) to whichever one(s) of the multiple types of programmable circuitry is/are suited and available to perform the computing task(s).

As used herein integrated circuit/circuitry is defined as one or more semiconductor packages containing one or more circuit elements such as transistors, capacitors, inductors, resistors, current paths, diodes, etc. For example an integrated circuit may be implemented as one or more of an ASIC, an FPGA, a chip, a microchip, programmable circuitry, a semiconductor substrate coupling multiple circuit elements, a system on chip (SoC), etc.

Methods and apparatus for immersion cooling systems are disclosed herein. Further examples and combinations thereof include the following:

Example 1 includes an apparatus comprising a base plate, fins extending from the base plate, a tube extending along an axis through the fins, the tube including an inlet, and a slot extending along the axis, wherein the inlet, the slot, and the fins sequentially define a flow pathway.

Example 2 includes the apparatus of example 1, further including a first side wall, and a second side wall, the fins disposed between the first side wall and the second side wall.

Example 3 includes the apparatus of example 1, wherein the slot has a first width at a first location adjacent to the inlet and a second width at a second location distal to the inlet, the first width lesser than the second width.

Example 4 includes the apparatus of example 1, wherein the slot is a first slot, the apparatus further including a first arm including a second slot, and a second arm including a third slot, the tube disposed between the first arm and the second arm.

Example 5 includes the apparatus of example 1, wherein the base plate is a first base plate, the tube is a first tube, the fins are first fins, the slot is a first slot, the apparatus further including a second tube fluidly coupled to the first tube, the second tube including a second slot, a second base plate, and second fins, the tube extending through the second fins.

Example 6 includes the apparatus of example 5, wherein the first slot has a first width, the second slot has a second width, the second width wider than the first width.

Example 7 includes the apparatus of example 1, wherein the fins are perpendicular to the axis.

Example 8 includes an apparatus comprising an immersion cooling tank, a chassis in the immersion cooling tank, the chassis including a compute unit, a duct extending along the chassis, the duct defining a coolant pathway, the compute unit disposed in the coolant pathway, and a plate including an opening disposed in the coolant pathway.

Example 9 includes the apparatus of example 8, wherein the duct further includes a flange disposed between the plate and the chassis, an abutment of the flange and the plate retaining a position of the duct in the immersion cooling tank, and a seal disposed in a groove of the flange.

Example 10 includes the apparatus of example 8, wherein the duct further includes a first portion aligned with the compute unit, a second portion adjacent to the opening, and a tube disposed between the first portion and the second portion.

Example 11 includes the apparatus of example 10, wherein the compute unit is a first compute unit, the chassis includes a second compute unit, the tube is a first tube, and the duct further includes a third portion aligned with the second compute unit, and a second tube portion disposed between the second portion and the third portion.

Example 12 includes the apparatus of example 11, wherein the first compute unit and the second compute unit have a shadowed configuration in the chassis.

Example 13 includes the apparatus of example 8, wherein the coolant pathway is a first coolant pathway, the opening is a first opening and the plate further includes a second opening that is disposed in a second coolant pathway over the chassis.

Example 14 includes the apparatus of example 13, wherein the duct includes an outlet disposed in the coolant pathway.

Example 15 includes the apparatus of example 13, wherein the second opening is smaller than the first opening.

Example 16 includes the apparatus of example 8, wherein the opening is a first opening and the plate further includes a second opening disposed in the coolant pathway is a reverse flow pathway.

Example 17 includes a non-transitory machine readable storage medium comprising instructions to cause programmable circuitry to at least determine, based on an output of a sensor, a cooling demand of a compute unit disposed in an immersion cooling tank, the immersion cooling tank including a first junction, a second junction, and a third junction, determine, based on the cooling demand, a coolant pathway arrangement for the immersion cooling tank, the coolant pathway arrangement defining a flow of coolant between ones of the first junction, the second junction, and the third junction, and cause a position of at least two valves to change based on the coolant pathway arrangement.

Example 18 includes the non-transitory machine readable storage medium of example 17, wherein the coolant pathway arrangement includes a coolant pathway between the first junction and the third junction and the programmable circuitry executes the instructions to cause a first valve to open, the first valve regulating flow into the first junction, cause a second valve to open, the second valve regulating flow into the second junction, and cause a third valve to open, the third valve regulating flow into the third junction.

Example 19 includes the non-transitory machine readable storage medium of example 18, wherein the coolant pathway extends through a duct extending over the compute unit.

Example 20 includes the non-transitory machine readable storage medium of example 18, wherein the coolant pathway arrangement is a reverse coolant pathway arrangement.

Example 21 includes the non-transitory machine readable storage medium of example 17, wherein the coolant pathway arrangement includes a first coolant pathway between the first junction and the second junction and a second coolant pathway between the first junction and the third junction, and the programmable circuitry executes the instructions to cause a first valve to open, the first valve regulating flow into the first junction, cause a second valve to open, the second valve regulating flow into the second junction, cause a third valve to open, the third valve regulating flow into the third junction, and cause a fourth valve to open, the fourth valve disposed between the second valve and the third valve.

Example 22 includes the non-transitory machine readable storage medium of example 21, the programmable circuitry executes the instructions to open the first valve by partially opening the first valve.

The following claims are hereby incorporated into this Detailed Description by this reference. Although certain example systems, apparatus, articles of manufacture, and methods have been disclosed herein, the scope of coverage of this patent is not limited thereto. On the contrary, this patent covers all systems, apparatus, articles of manufacture, and methods fairly falling within the scope of the claims of this patent.

1. An apparatus comprising:
a base plate;
fins extending from the base plate;
a tube extending along an axis through the fins, the tube including:
an inlet; and
a slot extending along the axis, wherein the inlet, the slot, and the fins sequentially define a flow pathway.

2. The apparatus of claim 1, further including:
a first side wall; and
a second side wall, the fins disposed between the first side wall and the second side wall.

3. The apparatus of claim 1, wherein the slot has a first width at a first location adjacent to the inlet and a second width at a second location distal to the inlet, the first width lesser than the second width.

4. The apparatus of claim 1, wherein the slot is a first slot, the apparatus further including:
a first arm including a second slot; and
a second arm including a third slot, the tube disposed between the first arm and the second arm.

5. The apparatus of claim 1, wherein the base plate is a first base plate, the tube is a first tube, the fins are first fins, the slot is a first slot, the apparatus further including:
a second tube fluidly coupled to the first tube, the second tube including a second slot;
a second base plate; and
second fins, the tube extending through the second fins.

6. The apparatus of claim 5, wherein the first slot has a first width, the second slot has a second width, the second width wider than the first width.

7. (canceled)

8. An apparatus comprising:
an immersion cooling tank;
a chassis in the immersion cooling tank, the chassis including a compute unit;
a duct extending along the chassis, the duct defining a coolant pathway, the compute unit disposed in the coolant pathway; and
a plate including an opening disposed in the coolant pathway.

9. The apparatus of claim 8, wherein the duct further includes:
a flange disposed between the plate and the chassis, an abutment of the flange and the plate retaining a position of the duct in the immersion cooling tank; and
a seal disposed in a groove of the flange.

10. The apparatus of claim 8, wherein the duct further includes:
a first portion aligned with the compute unit;
a second portion adjacent to the opening; and
a tube disposed between the first portion and the second portion.

11. The apparatus of claim 10, wherein the compute unit is a first compute unit, the chassis includes a second compute unit, the tube is a first tube, and the duct further includes:
a third portion aligned with the second compute unit; and
a second tube portion disposed between the second portion and the third portion.

12. The apparatus of claim 11, wherein the first compute unit and the second compute unit have a shadowed configuration in the chassis.

13. The apparatus of claim 8, wherein the coolant pathway is a first coolant pathway, the opening is a first opening and the plate further includes a second opening that is disposed in a second coolant pathway over the chassis.

14. (canceled)

15. The apparatus of claim 13, wherein the second opening is smaller than the first opening.

16. The apparatus of claim 8, wherein the opening is a first opening and the plate further includes a second opening disposed in the coolant pathway is a reverse flow pathway.

17. A non-transitory machine readable storage medium comprising instructions to cause programmable circuitry to at least:
determine, based on an output of a sensor, a cooling demand of a compute unit disposed in an immersion cooling tank, the immersion cooling tank including a first junction, a second junction, and a third junction;
determine, based on the cooling demand, a coolant pathway arrangement for the immersion cooling tank, the coolant pathway arrangement defining a flow of coolant between ones of the first junction, the second junction, and the third junction; and
cause a position of at least two valves to change based on the coolant pathway arrangement.

18. The non-transitory machine readable storage medium of claim 17, wherein the coolant pathway arrangement includes a coolant pathway between the first junction and the third junction, and the programmable circuitry executes the instructions to:
cause a first valve to open, the first valve regulating flow into the first junction;
cause a second valve to open, the second valve regulating flow into the second junction; and
cause a third valve to open, the third valve regulating flow into the third junction.

19. The non-transitory machine readable storage medium of claim 18, wherein the coolant pathway extends through a duct extending over the compute unit.

20. The non-transitory machine readable storage medium of claim 18, wherein the coolant pathway arrangement is a reverse coolant pathway arrangement.

21. The non-transitory machine readable storage medium of claim 17, wherein the coolant pathway arrangement includes a first coolant pathway between the first junction and the second junction and a second coolant pathway between the first junction and the third junction, and the programmable circuitry executes the instructions to:
cause a first valve to open, the first valve regulating flow into the first junction;
cause a second valve to open, the second valve regulating flow into the second junction;
cause a third valve to open, the third valve regulating flow into the third junction; and
cause a fourth valve to open, the fourth valve disposed between the second valve and the third valve.

22. The non-transitory machine readable storage medium of claim 21, the programmable circuitry executes the instructions to open the first valve by partially opening the first valve.
